(19) United States
(12) Patent Application Publication
(10) Pub. No.: US 2024/0059720 A1
(43) Pub. Date: Feb. 22, 2024

(54) ORGANOMETALLIC COMPLEX, LIGHT-EMITTING DEVICE, LIGHT-EMITTING APPARATUS, ELECTRONIC DEVICE, AND LIGHTING DEVICE

(71) Applicant: Semiconductor Energy Laboratory Co., Ltd., Atsugi-shi Kanagawa-ken (JP)

(72) Inventors: Hideko YOSHIZUMI, Atsugi (JP); Hiromitsu KIDO, Atsugi (JP); Satomi WATABE, Atsugi (JP); Satoshi SEO, Sagamihara (JP)

(21) Appl. No.: 18/267,173

(22) PCT Filed: Dec. 16, 2021
(86) PCT No.: PCT/IB2021/061809

§ 371 Date: Jun. 14, 2023

(30) Foreign Application Priority Data
Dec. 25, 2020 (JP) 2020-216304

(51) Int. Cl. C07F 15/00; H10K 85/60

(52) U.S. Cl. CPC C07F 15/0033; H10K 85/654

(57) ABSTRACT

A novel organometallic complex is provided. An organometallic complex represented by General Formula (G1) includes iridium, a first ligand, and a second ligand. Each of the first ligand and the second ligand is a cyclometalated ligand. The first ligand has a quinoline ring coordinated to the iridium. The second ligand has a pyrimidine ring coordinated to the iridium. At least one of the first ligand and the second ligand includes a substituted or unsubstituted aryl group as a substituent. The proportion of the first ligand is twice the proportion of the second ligand.

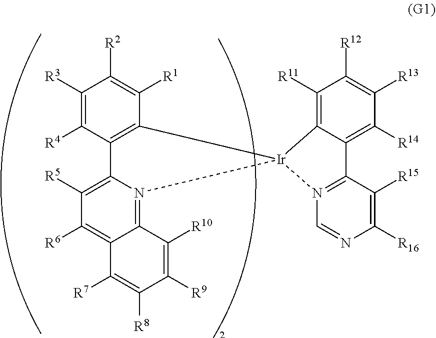

(In General Formula (G1), R1 to R16 each independently represent any one of hydrogen, a substituted or unsubstituted alkyl group having 1 to 6 carbon atoms, a substituted or unsubstituted aryl group having 6 to 13 carbon atoms, and a substituted or unsubstituted heteroaryl group having 3 to 12 carbon atoms.)

### TECHNICAL FIELD

One embodiment of the present invention relates to an organometallic complex. In particular, one embodiment of the present invention relates to an organometallic complex that can convert triplet excitation energy into light emission. Furthermore, one embodiment of the present invention relates to a light-emitting device, a light-emitting apparatus, an electronic device, and a lighting device each of which includes an organometallic complex. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Thus, more specifically, examples of the technical field of one embodiment of the present invention disclosed in this specification include, in addition to the above, a semiconductor device, a display device, a liquid crystal display device, a power storage device, a memory device, a driving method thereof, and a manufacturing method thereof.

### BACKGROUND ART

In recent years, research and development have been extensively conducted on light-emitting elements (organic EL elements) that use organic compounds and utilize electroluminescence (EL). In the basic structure of such light-emitting elements, an organic compound layer (an EL layer) containing a light-emitting substance is sandwiched between a pair of electrodes. By application of a voltage to the element, light emission from the light-emitting substance can be obtained.

An organic EL element is of self-emission type and thus has advantages over a liquid crystal display, such as high visibility of a pixel and no need of backlight, and is considered to be suitable as a flat panel display element. Furthermore, an organic EL element can provide planar light emission. This feature is difficult to realize with a point light source typified by an incandescent lamp and an LED or a linear light source typified by a fluorescent lamp; thus, the organic EL element also has a high utility value for application to lighting and the like.

In an organic EL element, electrons from a cathode and holes from an anode are injected into an EL layer. By recombination of them, the organic compound having a light-emitting property is excited and light emission can be obtained. The excited state can be a singlet excited state (S*) and a triplet excited state (T*): light emission from a singlet excited state is referred to as fluorescence, and light emission from a triplet excited state is referred to as phosphorescence. The statistical generation ratio thereof in the light-emitting element is considered to be S*:T*=1:3.

Among the above light-emitting substances, a compound capable of converting singlet excitation energy into light emission is called a fluorescent compound (a fluorescent material), and a compound capable of converting triplet excitation energy into light emission is called a phosphorescent compound (a phosphorescent material).

Accordingly, on the basis of the above generation ratio, the theoretical limit of the internal quantum efficiency (the ratio of generated photons to injected carriers) of a light-emitting element using each of the above light-emitting substances is 25% in the case of using a fluorescent material and 75% in the case of using a phosphorescent material.

In other words, a light-emitting element using a phosphorescent material can obtain higher efficiency than a light-emitting element using a fluorescent material. Thus, various kinds of phosphorescent materials have been actively developed in recent years. An organometallic complex that contains iridium or the like as a central metal is particularly attracting attention because of its high phosphorescence quantum yield (e.g., Patent Document 1).

### REFERENCE

[Patent Document]

[Patent Document 1] Japanese Published Patent Application No. 2009-23938

### SUMMARY OF THE INVENTION

### Problems to be Solved by the Invention

Although phosphorescent materials exhibiting excellent characteristics have been developed as disclosed in Patent Document 1 described above, development of novel materials with better characteristics has been desired.

In view of the above, one embodiment of the present invention is to provide a novel organometallic complex. One embodiment of the present invention is to provide a novel organometallic complex that can be used in a light-emitting device. One embodiment of the present invention is to provide a novel organometallic complex that can be used in an EL layer of a light-emitting device. One embodiment of the present invention is to provide a novel light-emitting device. In addition, a novel light-emitting apparatus, a novel electronic device, or a novel lighting device is provided. Note that the description of these objects does not preclude the existence of other objects. In one embodiment of the present invention, there is no need to achieve all of these objects. Note that other objects will be apparent from the description of the specification, the drawings, the claims, and the like, and other objects can be derived from the description of the specification, the drawings, the claims, and the like.

### Means for Solving the Problems

One embodiment of the present invention is an organometallic complex that includes iridium, a first ligand, and a second ligand. Each of the first ligand and the second ligand is a cyclometalated ligand. The first ligand has a quinoline ring coordinated to the iridium. The second ligand has a pyrimidine ring coordinated to the iridium. At least one of the first ligand and the second ligand includes a substituted or unsubstituted aryl group as a substituent. The proportion of the first ligand is twice the proportion of the second ligand.

Another embodiment of the present invention is an organometallic complex having a structure represented by General Formula (G1) below.

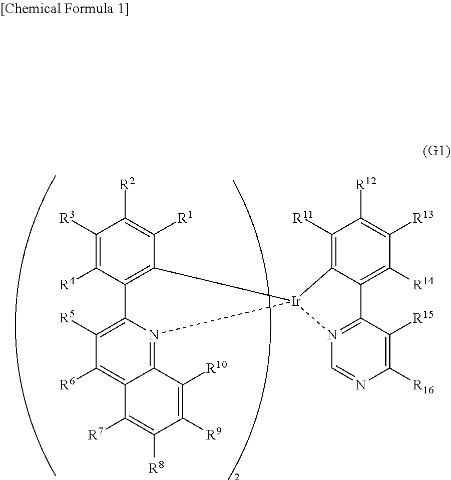

Note that in General Formula (G1), R¹ to R¹⁶ each independently represent any one of hydrogen, a substituted or unsubstituted alkyl group having 1 to 6 carbon atoms, a substituted or unsubstituted aryl group having 6 to 13 carbon atoms, and a substituted or unsubstituted heteroaryl group having 3 to 12 carbon atoms.

Another embodiment of the present invention is an organometallic complex represented by General Formula (G2) below.

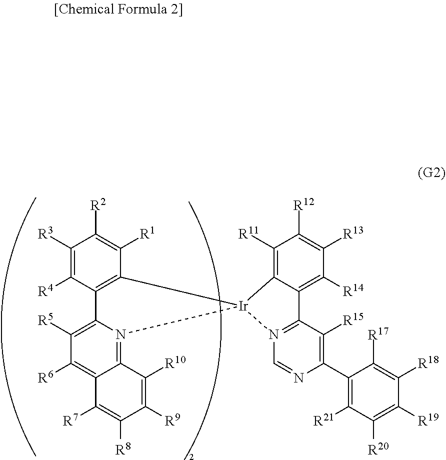

Note that in General Formula (G2), R¹ to R¹⁵ and R¹⁷ to R²¹ each independently represent any one of hydrogen, a substituted or unsubstituted alkyl group having 1 to 6 carbon atoms, a substituted or unsubstituted aryl group having 6 to 13 carbon atoms, and a substituted or unsubstituted heteroaryl group having 3 to 12 carbon atoms.

The organometallic complexes of embodiments of the present invention represented by General Formula (G1) and General Formula (G2) each contain, as ligands, two phenylquinoline compounds over which the highest occupied molecular orbital (also referred to as HOMO) is mainly distributed and one phenylpyrimidine compound over which the lowest unoccupied molecular orbital (also referred to as LUMO) is mainly distributed. By spatially separating HOMO and LUMO in this manner, holes are injected to a phenylquinoline ligand having a high resistance against holes, and electrons are injected to a phenylpyrimidine ligand having a high resistance against electrons; thus, the organometallic complex can have a high resistance against both holes and electrons. Furthermore, the above means that holes and electrons are separated also in an excited state, and contributes to stabilization in an excited state. Furthermore, the organometallic complex has improved hole-injection and electron-injection properties and thus has an improved balance of hole-transport and electron-transport properties; accordingly, element characteristics such as emission efficiency and a lifetime can be improved. Here, the feature is that at least either one of the first ligand and the second ligand includes an aryl group. This structure improves thermophysical properties, chemical stability, and electrical stability of the organometallic complex. In particular, a quinoline ring or a pyrimidine ring preferably includes an aryl group, in which case electrochemical stability of a heterocycle is improved. More preferably, a pyrimidine ring includes an aryl group, in which case LUMO is stabilized and HOMO and LUMO are easily separated. Therefore, with use of the organometallic complex of one embodiment of the present invention, the lifetime of a light-emitting device can be prolonged.

In the organometallic complex having any of the above structures, the half width of the emission spectrum is preferably greater than or equal to 70 nm and less than or equal to 120 nm, further preferably greater than or equal to 80 nm and less than or equal to 120 nm, still further preferably greater than or equal to 90 nm and less than or equal to 120 nm.

By using an organometallic complex exhibiting an emission spectrum with a large half width for a light-emitting device, the color-rendering properties of light emitted from the light-emitting device can be improved and light close to natural light can be obtained.

A large half width of an emission spectrum is attributed to a large change in the structure of the transition state of a light-emitting material. Therefore, there is a problem in that as the emission spectrum of a light-emitting material has a larger half width, the emission efficiency of a light-emitting device is likely to decrease. However, in spite of a large change in the structure of the transition state, the organometallic complex having any of the above structures can suppress a decrease in the emission efficiency of a light-emitting device. Thus, by using the organometallic complex having any of the above structures for a light-emitting device, a light-emitting device exhibiting an emission spectrum with a large half width and high emission efficiency can be obtained.

In the organometallic complex having any of the above structures, it is further preferable that the peak wavelength of the emission spectrum be greater than or equal to 590 nm and less than or equal to 620 nm.

By using an organometallic complex emitting such light for a light-emitting device, a light-emitting device emitting light of warm colors that is closer to natural light such as light of the setting sun, an incandescent lamp, a candle, and the like can be obtained even when different emission colors are not mixed.

Another embodiment of the present invention is an organometallic complex represented by Structural Formula (100) below.

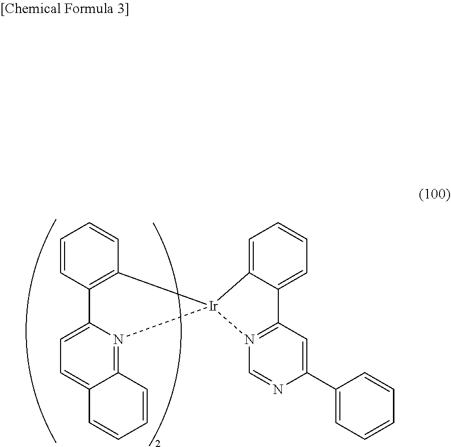

The organometallic complex of one embodiment of the present invention is very effective for the following reason: the organometallic complex can emit phosphorescence, that is, it can provide luminescence from a triplet excited state and can exhibit light emission, and therefore higher efficiency is possible when the organometallic complex is used in a light-emitting device. Therefore, a light-emitting device including the organometallic complex having any of the above structures is also one embodiment of the present invention.

Another embodiment of the present invention is a light-emitting device including an EL layer between a pair of electrodes. The EL layer includes the organometallic complex having any of the above structures.

Another embodiment of the present invention is a light-emitting device including an EL layer between a pair of electrodes. The EL layer includes a light-emitting layer. The light-emitting layer includes the organometallic complex having any of the above structures.

In the light-emitting device having any of the above structures, the half width of the electroluminescence spectrum is preferably greater than or equal to 70 nm and less than or equal to 120 nm, further preferably greater than or equal to 80 nm and less than or equal to 120 nm, still further preferably greater than or equal to 90 nm and less than or equal to 120 nm.

In a light-emitting device whose electroluminescence spectrum has a large half width, the color-rendering properties of light can be improved and light close to natural light can be obtained.

There is a problem in that as the electroluminescence spectrum of has a larger half width, the emission efficiency of a light-emitting device is likely to decrease. However, by employing any of the above structures for a light-emitting device, a light-emitting device exhibiting an electroluminescence spectrum with a large half width and high emission efficiency can be obtained.

In the light-emitting device having any of the above structures, it is preferable that the peak wavelength of the electroluminescence spectrum be greater than or equal to 590 nm and less than or equal to 620 nm.

Accordingly, a light-emitting device emitting light of warm colors that is closer to natural light such as light of the setting sun, an incandescent lamp, a candle, and the like can be obtained.

Another embodiment of the present invention is a light-emitting apparatus including a light-emitting device having any of the above structures, and at least one of a transistor and a substrate.

Another embodiment of the present invention is an electronic device including a light-emitting device having any of the above structures, and at least one of a microphone, a camera, a button for operation, an external connection portion, and a speaker.

Another embodiment of the present invention is a lighting device including a light-emitting device having any of the above structures and a housing.

The category of one embodiment of the present invention includes not only a light-emitting apparatus including a light-emitting device but also a lighting device including a light-emitting device. Accordingly, a light-emitting apparatus in this specification refers to an image display device or a light source (including a lighting device). In addition, a light-emitting apparatus includes a module in which a light-emitting apparatus is attached to a connector such as an FPC (Flexible Printed Circuit) or a TCP (Tape Carrier Package), a module in which a printed wiring board is provided on the tip of a TCP, or a module in which an IC (integrated circuit) is directly mounted on a light-emitting device by a COG (Chip On Glass) method.

### Effect of the Invention

One embodiment of the present invention can provide a novel organometallic complex. One embodiment of the present invention can provide a novel organometallic complex that can be used in a light-emitting device. One embodiment of the present invention can provide a novel organometallic complex that can be used in an EL layer of a light-emitting device. Note that a novel light-emitting device including a novel organometallic complex can be provided. In addition, a novel light-emitting apparatus, a novel electronic device, or a novel lighting device can be provided. Note that the description of these effects does not preclude the existence of other effects. One embodiment of the present invention does not need to have all of these effects. Note that other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A to FIG. 1C are schematic diagrams of light-emitting devices.

FIG. 2A and FIG. 2B are conceptual diagrams of an active matrix light-emitting apparatus.

FIG. 3A and FIG. 3B are conceptual diagrams of active matrix light-emitting apparatuses.

FIG. 4 is a conceptual diagram of an active matrix light-emitting apparatus.

FIG. 5A and FIG. 5B are conceptual diagrams of a passive matrix light-emitting apparatus.

FIG. 6A and FIG. 6B are diagrams illustrating structures of a light-emitting apparatus of one embodiment.

FIG. 7A and FIG. 7B are diagrams illustrating a manufacturing method of a light-emitting apparatus of one embodiment.

FIG. 8A to FIG. 8C are diagrams illustrating a manufacturing method of a light-emitting apparatus of one embodiment.

FIG. 9A to FIG. 9C are diagrams illustrating a manufacturing method of a light-emitting apparatus of one embodiment.

FIG. 10A and FIG. 10B are diagrams illustrating a manufacturing method of a light-emitting apparatus of one embodiment.

FIG. 11A and FIG. 11B are diagrams illustrating a light-emitting apparatus of one embodiment.

FIG. 12A and FIG. 12B are diagrams illustrating a lighting device.

FIG. 13A to FIG. 13D are diagrams illustrating electronic devices.

FIG. 14A, FIG. 14B, and FIG. 14C are diagrams illustrating electronic devices.

FIG. 15 is a diagram illustrating a lighting device.

FIG. 16 is a diagram illustrating a lighting device.

FIG. 17 is a diagram illustrating in-vehicle display devices and lighting devices.

FIG. 18A and FIG. 18B are diagrams illustrating an electronic device.

FIG. 19A, FIG. 19B, and FIG. 19C are diagrams illustrating an electronic device.

FIG. 20 is a ¹H-NMR chart of [Ir(pqn)₂(dppm)].

FIG. 21 shows an absorption spectrum and an emission spectrum of [Ir(pqn)₂(dppm)] in a dichloromethane solution.

FIG. 22 is a diagram illustrating a structure of a light-emitting device 1.

FIG. 23 is a diagram showing the luminance-current density characteristics of the light-emitting device 1.

FIG. 24 is a diagram showing the current efficiency-luminance characteristics of the light-emitting device 1.

FIG. 25 is a diagram showing the luminance-voltage characteristics of the light-emitting device 1.

FIG. 26 is a diagram showing the current-voltage characteristics of the light-emitting device 1.

FIG. 27 is a diagram showing the emission spectrum of the light-emitting device 1.

FIG. 28 is a diagram showing the reliability of the light-emitting device 1.

### MODE FOR CARRYING OUT THE INVENTION

Embodiments of the present invention will be described in detail below with reference to the drawings. Note that the present invention is not limited to the following description, and the modes and details of the present invention can be modified in various ways without departing from the spirit and scope of the present invention. Therefore, the present invention should not be construed as being limited to the description in the following embodiments.

Note that the term “film” and the term “layer” can be interchanged with each other depending on the case or circumstances. For example, the term “conductive layer” can be changed into the term “conductive film” in some cases. As another example, the term “insulating film” can be changed into the term “insulating layer” in some cases.

### Embodiment 1

In this embodiment, an organometallic complex of one embodiment of the present invention will be described.

One embodiment of the present invention is an organometallic complex that includes iridium, a first ligand, and a second ligand. Each of the first ligand and the second ligand is a cyclometalated ligand. The first ligand has a quinoline ring coordinated to the iridium. A second aromatic ring has a pyrimidine ring coordinated to the iridium. At least one of the first ligand and the second ligand includes a substituted or unsubstituted aryl group as a substituent. The proportion of the first ligand is twice the proportion of the second ligand.

Another embodiment of the present invention is an organometallic complex having a structure represented by General Formula (G1) below.

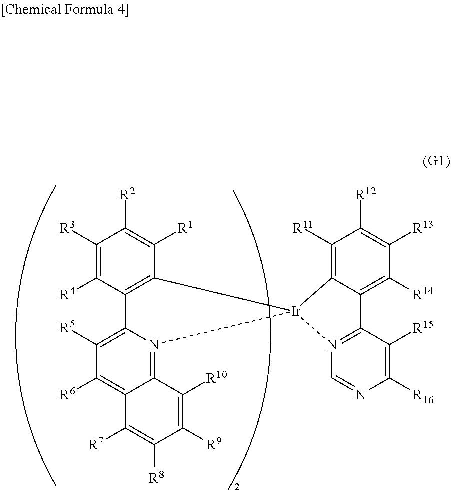

Note that in General Formula (G1), R¹ to R¹⁶ each independently represent any one of hydrogen, a substituted or unsubstituted alkyl group having 1 to 6 carbon atoms, a substituted or unsubstituted aryl group having 6 to 13 carbon atoms, and a substituted or unsubstituted heteroaryl group having 3 to 12 carbon atoms.

Note that the number of the above-described aryl groups with respect to the organometallic complex of one embodiment of the present invention is preferably one. That is, in General Formula (G1), it is preferable that one of R¹ to R¹⁵ represent a substituted or unsubstituted aryl group having 6 to 13 carbon atoms and the others represent any one of hydrogen, a halogen group, a substituted or unsubstituted alkyl group having 1 to 6 carbon atoms, and a substituted or unsubstituted heteroaryl group having 3 to 12 carbon atoms. This structure leads to an improvement in sublimability of the organometallic complex and contributes to an increase in the lifetime of a light-emitting device.

Another embodiment of the present invention is an organometallic complex having a structure represented by General Formula (G2) below.

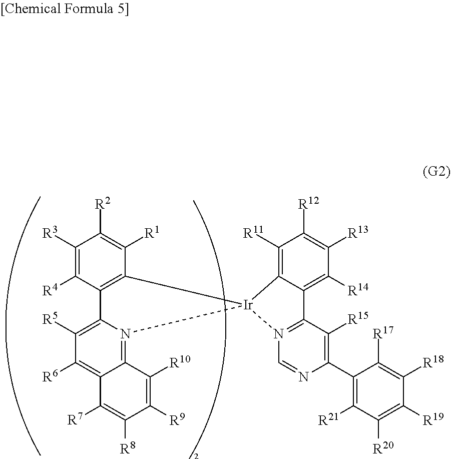

Note that in General Formula (G2), R¹ to R¹⁵ and R¹⁷ to R²¹ each independently represent any one of hydrogen, a substituted or unsubstituted alkyl group having 1 to 6 carbon atoms, a substituted or unsubstituted aryl group having 6 to 13 carbon atoms, and a substituted or unsubstituted heteroaryl group having 3 to 12 carbon atoms.

Specific examples of the alkyl group having 1 to 6 carbon atoms as any of R¹ to R¹⁶ in General Formula (G1) above and R¹ to R¹⁵ and R¹⁷ to R²¹ in General Formula (G2) above include a methyl group, an ethyl group, a propyl group, an isopropyl group, a butyl group, a sec-butyl group, an isobutyl group, a tent-butyl group, a pentyl group, an isopentyl group, a sec-pentyl group, a tent-pentyl group, a neopentyl group, a hexyl group, an isohexyl group, a sec-hexyl group, a tert-hexyl group, a neohexyl group, a 3-methylpentyl group, a 2-methylpentyl group, a 2-ethylbutyl group, a 1,2-dimethylbutyl group, a 2,3-dimethylbutyl group, and a trifluoromethyl group.

Specific examples of the aryl group having 6 to 13 carbon atoms as any of R¹ to R¹⁶ in General Formula (G1) above and R¹ to R¹⁵ and R¹⁷ to R²¹ in General Formula (G2) above include a phenyl group, a tolyl group (an o-tolyl group, an m-tolyl group, and a p-tolyl group), a naphthyl group (a 1-naphthyl group and a 2-naphthyl group), a biphenyl group (a biphenyl-2-yl group, a biphenyl-3-yl group, and a biphenyl-4-yl group), a xylyl group, a pentalenyl group, an indenyl group, a fluorenyl group, a phenanthryl group, and an indenyl group. Note that the above substituents may be bonded to each other to form a ring. Examples of such a case include the case where carbon at the 9-position in a fluorenyl group has two phenyl groups as substituents and the phenyl groups are bonded to each other to form a spirofluorene skeleton.

Specific examples of the heteroaryl group having 3 to 12 carbon atoms as any of R¹ to R¹⁶ in General Formula (G1) above and R¹ to R¹⁵ and R¹⁷ to R²¹ in General Formula (G2) above include an imidazolyl group, a pyrazolyl group, a pyridyl group, a pyridazyl group, a triazyl group, a benzimidazolyl group, a quinolyl group, a carbazolyl group, a dibenzofuranyl group, and a dibenzothiophenyl group.

In the organometallic complexes represented by General Formula (G1) above and General Formula (G2) above, in the case where any of the substituted or unsubstituted alkyl group having 1 to 6 carbon atoms, the substituted or unsubstituted aryl group having 6 to 13 carbon atoms, and the substituted or unsubstituted heteroaryl group having 3 to 12 carbon atoms includes a substituent, examples of the substituent include an alkyl group having 1 to 6 carbon atoms, such as a methyl group, an ethyl group, a propyl group, an isopropyl group, a butyl group, an isobutyl group, a sec-butyl group, a tent-butyl group, a pentyl group, or a hexyl group; a cycloalkyl group having 5 to 7 carbon atoms, such as a cyclopentyl group, a cyclohexyl group, a cycloheptyl group, a 1-norbornyl group, or a 2-norbornyl group; and an aryl group having 6 to 12 carbon atoms, such as a phenyl group or a biphenyl group. The above substituents may be bonded to each other to form a ring. In such a case, for example, a spirofluorene skeleton is formed in such a manner that any of R¹ to R¹⁶ in General Formula (G1) above and R¹ to R¹⁵ and R¹⁷ to R²¹ in General Formula (G2) above is a fluorenyl group that is an aryl group having 13 carbon atoms, carbon at the 9-position of the fluorenyl group has two phenyl groups as substituents, and these phenyl groups are bonded to each other.

The organometallic complexes of embodiments of the present invention represented by General Formula (G1) and General Formula (G2) each contain, as ligands, two phenylquinoline compounds over which the highest occupied molecular orbital (also referred to as HOMO) is mainly distributed and one phenylpyrimidine compound over which the lowest unoccupied molecular orbital (also referred to as LUMO) is mainly distributed. By spatially separating HOMO and LUMO in this manner, holes are injected to a phenylquinoline ligand having a high resistance against holes, and electrons are injected to a phenylpyrimidine ligand having a high resistance against electrons; thus, the organometallic complex can have a high resistance against both holes and electrons. Furthermore, the above means that holes and electrons are separated also in an excited state, and contributes to stabilization in an excited state. Furthermore, the organometallic complex has improved hole-injection and electron-injection properties and thus has an improved balance of hole-transport and electron-transport properties; accordingly, element characteristics such as emission efficiency and a lifetime can be improved. Here, the feature is that at least either one of the first ligand and the second ligand includes an aryl group. This structure improves thermophysical properties, chemical stability, and electrical stability of the organometallic complex. In particular, a quinoline ring or a pyrimidine ring preferably includes an aryl group, in which case electrochemical stability of a heterocycle is improved. More preferably, a pyrimidine ring includes an aryl group, in which case LUMO is stabilized and HOMO and LUMO are easily separated. Therefore, with use of the organometallic complex of one embodiment of the present invention, the lifetime of a light-emitting device can be prolonged.

In the organometallic complex having any of the structures represented by General Formula (G1) above and General Formula (G2) above, the half width of the emission spectrum is preferably greater than or equal to 70 nm, further preferably greater than or equal to 80 nm, still further preferably greater than or equal to 90 nm. By using an organometallic complex emitting light with a large half width of greater than or equal to 70 nm, preferably greater than or equal to 80 nm, further preferably greater than or equal to 90 nm for a light-emitting device, the color-rendering properties of light emitted from the light-emitting device can be improved and light close to natural light can be obtained. The half width of the emission spectrum is preferably less than or equal to 120 nm. Accordingly, light in which blue light is suppressed can be obtained as described later. Therefore, in the organometallic complex having any of the structures represented by General Formula (G1) above and General Formula (G2) above, the half width of the emission spectrum is preferably greater than or equal to 70 nm and less than or equal to 120 nm, further preferably greater than or equal to 80 nm and less than or equal to 120 nm, still further preferably greater than or equal to 90 nm and less than or equal to 120 nm.

Note that a large half width of an emission spectrum is attributed to a large change in the structure of the transition state of a light-emitting material. Therefore, there is a problem in that as the emission spectrum of a light-emitting material has a larger half width, the emission efficiency of a light-emitting device is likely to decrease. However, in spite of a large change in the structure of the transition state, the organometallic complex having any of the structures represented by General Formula (G1) above and General Formula (G2) above can suppress a decrease in the emission efficiency of a light-emitting device. Thus, by using the organometallic complex having any of the structures represented by General Formula (G1) above and General Formula (G2) above for a light-emitting device, a light-emitting device exhibiting an emission spectrum with a large half width and high emission efficiency can be obtained.

In the organometallic complex having any of the structures represented by General Formula (G1) above and General Formula (G2) above, it is further preferable that the peak wavelength of the emission spectrum be greater than or equal to 590 nm and less than or equal to 620 nm. By using an organometallic complex emitting such light for a light-emitting device, a light-emitting device emitting light of warm colors that is closer to natural light such as light of the setting sun, an incandescent lamp, a candle, and the like can be obtained even when different emission colors are not mixed (even when light is emitted from only the organometallic complex). In this case, the emission spectrum preferably has a large half width so that light closer to natural light is obtained; specifically, the half width is preferably greater than or equal to 70 nm, further preferably greater than or equal to 80 nm, still further preferably greater than or equal to 90 nm.

Light of warm colors emitted from the setting sun, an incandescent lamp, candle flame, and the like stimulates human's parasympathetic nerves and brings about a relaxing effect. By using, for a light-emitting device, the organometallic complex of one embodiment of the present invention exhibiting a peak wavelength of greater than or equal to 590 nm and less than or equal to 620 nm and a half width of greater than or equal to 70 nm, preferably greater than or equal to 80 nm, further preferably greater than or equal to 90 nm, the light-emitting device can bring about a relaxing effect for a user.

It is further preferable that the organometallic complexes of embodiments of the present invention represented by General Formula (G1) and General Formula (G2) emit light hardly including blue light. Specifically, in an emission spectrum, the emission intensity of a visible light component of less than or equal to 495 nm is preferably less than or equal to 1/100 of the emission intensity of light having a peak wavelength.

Blue light refers to high-energy light (wavelength: 360 to 495 nm) in a range of visible light. Blue light reaches the retina without being absorbed by the film and the lens, and therefore causes damage to the retina and the optic nerve. In addition, exposure to blue light late at night causes disturbance of the circadian rhythm. The danger from blue light lies in the low visibility of light in that wavelength range to human eyes. Even when exposed to intense blue light, humans cannot be aware of it and therefore damage is easily accumulated.

Thus, by using the organometallic complex of one embodiment of the present invention that emits light hardly including blue light for a light-emitting device, the light-emitting device can suppress eye fatigue of a user and improve the quality of sleep. In view of the above, the half width of the emission spectrum of the organometallic complex of one embodiment of the present invention is preferably less than or equal to 120 nm so that a blue light component is suppressed.

As described above, by using the organometallic complex of one embodiment of the present invention, an unprecedented light-emitting device can be obtained. This is a light-emitting device for light therapy, which brings about a relaxation effect and an effect of improving the quality of sleep. That is, one embodiment of the present invention is a light-emitting device for light therapy, in which the peak wavelength of an emission spectrum is greater than or equal to 590 nm and less than or equal to 620 nm; the half width of the emission spectrum is greater than or equal to 70 nm and less than or equal to 120 nm, preferably greater than or equal to 80 nm and less than or equal to 120 nm, further preferably greater than or equal to 90 nm and less than or equal to 120 nm; and the emission intensity of a visible light component of less than or equal to 495 nm is less than or equal to 1/100 of the emission intensity of light having an emission spectrum peak wavelength. Here, the light-emitting device for light therapy preferably emits light of warm colors (e.g., orange) that is closer to natural light such as light of the setting sun, an incandescent lamp, a candle, and the like. That is, the light-emitting device for light therapy preferably has a CIE chromaticity x of greater than or equal to 0.58 and less than or equal to 0.63 and a CIE chromaticity y of greater than or equal to 0.37 and less than or equal to 0.42.

The organometallic complex of one embodiment of the present invention can provide, by itself, spectrum characteristics required for the light-emitting device for light therapy, so that the organometallic complex of one embodiment of the present invention is suitable for the light-emitting device for light therapy.

Next, specific structural formulae of the above organometallic complexes of embodiments of the present invention are shown below. Note that the present invention is not limited to these formulae.

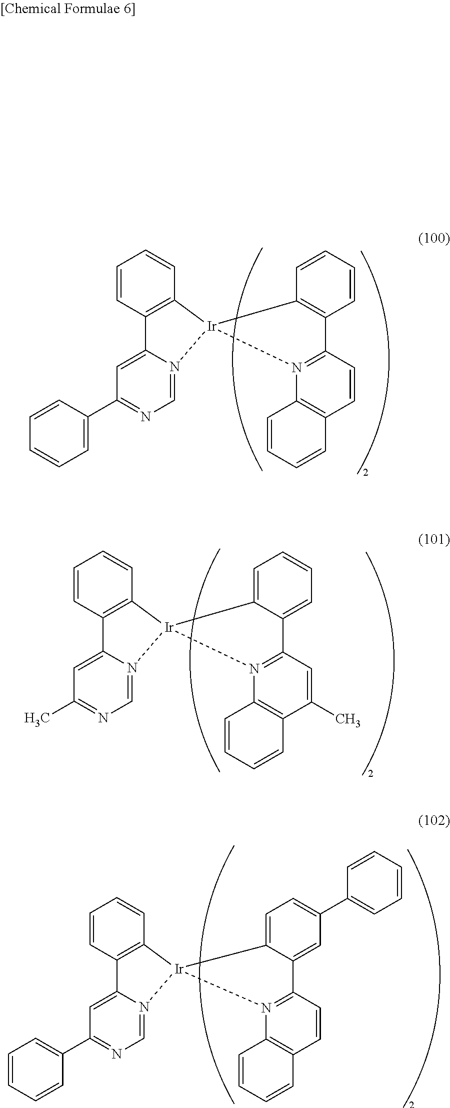

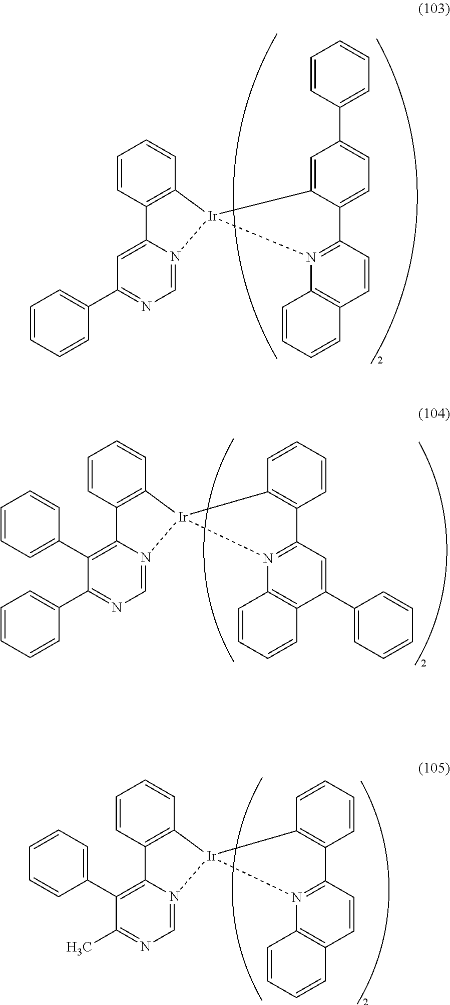

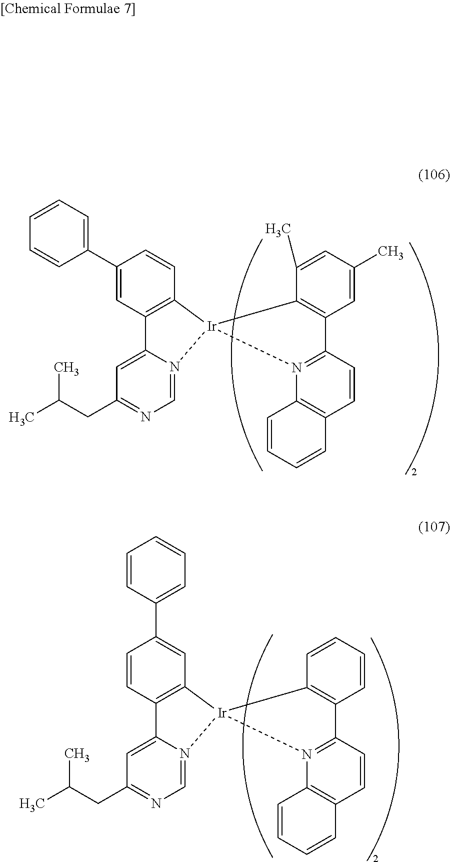

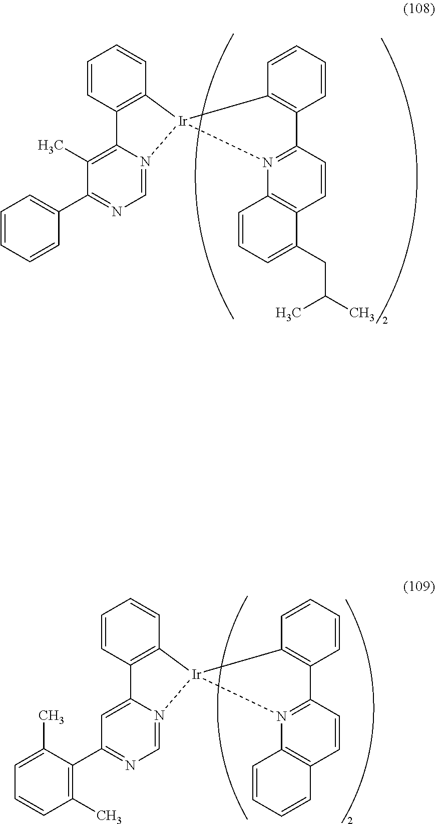

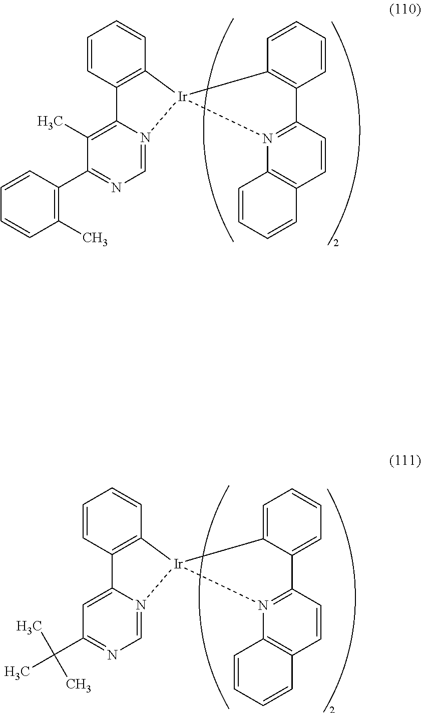

The organometallic complexes represented by the above structural formulae are novel substances capable of exhibiting phosphorescence. There can be geometrical isomers and stereoisomers of these substances depending on the type of the ligand. Each of the isomers is also an organometallic complex of one embodiment of the present invention.

Next, an example of a method for synthesizing the organometallic complex of one embodiment of the present invention represented by General Formula (G1) below will be described.

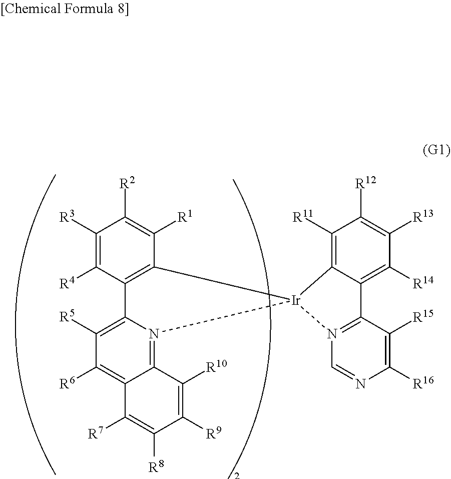

### <<Method for Synthesizing Organometallic Complex Represented by General Formula (G1)>>

As shown in Synthesis Scheme (a) below, a halogen-bridged dinuclear complex (P) and a pyrimidine compound represented by General Formula (GO) are reacted under an inert gas atmosphere, whereby the organometallic complex of one embodiment of the present invention represented by General Formula (G1) can be obtained.

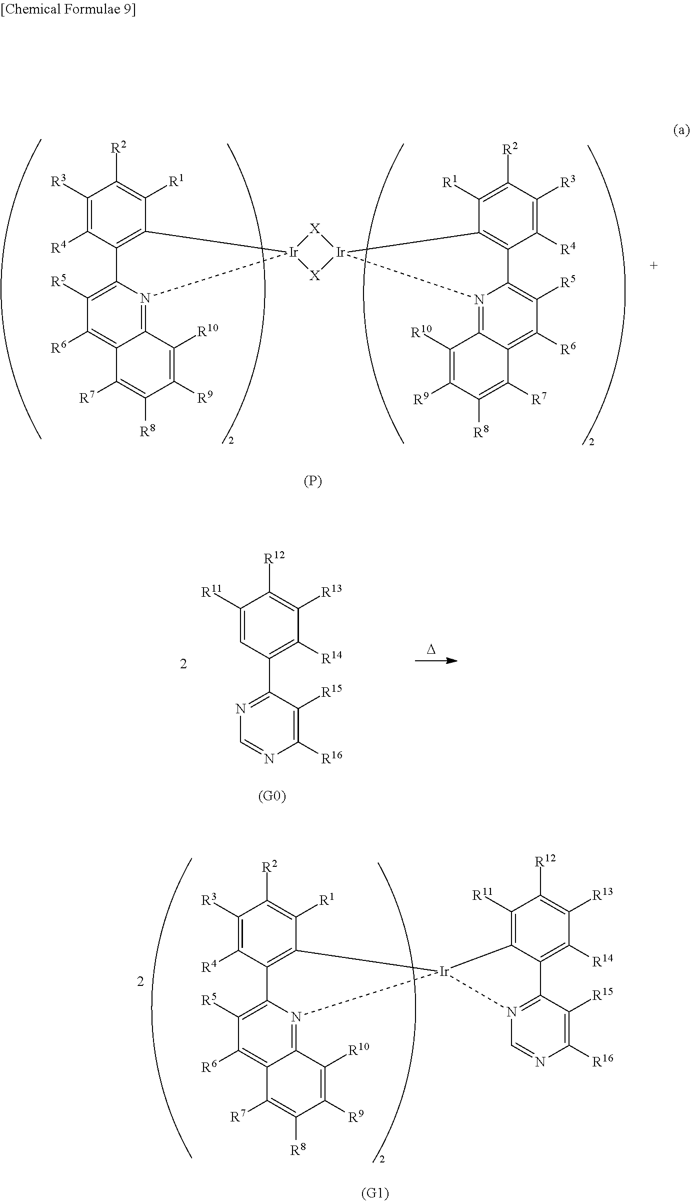

In Synthesis Scheme (a) above, X represents a halogen atom, and R¹ to R¹⁶ each independently represent any one of hydrogen, a substituted or unsubstituted alkyl group having 1 to 6 carbon atoms, a substituted or unsubstituted aryl group having 6 to 13 carbon atoms, and a substituted or unsubstituted heteroaryl group having 3 to 12 carbon atoms.

The organometallic complex (G1) that is obtained under Synthesis Scheme (a) above may be irradiated with light or heat to cause a reaction so that an isomer such as a geometrical isomer or an optical isomer is obtained; this isomer is also the organometallic complex represented by General Formula (G1). After the dinuclear complex (P) having a halogen-bridged structure is reacted with an antichlor such as silver trifluoromethanesulfonate to precipitate silver chloride, a supernatant liquid may be reacted with the pyrimidine compound represented by General Formula (G0) under an inert gas atmosphere.

In the present invention, a substituent is preferably introduced into R¹⁶ of the pyrimidine compound in order to obtain an ortho-metalated complex containing, as a ligand, the pyrimidine compound. As R¹⁶, it is particularly preferable to use any of a substituted or unsubstituted alkyl group having 1 to 6 carbon atoms, a substituted or unsubstituted aryl group having 6 to 13 carbon atoms, and a substituted or unsubstituted heteroaryl group having 3 to 12 carbon atoms. In that case, decomposition of the halogen-bridged dinuclear metal complex during the reaction represented by Synthesis Scheme (a) is more suppressed than in the case where hydrogen is used as R¹⁶, leading to a drastically high yield.

An example of the synthesis method of the organometallic complex of one embodiment of the present invention is described above; however, the present invention is not limited thereto and the organometallic complex may be synthesized by any other synthesis method.

The above-described organometallic complex of one embodiment of the present invention can exhibit phosphorescence and thus can be used as a light-emitting material and a light-emitting substance of a light-emitting device.

With the use of the organometallic complex of one embodiment of the present invention, a light-emitting device, a light-emitting apparatus, an electronic device, or a lighting device with high emission efficiency, a low driving voltage, and a long lifetime can be achieved.

Note that, in this embodiment, one embodiment of the present invention has been described. Other embodiments of the present invention are described in the other embodiments. However, one embodiment of the present invention is not limited thereto. In other words, since various embodiments of the invention are described in this embodiment and the other embodiments, embodiments of the present invention are not limited to particular embodiments. Although the example in which one embodiment of the present invention is used in a light-emitting device is described as an example, one embodiment of the present invention is not limited thereto. Depending on circumstances, one embodiment of the present invention may be applied to objects other than a light-emitting device.

The structures described in this embodiment can be used in an appropriate combination with the structures described in the other embodiments.

### Embodiment 2

In this embodiment, a light-emitting device using the organometallic complex described in Embodiment 1 will be described.

In the light-emitting device of one embodiment of the present invention, the half width of the electroluminescence spectrum is preferably greater than or equal to 70 nm, further preferably greater than or equal to 80 nm, still further preferably greater than or equal to 90 nm. Accordingly, the color-rendering properties of light emitted from the light-emitting device can be improved and light close to natural light can be obtained. The half width of the emission spectrum is preferably less than or equal to 120 nm. Accordingly, light in which blue light is suppressed can be obtained as described later. Therefore, in the organometallic complex having any of the structures represented by General Formula (G1) above and General Formula (G2) above, the half width of the emission spectrum is preferably greater than or equal to 70 nm and less than or equal to 120 nm, further preferably greater than or equal to 80 nm and less than or equal to 120 nm, still further preferably greater than or equal to 90 nm and less than or equal to 120 nm.

There is a problem in that as the electroluminescence spectrum of has a larger half width, the emission efficiency of a light-emitting device is likely to decrease. However, the use of the organometallic complex described in Embodiment 1 makes it possible to provide a light-emitting device having high emission efficiency even with a large half width of an electroluminescence spectrum.

In the light-emitting device of one embodiment of the present invention, it is further preferable that the peak wavelength of the electroluminescence spectrum be greater than or equal to 590 nm and less than or equal to 620 nm. Accordingly, a light-emitting device emitting light of warm colors that is closer to natural light such as light of the setting sun, an incandescent lamp, a candle, and the like can be obtained.

It is further preferable that the light-emitting device of one embodiment of the present invention emit light hardly including blue light. Specifically, in the electroluminescence spectrum of the light-emitting device of one embodiment of the present invention, the emission intensity of a visible light component of less than or equal to 495 nm is preferably less than or equal to 1/100 of the emission intensity of light having a peak wavelength.

The light-emitting device of one embodiment of the present invention is a light-emitting device for light therapy, which brings about a relaxation effect and an effect of improving the quality of sleep. That is, one embodiment of the present invention is a light-emitting device for light therapy, in which the peak wavelength of an emission spectrum is greater than or equal to 590 nm and less than or equal to 620 nm; the half width of the emission spectrum is greater than or equal to 70 nm and less than or equal to 120 nm, preferably greater than or equal to 80 nm and less than or equal to 120 nm, further preferably greater than or equal to 90 nm and less than or equal to 120 nm; and the emission intensity of a visible light component of less than or equal to 495 nm is less than or equal to 1/100 of the emission intensity of light having an emission spectrum peak wavelength. Here, the light-emitting device for light therapy preferably emits light of warm colors (e.g., orange) that is closer to natural light such as light of the setting sun, an incandescent lamp, a candle, and the like. That is, the light-emitting device for light therapy preferably has a CIE chromaticity x of greater than or equal to 0.58 and less than or equal to 0.63 and a CIE chromaticity y of greater than or equal to 0.37 and less than or equal to 0.42.

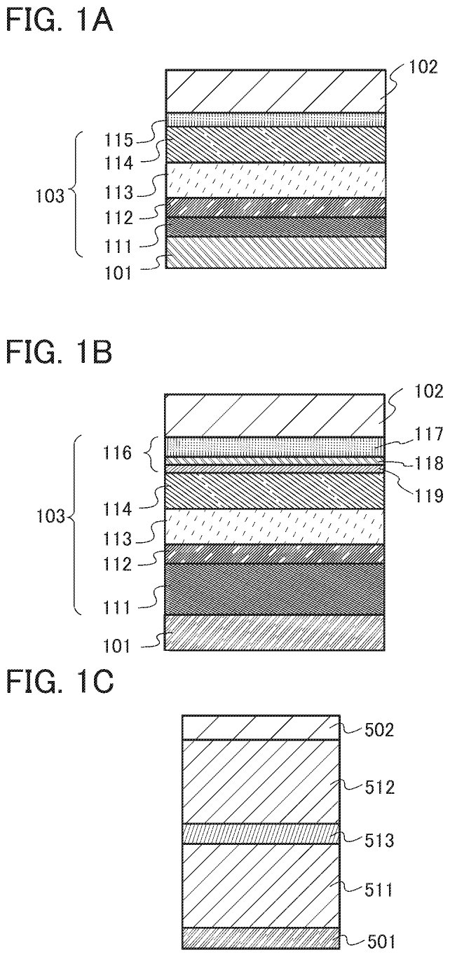

FIG. 1A is a diagram illustrating a light-emitting device of one embodiment of the present invention. The light-emitting device of one embodiment of the present invention includes a first electrode 101, a second electrode 102, and an EL layer 103. The EL layer 103 contains the organometallic complex described in Embodiment 1.

The EL layer 103 includes a light-emitting layer 113, and the light-emitting layer 113 contains a light-emitting material. The organometallic complex described in Embodiment 1 is preferably used as the light-emitting material. Note that the light-emitting layer 113 may contain other materials.

Note that although FIG. 1A illustrates an hole-injection layer 111, a hole-transport layer 112, an electron-transport layer 114, and an electron-injection layer 115 in the EL layer 103 in addition to the light-emitting layer 113, the structure of the light-emitting device is not limited thereto. Any of these layers may be omitted or a layer having another function may be included.

Next, examples of specific structures and materials of the aforementioned light-emitting device will be described. As described above, the light-emitting device of one embodiment of the present invention includes, between the pair of electrodes of the first electrode 101 and the second electrode 102, the EL layer 103 including a plurality of layers; the EL layer 103 includes the organometallic complex disclosed in Embodiment 1 in any of the layers.

The first electrode 101 is preferably formed using a metal, an alloy, or a conductive compound having a high work function (specifically, 4.0 eV or more), a mixture thereof, or the like. Specifically, for example, indium oxide-tin oxide (ITO: Indium Tin Oxide), indium oxide-tin oxide containing silicon or silicon oxide, indium oxide-zinc oxide, indium oxide containing tungsten oxide and zinc oxide (IWZO), and the like can be given. These conductive metal oxide films are usually deposited by a sputtering method but may also be formed by application of a sol-gel method or the like. An example of the formation method is a method in which indium oxide-zinc oxide is formed by a sputtering method using a target in which 1 to 20 wt % zinc oxide is added to indium oxide. Indium oxide containing tungsten oxide and zinc oxide can also be formed by a sputtering method using a target containing 0.5 to 5 wt % tungsten oxide and 0.1 to 1 wt % zinc oxide with respect to indium oxide. Alternatively, gold (Au), platinum (Pt), nickel (Ni), tungsten (W), chromium (Cr), molybdenum (Mo), iron (Fe), cobalt (Co), copper (Cu), palladium (Pd), a nitride of a metal material (such as titanium nitride), and the like can be given. Graphene can also be used. Note that when a composite material described later is used for a layer that is in contact with the first electrode 101 in the EL layer 103, an electrode material can be selected regardless of its work function.

Although the EL layer 103 preferably has a stacked-layer structure, there is no particular limitation on the stacked-layer structure, and various layer structures such as a hole-injection layer, a hole-transport layer, a light-emitting layer, an electron-transport layer, an electron-injection layer, a carrier-blocking layer, an exciton-blocking layer, and a charge-generation layer can be employed. In this embodiment, two kinds of structures are described: the structure including the electron-transport layer 114 and the electron-injection layer 115 in addition to the hole-injection layer 111, the hole-transport layer 112, and the light-emitting layer 113 as illustrated in FIG. 1A; and the structure including the electron-transport layer 114 and a charge-generation layer 116 in addition to the hole-injection layer 111, the hole-transport layer 112, and the light-emitting layer 113 as illustrated in FIG. 1B. Materials forming the layers are specifically described below.

The hole-injection layer 111 contains a substance having an acceptor property. Either an organic compound or an inorganic compound can be used as the substance having an acceptor property.

As the substance having an acceptor property, it is possible to use a compound having an electron-withdrawing group (a halogen group, a cyano group, or the like); for example, 7,7,8,8-tetracyano-2,3,5,6-tetrafluoroquinodimethane (abbreviation: F₄-TCNQ), chloranil, 2,3,6,7,10,11-hexacyano-1,4,5,8,9,12-hexaazatriphenyl ene (abbreviation: HAT-CN), 1,3,4,5,7,8-hexafluorotetracy ano-naphthoquinodim ethane (abbreviation: F6-TCNNQ), or 2-(7-dicyanomethylene-1,3,4,5,6,8,9,10-octafluoro-7H-pyren-2-ylidene)malononitrile can be used. A compound in which electron-withdrawing groups are bonded to a condensed aromatic ring having a plurality of heteroatoms, such as HAT-CN, is particularly preferable because it is thermally stable. A [3]radialene derivative having an electron-withdrawing group (in particular, a cyano group, a halogen group such as a fluoro group, or the like) has a very high electron-accepting property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris [2,3,4,5,6-pentafluorob enzeneacetonitrile]. As the substance having an acceptor property, transition metal oxide such as molybdenum oxide, vanadium oxide, ruthenium oxide, tungsten oxide, or manganese oxide can be used, other than the above-described organic compounds. Alternatively, the hole-injection layer 111 can be formed using phthalocyanine (abbreviation: H2Pc), a phthalocyanine-based complex compound such as copper phthalocyanine (CuPc), an aromatic amine compound such as 4,4′-bis[N-(4-diphenylaminophenyl)-N-phenylamino]biphenyl (abbreviation: DPAB) or N,N′-bis{4-[bis(3-methylphenyl)amino]phenyl}-N,N′-diphenyl-(1,1′-biphenyl)-4,4′-diamine (abbreviation: DNTPD), or a high molecule such as poly(3,4-ethylenedioxythiophene)/poly(styrenesulfonic acid) (PEDOT/PSS). The substance having an acceptor property can extract electrons from an adjacent hole-transport layer (or hole-transport material) by the application of an electric field.

Alternatively, a composite material in which a material having a hole-transport property contains the above-described substance having an acceptor property can be used for the hole-injection layer 111. By using a composite material in which a material having a hole-transport property contains a substance having an acceptor property, a material used to form an electrode can be selected regardless of its work function. In other words, besides a material having a high work function, a material having a low work function can also be used for the first electrode 101.

As the material having a hole-transport property used for the composite material, any of a variety of organic compounds such as aromatic amine compounds, carbazole derivatives, aromatic hydrocarbons, and high molecular compounds (e.g., oligomers, dendrimers, or polymers) can be used. Note that the material having a hole-transport property used for the composite material preferably has a hole mobility higher than or equal to 1×10⁻⁶ cm²/Vs. Organic compounds which can be used as the material having a hole-transport property in the composite material are specifically given below.

Examples of the aromatic amine compounds that can be used for the composite material include N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis{4-[bis(3-methylphenyl)amino]phenyl}-N,N′-diphenyl-(1,1′-biphenyl)-4,4′-diamine (abbreviation: DNTPD), and 1,3,5-tris[N-(4-diphenylaminophenyl)-N-phenylamino]benzene (abbreviation: DPA3B). Specific examples of the carbazole derivative include 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthracenyl)phenyl]-9H-carbazole (abbreviation: CzPA), and 1,4-bis[4-(N-carbazolyl)phenyl]-2,3,5,6-tetraphenylbenzene. Examples of the aromatic hydrocarbon include 2-tent-butyl-9,10-di(2-naphthyl)anthracene (abbreviation: t-BuDNA), 2-tent-butyl-9,10-di(1-naphthyl)anthracene, 9,10-bis(3,5-diphenylphenyl)anthracene (abbreviation: DPPA), 2-tent-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tent-butyl-9,10-bis [2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, and 2,5,8,11-tetra(tert-butyl)perylene. Other examples include pentacene and coronene. The aromatic hydrocarbon may have a vinyl skeleton. Examples of the aromatic hydrocarbon having a vinyl group include 4,4′-bis(2,2-diphenylvinyl)biphenyl (abbreviation: DPVBi) and 9,10-bis[4-(2,2-diphenylvinyl)phenyl]anthracene (abbreviation: DPVPA).

Other examples include high molecular compounds such as poly(N-vinylcarbazole) (abbreviation: PVK), poly(4-vinyltriphenylamine) (abbreviation: PVTPA), poly [N-(4-{N′-[4-(4-diphenylamino)phenyl]phenyl-N-phenylamino}phenyl)methacrylamide] (abbreviation: PTPDMA), and poly [N,N′-bis(4-butylphenyl)-N,N′-bis(phenyl)benzidine] (abbreviation: Poly-TPD).

The material having a hole-transport property used for the composite material further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that includes a naphthalene ring, or an aromatic monoamine in which a 9-fluorenyl group is bonded to nitrogen of the amine through an arylene group may be used. Note that these second organic compounds are preferably substances having an N,N-bis(4-biphenyl)amino group because a light-emitting device with a long lifetime can be manufactured. Specific examples of the above second organic compound include N-(4-biphenyl)-6,N-diphenylbenzo[b]naphtho[1,2-d]furan-8-amine (abbreviation: BnfABP),N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi(9H-fluoren)-2-amine (abbreviation: PCBNBSF), N,N-bis([1,1′-biphenyl]-4-yl)-9,9′-spirobi[9H-fluoren]-2-amine (abbreviation: BBASF), N,N-bis([1,1′-biphenyl]-4-yl)-9,9′-spirobi[9H-fluoren]-4-amine (abbreviation: BBASF(4)), N-(1,1′-biphenyl-2-yl)-N-(9,9-dimethyl-9H-fluoren-2-yl)-9,9′-spirobi(9H-fluoren)-4-amine (abbreviation: oFBiSF), N-(4-biphenyl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBilBP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(1,1′-biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

Note that it is further preferable that the material having a hole-transport property used for the composite material have a relatively deep HOMO level greater than or equal to −5.7 eV and less than or equal to −5.4 eV. The relatively deep HOMO level of the material having a hole-transport property used for the composite material makes it easy to inject holes into the hole-transport layer 112 and to obtain a light-emitting device with a long lifetime.

Note that mixing the above composite material with a fluoride of an alkali metal or an alkaline earth metal (the proportion of fluorine atoms in the layer is preferably greater than or equal to 20%) can lower the refractive index of the layer. This also enables a layer with a low refractive index to be formed in the EL layer 103, leading to higher external quantum efficiency of the light-emitting device.

The formation of the hole-injection layer 111 can improve the hole-injection property, whereby a light-emitting device having a low driving voltage can be obtained. The organic compound having an acceptor property is an easy-to-use material because evaporation is easy and its film can be easily deposited.

The hole-transport layer 112 contains a material having a hole-transport property. The material having a hole-transport property preferably has a hole mobility higher than or equal to 1×10⁻⁶ cm²/Vs. Examples of the material having a hole-transport property include a compound having an aromatic amine skeleton, such as 4,4′-bis[N-(1-naphthyl)-N-phenylamino]biphenyl (abbreviation: NPB), N,N′-bis(3-methylphenyl)-N,N′-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBilBP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]-9,9′-spirobi[9H-fluoren]-2-amine (abbreviation: PCBASF), a compound having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 3,3′-bis(9-phenyl-9H-carbazole) (abbreviation: PCCP), a compound having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV), and a compound having a furan skeleton, such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl }dibenzofuran (abbreviation: mmDBFFLBi-II). Among the above, the compound having an aromatic amine skeleton and the compound having a carbazole skeleton are preferable because these have favorable reliability, have high hole-transport properties, and contribute to a reduction in driving voltage. Note that any of the substances given as examples of the material having a hole-transport property that is used for the composite material for the hole-injection layer 111 can also be suitably used as the material included in the hole-transport layer 112.

The light-emitting layer 113 contains a light-emitting substance and a host material. The light-emitting layer 113 may additionally contain other materials. Furthermore, the light-emitting layer 113 may be a stack of two layers with different compositions. The organometallic complex described in Embodiment 1 can be used for the light-emitting layer 113.

The light-emitting substance may be a fluorescent substance, a phosphorescent substance, a substance exhibiting thermally activated delayed fluorescence (TADF), or another light-emitting substance.

Examples of a material that can be used as a fluorescent substance in the light-emitting layer 113 include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N-bis[4-(9-phenyl-9H-fluoren-9-yl)phenyl]pyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl)perylene (abbreviation: TBP), 4-(10-phenyl-9-anthryl)-4′-(9-phenyl-9H-carbazol-3-yl)triphenylamine (abbreviation: PCBAPA), N,N′-(2-tert-butyl anthracene-9,10-diyldi-4,1-phenylene)bis[N,N′,N′-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldib enzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-c]fluoranthene-3,10-diamine (abbreviation: p-mPhAFD), 2-{2-isopropyl-6-[2-(1,1,7,7-tetram ethyl-2,3,6,7-tetrahydro-1H, 5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H, 5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N′-(pyrene-1,6-diyl)bis[(6,N-diphenylbenzo[b]naphtho[1,2-d]furan)-8-amine] (abbreviation: 1,6BnfAPrn-03), 3,10-bis[N-(9-phenyl-9H-carbazol-2-yl)-N-phenylamino]naphtho[2,3-b; 6,7-b′]bisbenzofuran (abbreviation: 3,10PCA2Nbf(IV)-02), and 3,10-bis[N-(dibenzofuran-3-yl)-N-phenylamino]naphtho[2,3-b; 6,7-b′]bisbenzofuran (abbreviation: 3,10FrA2Nbf(IV)-02). In particular, a condensed aromatic diamine compound typified by a pyrenediamine compound such as 1,6FLPAPrn, 1,6mMemFLPAPrn, and 1,6BnfAPrn-03 is preferable because of its high hole-trapping property, high emission efficiency, and high reliability. Fluorescent substances other than those can also be used.

In the case where a phosphorescent substance is used as the light-emitting substance in the light-emitting layer 113, examples of a material that can be used include an organometallic iridium complex having a 4H-triazole skeleton, such as tris{2-[5-(2-methylphenyl)-4-(2,6-dimethylphenyl)-4H-1,2,4-triazol-3-yl-κN2]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), or tris[4-(3-biphenyl)-5-isopropyl-3-phenyl-4H-1,2,4-triazolato]iridium(III) (abbreviation: [Ir(iPrptz-3b)₃]); an organometallic iridium complex having a 1H-triazole skeleton, such as tris[3-methyl-1-(2-methylphenyl)-5-phenyl-1H-1,2,4-triazolato]iridium(III) (abbreviation: [Ir(Mptzl-mp)₃]) or tris(1-methyl-5-phenyl-3-propyl-1H-1,2,4-triazolato)iridium(III) (abbreviation:

[Ir(Prptzl-Me)₃]); an organometallic iridium complex having an imidazole skeleton, such as fac-tris[1-(2,6-diisopropylphenyl)-2-phenyl-1H-imidazole]iridium(III) (abbreviation: [Ir(iPrpmi)₃]) or tris[3-(2,6-dimethylphenyl)-7-methylimidazo[1,2-f]phenanthridinato]iridium(III) (abbreviation: [Ir(dmpimpt-Me)₃]); and an organometallic iridium complex in which a phenylpyridine derivative having an electron-withdrawing group is a ligand, such as bis[2-(4′,6′-difluorophenyl)pyridinato-N,C²′]iridium(III) tetrakis(1-pyrazolyl)borate (abbreviation: FIr6), bis[2-(4′,6′-difluorophenyl)pyridinato-N,C²′]iridium(III) picolinate (abbreviation: FIrpic), bis{2-[3′,5′-bis(trifluoromethyl)phenyl]pyridinato-N,C²′}iridium(III) picolinate (abbreviation: [Ir(CF₃ppy)₂(pic)]), or bis[2-(4′,6′-difluorophenyl)pyridinato-N,C^{2′}]iridium(III) acetylacetonate (abbreviation: FIr(acac)). These are compounds exhibiting blue phosphorescent light, and are compounds having an emission spectrum peak at 440 nm to 520 nm.

Examples also include an organometallic iridium complex having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetyl acetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), or (acetylacetonato)bis(4,6-diphenylpyrimidinato)iridium(III) (abbreviation: [Ir(dppm)₂(acac)]), an organometallic iridium complex having a pyrazine skeleton, such as (acetylacetonato)bis(3,5-dimethyl-2-phenylpyrazinato)iridium(III) (abbreviation: [Ir(mppr-Me)₂(acac)]) or (acetylacetonato)bis(5-isopropyl-3-methyl-2-phenylpyrazinato)iridium(III) (abbreviation: [Ir(mppr-iPr)₂(acac)]), an organometallic iridium complex having a pyridine skeleton, such as tri s(2-phenylpyridinato-N,C²′)iridium(III) (abbreviation: [Ir(ppy)₃]), bis(2-phenylpyridinato-N,C²′)iridium(III) acetyl acetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²′)iridium(III) (abbreviation: [Ir(pq)₃]), or bis(2-phenylquinolinato-N,C²′)ffidium(III) acetylacetonate (abbreviation: [Ir(pq)₂(acac)]), and a rare earth metal complex such as tris(acetylacetonato)(monophenanthroline)terbium(III) (abbreviation: [Tb(acac)₃(Phen)]). These are compounds that mainly exhibit green phosphorescent light, and have an emission spectrum peak at 500 nm to 600 nm. Note that an organometallic iridium complex having a pyrimidine skeleton is particularly preferable because of its distinctively high reliability and emission efficiency.

Examples also include an organometallic iridium complex having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato] (dipivaloylmethanato)iridium(III) (abbreviation: [Ir(5mdppm)₂(dpm)]), or bis[4,6-di(naphthalen-1-yl)pyrimidinato](dipivaloylmethanato)iridium(III) (abbreviation: [Ir(d1npm)₂(dpm)]), an organometallic iridium complex having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), or (acetylacetonato)bis[2,3-bis(4-fluorophenyl)quinoxalinato]iridium(III) (abbreviation: [Ir(Fdpq)₂(acac)]), an organometallic iridium complex having a pyridine skeleton, such as tris(1-phenylisoquinolinato-N,C²′)iridium(III) (abbreviation: [Ir(piq)_{3]}) or bis(1-phenylisoquinolinato-N,C²′)iridium(III) acetylacetonate (abbreviation: [Ir(piq)₂(acac)]), a platinum complex such as 2,3,7,8,12,13,17,18-octaethyl-21H,23H-porphyrin platinum(II) (abbreviation: PtOEP), and a rare earth metal complex such as tris(1,3-diphenyl-1,3-propanedionato)(monophenanthroline)europium(III) (abbreviation: [Eu(DBM)₃(Phen)]) or tris[1-(2-thenoyl)-3,3,3-trifluoroacetonato](monophenanthroline)europium(III) (abbreviation: [Eu(TTA)₃(Phen)]). These are compounds exhibiting red phosphorescent light, and have a spectrum peak at 600 nm to 700 nm. Furthermore, from the organometallic iridium complex having a pyrazine skeleton, red light emission with favorable chromaticity can be obtained.

Besides the above-described phosphorescent light-emitting compounds, other known phosphorescent substances may be selected and used.

As a TADF material, a fullerene, a derivative thereof, an acridine, a derivative thereof, an eosin derivative, or the like can be used. Other examples include a metal-containing porphyrin containing magnesium (Mg), zinc (Zn), cadmium (Cd), tin (Sn), platinum (Pt), indium (In), palladium (Pd), or the like. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

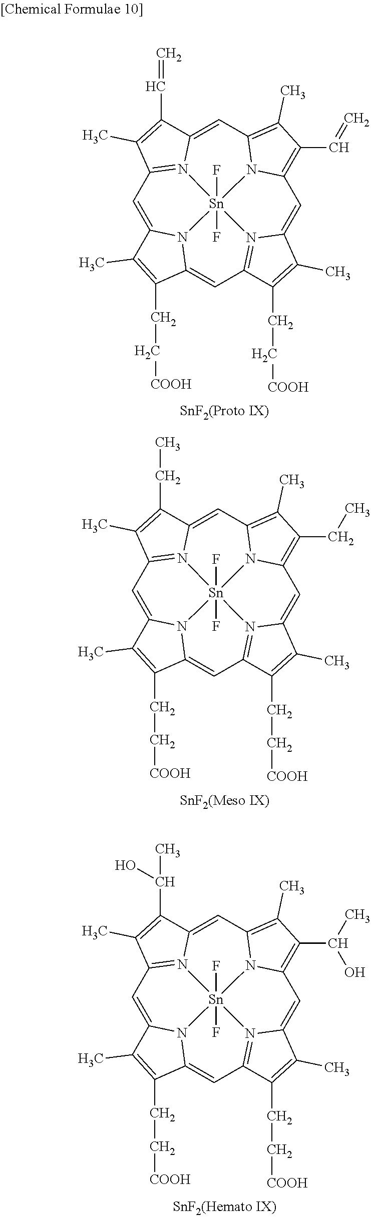

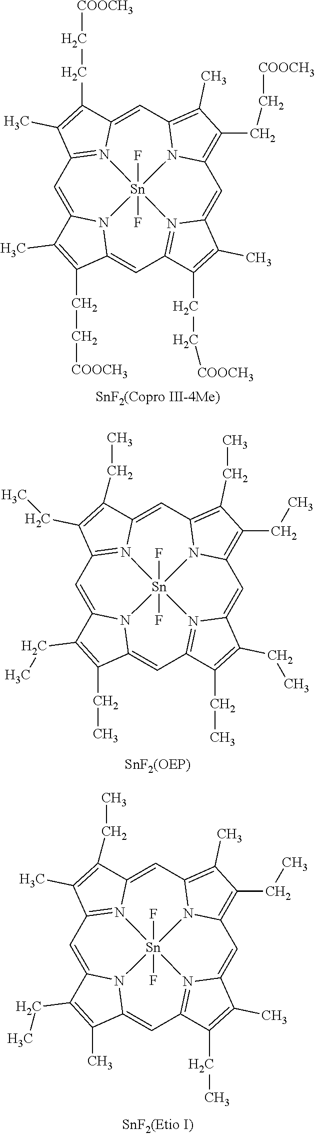

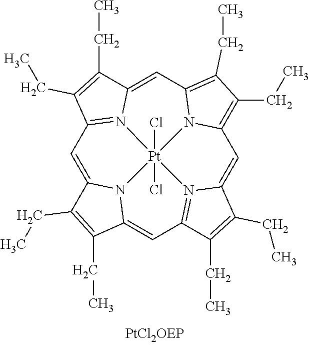

Alternatively, a heterocyclic compound having one or both of a π-electron rich heteroaromatic ring and a π-electron deficient heteroaromatic ring that is represented by the following structural formulae, such as 2-(biphenyl-4-yl)-4,6-bis(12-phenylindolo[2,3-α]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA) can be used. These heterocyclic compounds are preferable because of having both a high electron-transport property and a high hole-transport property owing to the π-electron rich heteroaromatic ring and the π-electron deficient heteroaromatic ring. Among skeletons having a π-electron deficient heteroaromatic ring, a pyridine skeleton, a diazine skeleton (a pyrimidine skeleton, a pyrazine skeleton, and a pyridazine skeleton), and a triazine skeleton are particularly preferable because of their stability and favorable reliability. In particular, a benzofuropyrimidine skeleton, a benzothienopyrimidine skeleton, a benzofuropyrazine skeleton, and a benzothienopyrazine skeleton are preferable because of their high acceptor property and favorable reliability. Among skeletons having a π-electron rich heteroaromatic ring, an acridine skeleton, a phenoxazine skeleton, a phenothiazine skeleton, a furan skeleton, a thiophene skeleton, and a pyrrole skeleton have stability and favorable reliability; therefore, at least one of these skeletons is preferably included. Note that a dibenzofuran skeleton and a dibenzothiophene skeleton are preferable as the furan skeleton and the thiophene skeleton, respectively. As the pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which a π-electron rich heteroaromatic ring and a π-electron deficient heteroaromatic ring are directly bonded to each other is particularly preferable because the electron-donating property of the π-electron rich heteroaromatic ring and the electron-accepting property of the π-electron deficient heteroaromatic ring are both increased and the energy difference between the S1 level and the T1 level becomes small, and thus thermally activated delayed fluorescence can be obtained efficiently. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a boron-containing skeleton such as phenylborane or boranthrene, an aromatic ring or a heteroaromatic ring having a nitrile group or a cyano group, such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

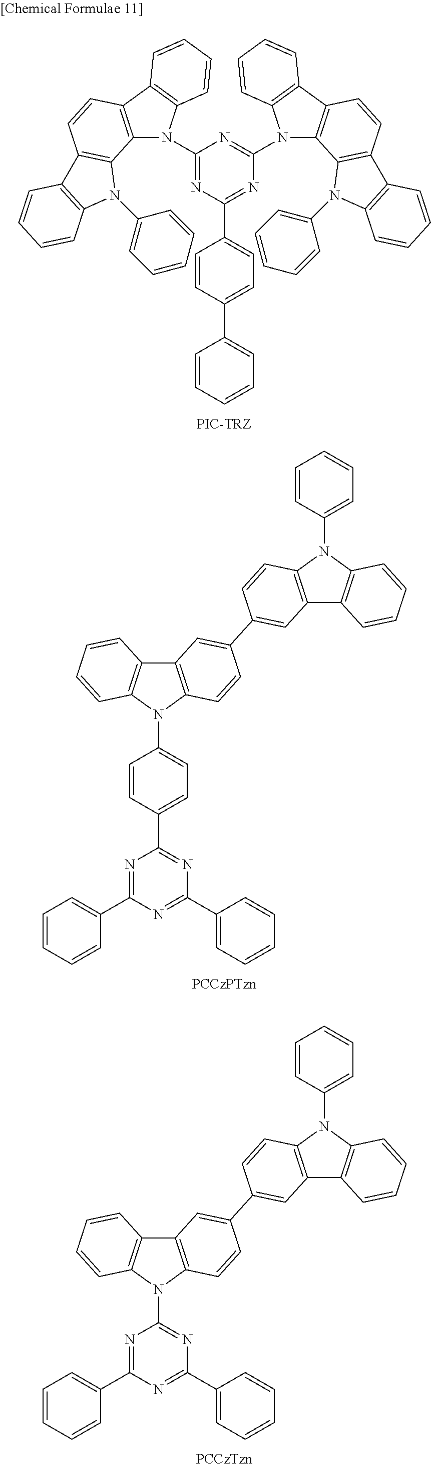 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

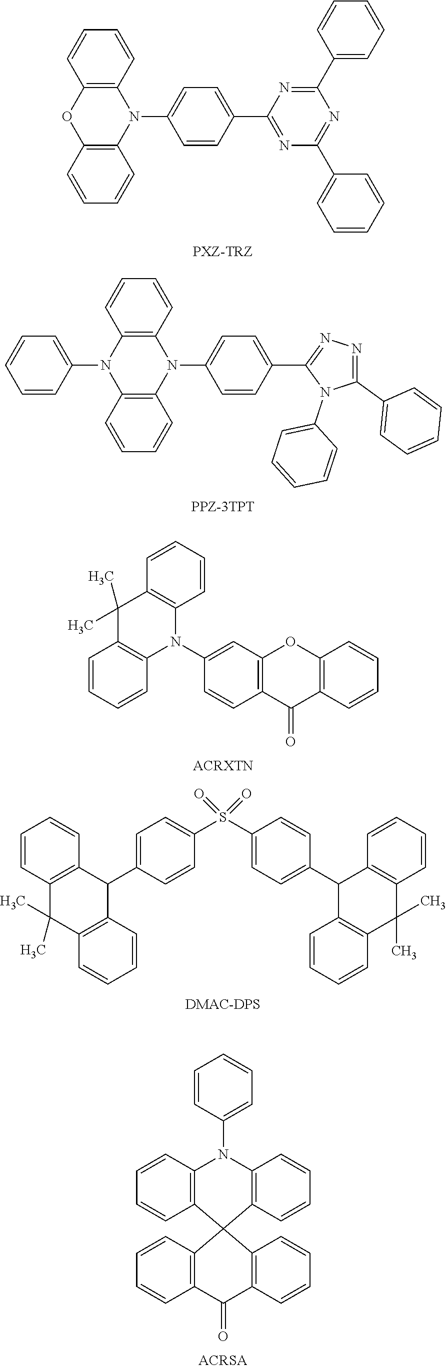 [SMILES: c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1 ; CC1(C)c2ccccc2N(c2ccc3c(=O)c4ccccc4oc3c2)c2ccccc21 ; CC1(C)c2ccccc2C(c2ccc(S(=O)(=O)c3ccc(C4c5ccccc5C(C)(C)c5ccccc54)cc3)cc2)c2ccccc21 ; O=C1c2ccccc2C2(c3ccccc31)c1ccccc1N(c1ccccc1)c1ccccc12]

Note that the TADF material is a material that has a small difference between the S1 level and the T1 level and has a function of converting triplet excitation energy into singlet excitation energy by reverse intersystem crossing. Thus, it is possible to upconvert triplet excitation energy into singlet excitation energy (reverse intersystem crossing) using a little thermal energy and to efficiently generate a singlet excited state. In addition, the triplet excitation energy can be converted into light emission.

An exciplex whose excited state is formed of two kinds of substances has an extremely small difference between the S1 level and the T1 level and functions as a TADF material capable of converting triplet excitation energy into singlet excitation energy.

Note that a phosphorescent spectrum observed at low temperatures (e.g., 77 K to 10 K) is used for an index of the T1 level. When the level of energy with a wavelength of the line obtained by extrapolating a tangent to the fluorescent spectrum at a tail on the short wavelength side is the Si level and the level of energy with a wavelength of the line obtained by extrapolating a tangent to the phosphorescent spectrum at a tail on the short wavelength side is the T1 level, the difference between S1 and T1 of the TADF material is preferably less than or equal to 0.3 eV, further preferably less than or equal to 0.2 eV.

When the TADF material is used as the light-emitting substance, the Si level of the host material is preferably higher than the Si level of the TADF material. In addition, the T1 level of the host material is preferably higher than the T1 level of the TADF material.

As the host material in the light-emitting layer, various carrier-transport materials such as a material having an electron-transport property, a material having a hole-transport property, and the TADF material can be used.

The material having a hole-transport property is preferably an organic compound having an amine skeleton or a π-electron rich heteroaromatic ring skeleton. Examples include a compound having an aromatic amine skeleton, such as 4,4′-bis[N-(1-naphthyl)-N-phenylamino]biphenyl (abbreviation: NPB), N,N′-bis(3-methylphenyl)-N,N′-diphenyl[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBilBP), 4-(1-naphthyl)-4′-(9-phenyl-9H-carbazol-3-yl)-triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]-9,9′-spirobi [9H-fluoren]-2-amine (abbreviation: PCBASF), a compound having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 3,3′-bis(9-phenyl-9H-carbazole) (abbreviation: PCCP), a compound having a thiophene skeleton, such as 4,4′,4″-(benzene-1,3,5-triyl)tri(dibenzothiophene) (abbreviation: DB T3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV), and a compound having a furan skeleton, such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above, the compound having an aromatic amine skeleton and the compound having a carbazole skeleton are preferable because these have favorable reliability, have high hole-transport properties, and contribute to a reduction in driving voltage.

As the material having an electron-transport property, for example, a metal complex such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ), or an organic compound having a π-electron deficient heteroaromatic ring skeleton is preferable. Examples of the organic compound having a π-electron deficient heteroaromatic ring skeleton include a heterocyclic compound having a polyazole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), or 2[3-(dibenzothiophen-4-yl)phenyl]-1-phenyl-1H-benzimidazole (abbreviation: mDBTBIm-II); a heterocyclic compound having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), or 2,8-bis[3-(dibenzothiophen-4-yl)phenyl]benzo[h]quinazoline (abbreviation: 4,8mDBtP2B qn); and a heterocyclic compound having a pyridine skeleton, such as 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB). Among the above materials, the heterocyclic compound having a diazine skeleton or the heterocyclic compound having a pyridine skeleton have high reliability and thus are preferable. In particular, the heterocyclic compound having a diazine (pyrimidine, pyrazine, or the like) skeleton has a high electron-transport property and contributes to a reduction in driving voltage.

As the TADF material that can be used as the host material, the above-mentioned materials given as TADF materials can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. At this time, the TADF material functions as an energy donor, and the light-emitting substance functions as an energy acceptor.

This is very effective in the case where the light-emitting substance is a fluorescent substance. In this case, the S1 level of the TADF material is preferably higher than the S1 level of the fluorescent substance in order to achieve high emission efficiency. Furthermore, the T1 level of the TADF material is preferably higher than the S1 level of the fluorescent substance. Therefore, the T1 level of the TADF material is preferably higher than the T1 level of the fluorescent substance.

It is also preferable to use a TADF material that exhibits light emission overlapping with the wavelength of a lowest-energy-side absorption band of the fluorescent substance. This enables smooth transfer of excitation energy from the TADF material to the fluorescent substance and accordingly enables efficient light emission, which is preferable.

In order that singlet excitation energy is efficiently generated from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton that causes light emission) of the fluorescent substance. As the protective group, a substituent having no π bond and saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituent having no n bond has a poor carrier-transport property; thus, the TADF material and the luminophore of the fluorescent substance can be made away from each other with little influence on carrier transportation or carrier recombination. Here, the luminophore refers to an atomic group (skeleton) that causes light emission in a fluorescent substance. The luminophore is preferably a skeleton having a n bond, further preferably includes an aromatic ring, and still further preferably includes a condensed aromatic ring or a condensed heteroaromatic ring. Examples of the condensed aromatic ring and the condensed heteroaromatic ring include a phenanthrene skeleton, a stilbene skeleton, an acridone skeleton, a phenoxazine skeleton, and a phenothiazine skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the light-emitting substance, a material having an anthracene skeleton is suitable for the host material. The use of a substance having an anthracene skeleton as a host material for a fluorescent substance makes it possible to achieve a light-emitting layer with a favorable emission efficiency and durability. As the substance having an anthracene skeleton that is used as the host material, a substance having a diphenylanthracene skeleton, in particular, a substance having a 9,10-diphenylanthracene skeleton, is preferable because of its chemical stability. The host material preferably has a carbazole skeleton because the hole-injection and hole-transport properties are improved; further preferably, the host material has a benzocarbazole skeleton in which a benzene ring is further condensed to carbazole because the HOMO level thereof is shallower than that of carbazole by approximately 0.1 eV and thus holes enter the host material easily. In particular, the host material having a dibenzocarbazole skeleton is preferable because its HOMO level is shallower than that of carbazole by approximately 0.1 eV so that holes enter the host material easily, the hole-transport property is improved, and the heat resistance is increased. Accordingly, a substance that has both a 9,10-diphenylanthracene skeleton and a carbazole skeleton (or a benzocarbazole skeleton or a dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)-phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]-benzo[b]naphtho[1,2-d]furan (abbreviation: 2mBnfPPA), 9-phenyl-10-{4-(9-phenyl-9H-fluoren-9-yl)biphenyl-4′-yl}anthracene (abbreviation: FLPPA), and 9-(1-naphthyl)-10-[4-(2-naphthyl)phenyl]anthracene (abbreviation: αN-βNPAnth). In particular, CzPA, cgDBCzPA, 2mBnfPPA, and PCzPA are preferably selected because they exhibit highly favorable characteristics.

Note that a host material may be a material of a mixture of a plurality of kinds of substances; in the case of using a mixed host material, it is preferable to mix a material having an electron-transport property with a material having a hole-transport property. When the material having an electron-transport property is mixed with the material having a hole-transport property, the transport property of the light-emitting layer 113 can be easily adjusted and a recombination region can be easily controlled. The weight ratio of the content of the material having a hole-transport property to the content of the material having an electron-transport property may be 1:19 to 19:1.

Note that a phosphorescent substance can be used as part of the mixed material. When a fluorescent substance is used as the light-emitting substance, a phosphorescent substance can be used as an energy donor for supplying excitation energy to the fluorescent substance.

An exciplex may be formed by these mixed materials. A combination is preferably selected so as to form an exciplex that exhibits light emission overlapping with the wavelength of a lowest-energy-side absorption band of a light-emitting substance, because energy can be transferred smoothly and light emission can be efficiently obtained. The use of the structure is preferable because the driving voltage is also reduced.

Note that at least one of the materials forming an exciplex may be a phosphorescent substance. In this case, triplet excitation energy can be efficiently converted into singlet excitation energy by reverse intersystem crossing.

A combination of a material having an electron-transport property and a material having a hole-transport property whose HOMO level is higher than or equal to the HOMO level of the material having an electron-transport property is preferable for forming an exciplex efficiently. In addition, the LUMO level of the material having a hole-transport property is preferably higher than or equal to the LUMO level of the material having an electron-transport property. Note that the LUMO levels and the HOMO levels of the materials can be derived from the electrochemical characteristics (the reduction potentials and the oxidation potentials) of the materials that are measured by cyclic voltammetry (CV).

Note that the formation of an exciplex can be confirmed by a phenomenon in which the emission spectrum of the mixed film in which the material having a hole-transport property and the material having an electron-transport property are mixed is shifted to the longer wavelength side than the emission spectrum of each of the materials (or has another peak on the longer wavelength side), observed by comparison of the emission spectrum of the material having a hole-transport property, the emission spectrum of the material having an electron-transport property, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than the transient PL lifetime of each of the materials, observed by comparison of the transient PL of the material having a hole-transport property, the transient PL of the material having an electron-transport property, and the transient PL of the mixed film of these materials. The transient PL can be rephrased as transient electroluminescence (EL). That is, the formation of an exciplex can also be confirmed by a difference in transient response observed by comparison of the transient EL of the material having a hole-transport property, the transient EL of the material having an electron-transport property, and the transient EL of the mixed film of these materials.

The electron-transport layer 114 is a layer containing a substance having an electron-transport property. As the substance having an electron-transport property, it is possible to use any of the above-listed substances having electron-transport properties that can be used as the host material.

The electron mobility of the electron-transport layer 114 in the case where the square root of the electric field strength [V/cm] is 600 is preferably higher than or equal to 1×10⁻⁷ cm²/Vs and lower than or equal to 5×10⁻⁵ cm²/Vs. Lowering the electron-transport property of the electron-transport layer 114 enables control of the amount of electrons injected into the light-emitting layer and can prevent the light-emitting layer from having excess electrons. The electron-transport layer 114 preferably contains a material having an electron-transport property and any of an alkali metal itself, an alkali earth metal itself, a compound thereof, and a complex thereof. It is particularly preferable that this structure be employed when the hole-injection layer is formed using a composite material that includes a material having a hole-transport property with a relatively deep HOMO level of −5.7 eV or higher and −5.4 eV or lower, in which case a long lifetime can be achieved. Here, the material having an electron-transport property preferably has a HOMO level of higher than or equal to −6.0 eV. The material having an electron-transport property is preferably an organic compound having an anthracene skeleton and is further preferably an organic compound having both an anthracene skeleton and a heterocyclic skeleton. The heterocyclic skeleton is preferably a nitrogen-containing five-membered ring skeleton or a nitrogen-containing six-membered ring skeleton, and particularly preferably a nitrogen-containing five-membered ring skeleton or a nitrogen-containing six-membered ring skeleton including two heteroatoms in the ring, such as a pyrazole ring, an imidazole ring, an oxazole ring, a thiazole ring, a pyrazine ring, a pyrimidine ring, or a pyridazine ring. In addition, it is preferable that the alkali metal itself, the alkali earth metal itself, the compound thereof, and the complex thereof have an 8-hydroxyquinolinato structure. Specific examples include 8-hydroxyquinolinato-lithium (abbreviation: Liq) and 8-hydroxyquinolinato-sodium (abbreviation: Naq). In particular, a complex of a monovalent metal ion, especially a complex of lithium is preferable, and Liq is further preferable. Note that in the case where the 8-hydroxyquinolinato structure is included, a methyl-substituted product (e.g., a 2-methyl-substituted product or a 5-methyl-substituted product) thereof or the like can also be used. There is preferably a difference in the concentration (including 0) of the alkali metal itself, the alkali earth metal itself, the compound thereof, or the complex thereof in the electron-transport layer in the thickness direction.

As the electron-injection layer 115, a layer containing an alkali metal, an alkaline earth metal, or a compound thereof, such as lithium fluoride (LiF), cesium fluoride (CsF), calcium fluoride (CaF2), or 8-hydroxyquinolinato-lithium (abbreviation: Liq), may be provided between the electron-transport layer 114 and the second electrode 102. An electride or a layer that is formed using a substance having an electron-transport property and that includes an alkali metal, an alkaline earth metal, or a compound thereof can be used as the electron-injection layer 115. Examples of the electride include a substance in which electrons are added at high concentration to a mixed oxide of calcium and aluminum.

Note that as the electron-injection layer 115, it is possible to use a layer that contains a substance having an electron-transport property (preferably an organic compound having a bipyridine skeleton) and contains a fluoride of the alkali metal or the alkaline earth metal at a concentration higher than or equal to that at which the electron-injection layer 115 becomes in a microcrystalline state (50 wt % or higher). Since the layer has a low refractive index, a light-emitting device having more favorable external quantum efficiency can be provided.

Instead of the electron-injection layer 115, the charge-generation layer 116 may be provided (FIG. 1B). The charge-generation layer 116 refers to a layer capable of injecting holes into a layer in contact therewith on the cathode side and injecting electrons into a layer in contact therewith on the anode side when supplied with a potential. The charge-generation layer 116 includes at least a P-type layer 117. The P-type layer 117 is preferably formed using the composite materials given above as the material that can form the hole-injection layer 111. The P-type layer 117 may be formed by stacking a film containing the above acceptor material as a material included in the composite material and a film containing the above hole-transport material. When a potential is applied to the P-type layer 117, electrons are injected into the electron-transport layer 114 and holes are injected into the second electrode 102 that is a cathode; thus, the light-emitting device operates.

Note that one or both of an electron-relay layer 118 and an electron-injection buffer layer 119 are preferably provided in the charge-generation layer 116 in addition to the P-type layer 117.

The electron-relay layer 118 contains at least a substance having an electron-transport property and has a function of preventing an interaction between the electron-injection buffer layer 119 and the P-type layer 117 to transfer electrons smoothly. The LUMO level of the substance having an electron-transport property contained in the electron-relay layer 118 is preferably between the LUMO level of an acceptor substance in the P-type layer 117 and the LUMO level of a substance contained in a layer of the electron-transport layer 114 in contact with the charge-generation layer 116. A specific energy level of the LUMO level of the substance having an electron-transport property used for the electron-relay layer 118 may be higher than or equal to −5.0 eV, preferably higher than or equal to −5.0 eV and lower than or equal to −3.0 eV. Note that as the substance having an electron-transport property used for the electron-relay layer 118, a phthalocyanine-based material or a metal complex having a metal-oxygen bond and an aromatic ligand is preferably used.

For the electron-injection buffer layer 119, a substance having a high electron-injection property, such as an alkali metal, an alkaline earth metal, a rare earth metal, or a compound thereof (an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)), can be used.

In the case where the electron-injection buffer layer 119 is formed so as to contain the substance having an electron-transport property and a donor substance, an organic compound such as tetrathianaphthacene (abbreviation: TTN), nickelocene, or decamethylnickelocene can be used as the donor substance, as well as an alkali metal, an alkaline earth metal, a rare earth metal, a compound thereof (an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)). Note that as the substance having an electron-transport property, a material similar to the above-described material forming the electron-transport layer 114 can be used for the formation.

As a substance forming the second electrode 102, a metal, an alloy, an electrically conductive compound, or a mixture thereof having a low work function (specifically, 3.8 eV or less) or the like can be used. As specific examples of such a cathode material, elements belonging to Group 1 or Group 2 of the periodic table, such as alkali metals, e.g., lithium (Li) and cesium (Cs), magnesium (Mg), calcium (Ca), and strontium (Sr), alloys containing these (MgAg and AlLi), rare earth metals such as europium (Eu) and ytterbium (Yb), alloys containing these rare earth metals, and the like can be given. However, when the electron-injection layer is provided between the second electrode 102 and the electron-transport layer, for the second electrode 102, a variety of conductive materials such as Al, Ag, ITO, and indium oxide-tin oxide containing silicon or silicon oxide can be used regardless of their work functions. Films of these conductive materials can be deposited by a dry process such as a vacuum evaporation method or a sputtering method, an ink-jet method, a spin coating method, or the like. Alternatively, the films may be formed by a wet process using a sol-gel method or a wet process using a paste of a metal material.

Various methods can be used as a method for forming the EL layer 103 regardless of whether it is a dry process or a wet process. For example, a vacuum evaporation method, a gravure printing method, an offset printing method, a screen printing method, an ink-jet method, a spin coating method, or the like may be used.

Different deposition methods may be used to form the electrodes or the layers described above.

The structure of the layers provided between the first electrode 101 and the second electrode 102 is not limited to the above structure. However, a structure is preferable in which a light-emitting region where holes and electrons recombine is provided at a position away from the first electrode 101 and the second electrode 102 so as to prevent quenching caused by the proximity of the light-emitting region and a metal used for electrodes and carrier-injection layers.

Furthermore, in order to inhibit energy transfer from an exciton generated in the light-emitting layer, it is preferable to form the hole-transport layer or the electron-transport layer that is in contact with the light-emitting layer 113, particularly a carrier-transport layer closer to the recombination region in the light-emitting layer 113, using the light-emitting material of the light-emitting layer or a substance having a wider band gap than the light-emitting material included in the light-emitting layer.

Next, an embodiment of a light-emitting device with a structure where a plurality of light-emitting units are stacked (also referred to as a stacked-type element or a tandem element) will be described with reference to FIG. 1C. This light-emitting device is a light-emitting device including a plurality of light-emitting units between an anode and a cathode. One light-emitting unit has substantially the same structure as the EL layer 103, which is illustrated in FIG. 1A. In other words, the light-emitting device illustrated in FIG. 1C can be called a light-emitting device including a plurality of light-emitting units, and the light-emitting device illustrated in FIG. 1A or FIG. 1B can be called a light-emitting device including one light-emitting unit. Note that the organometallic complex described in Embodiment 1 is included in at least any of the plurality of light-emitting units.

In FIG. 1C, a first light-emitting unit 511 and a second light-emitting unit 512 are stacked between an anode 501 and a cathode 502, and a charge-generation layer 513 is provided between the first light-emitting unit 511 and the second light-emitting unit 512. The anode 501 and the cathode 502 correspond, respectively, to the first electrode 101 and the second electrode 102 in FIG. 1A, and the same substance as what is given in the description for FIG. 1A can be used. Furthermore, the first light-emitting unit 511 and the second light-emitting unit 512 may have the same structure or different structures.

The charge-generation layer 513 has a function of injecting electrons into one of the light-emitting units and injecting holes into the other of the light-emitting units when a voltage is applied to the anode 501 and the cathode 502. That is, in FIG. 1C, any layer can be used as the charge-generation layer 513 as long as the layer injects electrons into the first light-emitting unit 511 and injects holes into the second light-emitting unit 512 in the case where a voltage is applied such that the potential of the anode is higher than the potential of the cathode.

The charge-generation layer 513 is preferably formed with a structure similar to that of the charge-generation layer 116 described with reference to FIG. 1B. A composite material of an organic compound and a metal oxide has an excellent carrier-injection property and an excellent carrier-transport property; thus, low-voltage driving and low-current driving can be achieved. Note that in the case where the anode-side surface of a light-emitting unit is in contact with the charge-generation layer 513, the charge-generation layer 513 can also serve as a hole-injection layer of the light-emitting unit; therefore, a hole-injection layer is not necessarily provided in the light-emitting unit.

In the case where the electron-injection buffer layer 119 is provided in the charge-generation layer 513, the electron-injection buffer layer 119 serves as an electron-injection layer in the light-emitting unit on the anode side; therefore, an electron-injection layer is not necessarily formed in the light-emitting unit on the anode side.

The light-emitting device having two light-emitting units is described with reference to FIG. 1C; however, the same can also be applied to a light-emitting device in which three or more light-emitting units are stacked. With a plurality of light-emitting units partitioned by the charge-generation layer 513 between a pair of electrodes as in the light-emitting device of this embodiment, it is possible to provide a long-life device that can emit light with high luminance at a low current density. Moreover, a light-emitting apparatus that can be driven at a low voltage and has low power consumption can be achieved.

Furthermore, when emission colors of the light-emitting units are different, light emission of a desired color can be obtained from the light-emitting device as a whole. For example, in a light-emitting device having two light-emitting units, emission colors of red and green are obtained in the first light-emitting unit and an emission color of blue is obtained in the second light-emitting unit, whereby a light-emitting device that emits white light as the whole light-emitting device can be obtained.

The EL layer 103, the first light-emitting unit 511, the second light-emitting unit 512, the layers such as the charge-generation layer, and the electrodes that are described above can be formed by a method such as an evaporation method (including a vacuum evaporation method), a droplet discharge method (also referred to as an ink-jet method), a coating method, or a gravure printing method. Those may include a low molecular material, a middle molecular material (including an oligomer and a dendrimer), or a high molecular material.

### Embodiment 3

In this embodiment, a light-emitting apparatus using the light-emitting device described in Embodiment 2 will be described.

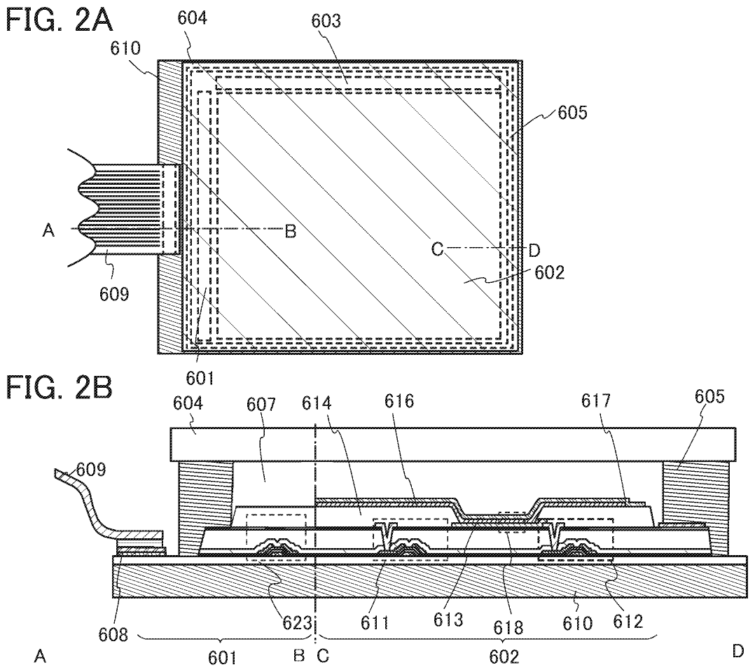

In this embodiment, a light-emitting apparatus fabricated using the light-emitting device described in Embodiment 2 will be described with reference to FIG. 2. Note that FIG. 2A is a top view illustrating the light-emitting apparatus, and FIG. 2B is a cross-sectional view taken along A-B and C-D in FIG. 2A. This light-emitting apparatus includes a driver circuit portion (source line driver circuit) 601, a pixel portion 602, and a driver circuit portion (gate line driver circuit) 603, which are for controlling light emission of a light-emitting device and are illustrated with dotted lines. Furthermore, 604 denotes a sealing substrate, 605 denotes a sealant, and the inside surrounded by the sealant 605 is a space 607.

Note that a lead wiring 608 is a wiring for transmitting signals to be input to the source line driver circuit 601 and the gate line driver circuit 603 and receives a video signal, a clock signal, a start signal, a reset signal, and the like from an FPC (flexible printed circuit) 609 serving as an external input terminal. Although only the FPC 609 is illustrated here, a printed wiring board (PWB) may be attached to this FPC 609. The light-emitting apparatus in this specification includes not only the light-emitting apparatus itself but also the apparatus provided with the FPC or the PWB.

Next, a cross-sectional structure will be described with reference to FIG. 2B. The driver circuit portion and the pixel portion are formed over an element substrate 610. Here, the source line driver circuit 601, which is the driver circuit portion, and one pixel of the pixel portion 602 are illustrated.

The element substrate 610 may be fabricated using a substrate containing glass, quartz, an organic resin, a metal, an alloy, a semiconductor, or the like, or a plastic substrate formed of FRP (Fiber Reinforced Plastic), PVF (polyvinyl fluoride), polyester, an acrylic resin, or the like.

There is no particular limitation on the structure of transistors used in pixels or driver circuits. For example, inverted staggered transistors may be used, or staggered transistors may be used. Furthermore, top-gate transistors or bottom-gate transistors may be used. There is no particular limitation on a semiconductor material used for the transistors, and for example, silicon, germanium, silicon carbide, gallium nitride, or the like can be used. Alternatively, an oxide semiconductor containing at least one of indium, gallium, and zinc, such as In—Ga—Zn-based metal oxide, may be used.

There is no particular limitation on the crystallinity of a semiconductor material used for the transistors, and either an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case deterioration of the transistor characteristics can be suppressed.

Here, an oxide semiconductor is preferably used for semiconductor devices such as the transistors provided in the pixels or driver circuits and transistors used for touch sensors described later, and the like. In particular, an oxide semiconductor having a wider band gap than silicon is preferably used. The use of an oxide semiconductor having a wider band gap than silicon can reduce the off-state current of the transistors.

The oxide semiconductor preferably contains at least indium (In) or zinc (Zn). Further preferably, the oxide semiconductor contains an oxide represented by an In—M—Zn-based oxide (M represents a metal such as Al, Ti, Ga, Ge, Y, Zr, Sn, La, Ce, or Hf).

As a semiconductor layer, it is particularly preferable to use an oxide semiconductor film including a plurality of crystal parts whose c-axes are aligned perpendicular to a surface on which the semiconductor layer is formed or the top surface of the semiconductor layer and in which the adjacent crystal parts have no grain boundary.

The use of such a material for the semiconductor layer makes it possible to achieve a highly reliable transistor in which a change in the electrical characteristics is reduced.

Charge accumulated in a capacitor through a transistor including the above-described semiconductor layer can be retained for a long time because of the low off-state current of the transistor. The use of such a transistor in a pixel allows a driver circuit to stop while the gray level of an image displayed on each display region is maintained. As a result, an electronic device with significantly reduced power consumption can be achieved.

For stable characteristics or the like of the transistor, a base film is preferably provided. The base film can be formed to be a single layer or a stacked layer using an inorganic insulating film such as a silicon oxide film, a silicon nitride film, a silicon oxynitride film, or a silicon nitride oxide film. The base film can be formed by a sputtering method, a CVD (Chemical Vapor Deposition) method (e.g., a plasma CVD method, a thermal CVD method, or an MOCVD (Metal Organic CVD) method), an ALD (Atomic Layer Deposition) method, a coating method, a printing method, or the like. Note that the base film is not necessarily provided when not needed.

Note that an FET 623 is illustrated as a transistor formed in the driver circuit portion 601. The driver circuit can be formed using various circuits such as a CMOS circuit, a PMOS circuit, and an NMOS circuit. Although a driver-integrated type in which the driver circuit is formed over the substrate is described in this embodiment, the driver circuit is not necessarily formed over the substrate and can be formed outside.

The pixel portion 602 is formed with a plurality of pixels each including a switching FET 611, a current control FET 612, and a first electrode 613 electrically connected to a drain of the current control FET 612; however, without being limited thereto, a pixel portion in which three or more FETs and a capacitor are combined may be employed.

Note that an insulator 614 is formed to cover an end portion of the first electrode 613. The insulator 614 can be formed using a positive photosensitive acrylic resin film here.

In order to improve the coverage with an EL layer or the like to be formed later, the insulator 614 is formed so as to have a curved surface with curvature at its upper end portion or lower end portion. For example, in the case where a positive photosensitive acrylic resin is used as a material for the insulator 614, only the upper end portion of the insulator 614 preferably has a curved surface with a curvature radius (0.2 μm to 3 μm). As the insulator 614, either a negative photosensitive resin or a positive photosensitive resin can be used.

An EL layer 616 and a second electrode 617 are formed over the first electrode 613. Here, as a material used for the first electrode 613 functioning as an anode, a material with a high work function is desirably used. For example, a single-layer film of an ITO film, an indium tin oxide film containing silicon, an indium oxide film containing zinc oxide at 2 to 20 wt %, a titanium nitride film, a chromium film, a tungsten film, a Zn film, a Pt film, or the like, a stacked layer of a titanium nitride film and a film containing aluminum as its main component, a three-layer structure of a titanium nitride film, a film containing aluminum as its main component, and a titanium nitride film, or the like can be used. Note that the stacked-layer structure achieves low wiring resistance, a favorable ohmic contact, and a function as an anode.

The EL layer 616 is formed by any of a variety of methods such as an evaporation method using an evaporation mask, an ink-jet method, and a spin coating method. The EL layer 616 has the structure described in Embodiment 2. As another material included in the EL layer 616, a low molecular compound or a high molecular compound (including an oligomer or a dendrimer) may be used.

As a material used for the second electrode 617, which is formed over the EL layer 616 and functions as a cathode, a material with a low work function (e.g., Al, Mg, Li, Ca, or an alloy or a compound thereof (e.g., MgAg, MgIn, or AlLi)) is preferably used. Note that in the case where light generated in the EL layer 616 passes through the second electrode 617, it is preferable to use, for the second electrode 617, a stacked layer of a thin metal film and a transparent conductive film (e.g., ITO, indium oxide containing zinc oxide at 2 to 20 wt %, indium tin oxide containing silicon, or zinc oxide (ZnO)).

Note that the light-emitting device is formed with the first electrode 613, the EL layer 616, and the second electrode 617. The light-emitting device is the light-emitting device described in Embodiment 2. A plurality of light-emitting devices are formed in the pixel portion, and the light-emitting apparatus of this embodiment may include both the light-emitting device described in Embodiment 2 and a light-emitting device having a different structure.

The sealing substrate 604 and the element substrate 610 are attached to each other using the sealant 605, so that a light-emitting device 618 is provided in the space 607 surrounded by the element substrate 610, the sealing substrate 604, and the sealant 605. The space 607 is filled with a filler, and may be filled with an inert gas (e.g., nitrogen or argon) or the sealant. It is preferable that the sealing substrate be provided with a recessed portion and a drying agent be provided in the recessed portion, in which case deterioration due to influence of moisture can be inhibited.

Note that an epoxy-based resin or glass frit is preferably used for the sealant 605. Furthermore, these materials are preferably materials that transmit moisture and oxygen as little as possible. As the material used for the sealing substrate 604, in addition to a glass substrate and a quartz substrate, a plastic substrate formed of FRP (Fiber Reinforced Plastics), PVF (polyvinyl fluoride), polyester, an acrylic resin, or the like can be used.

Although not illustrated in FIG. 2, a protective film may be provided over the second electrode. The protective film may be formed using an organic resin film or an inorganic insulating film. The protective film may be formed so as to cover an exposed portion of the sealant 605. The protective film can be provided to cover surfaces and side surfaces of the pair of substrates and exposed side surfaces of a sealing layer, an insulating layer, and the like.

For the protective film, a material that is less likely to transmit an impurity such as water can be used. Thus, diffusion of an impurity such as water from the outside into the inside can be effectively inhibited.

As a material included in the protective film, an oxide, a nitride, a fluoride, a sulfide, a ternary compound, a metal, a polymer, or the like can be used; for example, it is possible to use a material containing aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, or the like; a material containing aluminum nitride, hafnium nitride, silicon nitride, tantalum nitride, titanium nitride, niobium nitride, molybdenum nitride, zirconium nitride, gallium nitride, or the like; or a material containing a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like.

The protective film is preferably formed using a deposition method that enables favorable step coverage. One such method is an atomic layer deposition (ALD) method. A material that can be formed by an ALD method is preferably used for the protective film. With the use of an ALD method, a dense protective film with reduced defects such as cracks or pinholes or with a uniform thickness can be formed. Furthermore, damage caused to a process member in forming the protective film can be reduced.

By an ALD method, a uniform protective film with few defects can be formed even on a surface with a complex uneven shape or upper, side, and lower surfaces of a touch panel.

As described above, the light-emitting apparatus fabricated using the light-emitting device described in Embodiment 2 can be obtained.

For the light-emitting apparatus in this embodiment, the light-emitting device described in Embodiment 2 is used and thus a light-emitting apparatus having favorable characteristics can be obtained. Specifically, since the light-emitting device described in Embodiment 2 has high emission efficiency, the light-emitting apparatus with low power consumption can be obtained.

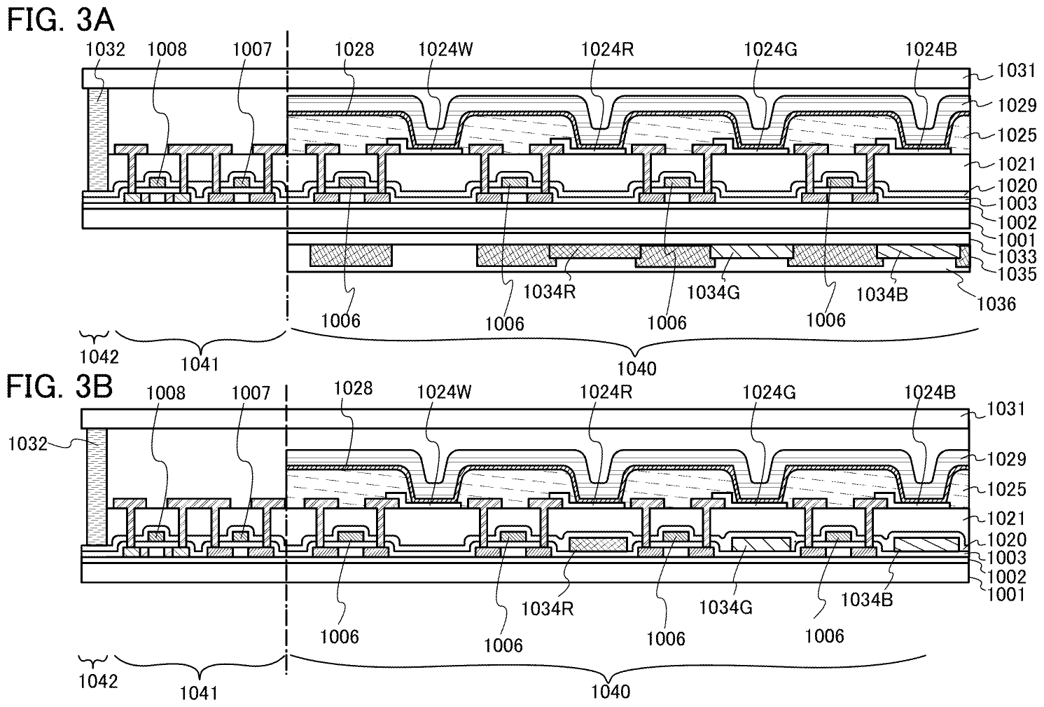

FIG. 3 illustrates examples of a light-emitting apparatus in which full color display is achieved by formation of light-emitting devices exhibiting white light emission and provision of coloring layers (color filters) and the like. FIG. 3A illustrates a substrate 1001, a base insulating film 1002, a gate insulating film 1003, gate electrodes 1006, 1007, and 1008, a first interlayer insulating film 1020, a second interlayer insulating film 1021, a peripheral portion 1042, a pixel portion 1040, a driver circuit portion 1041, first electrodes 1024W, 1024R, 1024G, and 1024B of the light-emitting devices, a partition 1025, an EL layer 1028, a second electrode 1029 of the light-emitting devices, a sealing substrate 1031, a sealant 1032, and the like.

In FIG. 3A, coloring layers (a red coloring layer 1034R, a green coloring layer 1034G, and a blue coloring layer 1034B) are provided on a transparent base material 1033. A black matrix 1035 may be additionally provided. The transparent base material 1033 provided with the coloring layers and the black matrix is positioned and fixed to the substrate 1001. Note that the coloring layers and the black matrix 1035 are covered with an overcoat layer 1036. In FIG. 3A, a light-emitting layer from which light is emitted to the outside without passing through a coloring layer and light-emitting layers from which light is emitted to the outside, passing through the coloring layers of the respective colors are shown. Since light that does not pass through a coloring layer is white and light that passes through the coloring layer is red, green, or blue, an image can be expressed using pixels of the four colors.

FIG. 3B shows an example in which the coloring layers (the red coloring layer 1034R, the green coloring layer 1034G, and the blue coloring layer 1034B) are formed between the gate insulating film 1003 and the first interlayer insulating film 1020. The coloring layers may be provided between the substrate 1001 and the sealing substrate 1031 in this manner.

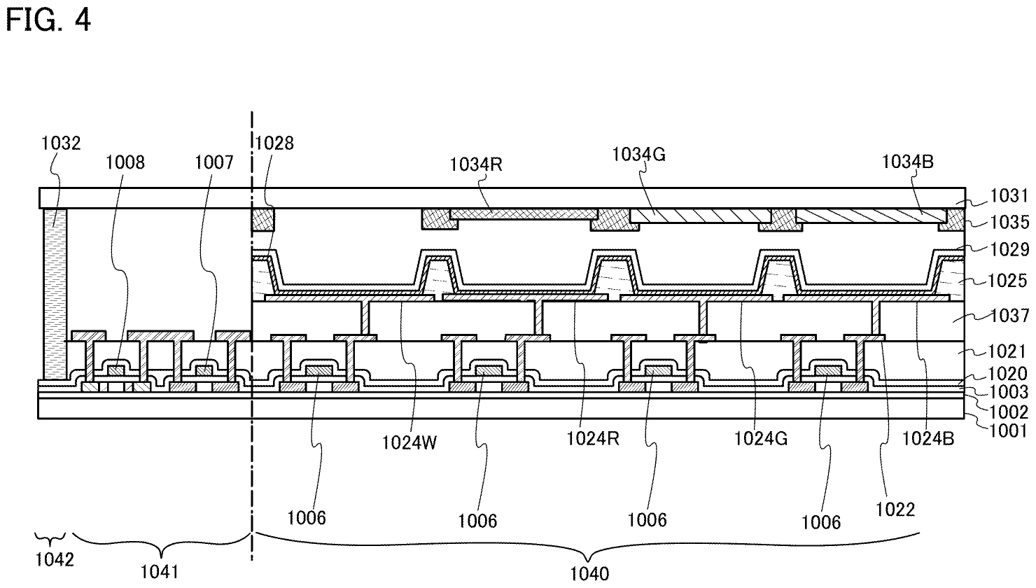

The above-described light-emitting apparatus is a light-emitting apparatus having a structure in which light is extracted to the substrate 1001 side where the FETs are formed (a bottom-emission type), but may be a light-emitting apparatus having a structure in which light emission is extracted to the sealing substrate 1031 side (a top-emission type). FIG. 4 is a cross-sectional view of a top-emission light-emitting apparatus. In this case, a substrate that does not transmit light can be used as the substrate 1001. The top-emission light-emitting apparatus is formed in a manner similar to that of the bottom-emission light-emitting apparatus until an electrode 1022 which connects the FET and the anode of the light-emitting device is formed. Then, a third interlayer insulating film 1037 is formed to cover the electrode 1022. This insulating film may have a planarization function. The third interlayer insulating film 1037 can be formed using a material similar to that for the second interlayer insulating film or using any other known materials.

The first electrodes 1024W, 1024R, 1024G, and 1024B of the light-emitting devices are each an anode here, but may each be a cathode. Furthermore, in the case of the top-emission light-emitting apparatus illustrated in FIG. 4, the first electrodes are preferably reflective electrodes. The EL layer 1028 is formed to have a structure similar to the structure of the EL layer 103 described in Embodiment 2, with which white light emission can be obtained.

In the case of such a top-emission structure as in FIG. 4, sealing can be performed with the sealing substrate 1031 on which the coloring layers (the red coloring layer 1034R, the green coloring layer 1034G, and the blue coloring layer 1034B) are provided. The sealing substrate 1031 may be provided with the black matrix 1035 which is positioned between pixels. The coloring layers (the red coloring layer 1034R, the green coloring layer 1034G, and the blue coloring layer 1034B) and the black matrix may be covered with the overcoat layer 1036. Note that a light-transmitting substrate is used as the sealing substrate 1031. Although an example in which full color display is performed using four colors of red, green, blue, and white is shown here, there is no particular limitation and full color display may be performed using four colors of red, yellow, green, and blue or three colors of red, green, and blue.

In the top-emission light-emitting apparatus, a microcavity structure can be favorably employed. A light-emitting device with a microcavity structure can be obtained with the use of a reflective electrode as the first electrode and a semi-transmissive and semi-reflective electrode as the second electrode. The light-emitting device with a microcavity structure includes at least an EL layer between the reflective electrode and the semi-transmissive and semi-reflective electrode, which includes at least a light-emitting layer serving as a light-emitting region.

Note that the reflective electrode is a film having a visible light reflectivity of 40% to 100%, preferably 70% to 100%, and a resistivity of 1×10⁻² Ωcm or lower. In addition, the semi-transmissive and semi-reflective electrode is a film having a visible light reflectivity of 20% to 80%, preferably 40% to 70%, and a resistivity of 1×10⁻² Ωcm or lower.

Light emitted from the light-emitting layer included in the EL layer is reflected and resonated by the reflective electrode and the semi-transmissive and semi-reflective electrode.

In the light-emitting device, by changing thicknesses of the transparent conductive film, the above-described composite material, the carrier-transport material, or the like, the optical path length between the reflective electrode and the semi-transmissive and semi-reflective electrode can be changed. Thus, light with a wavelength that is resonated between the reflective electrode and the semi-transmissive and semi-reflective electrode can be intensified while light with a wavelength that is not resonated therebetween can be attenuated.

Note that light that is reflected back by the reflective electrode (first reflected light) considerably interferes with light that directly enters the semi-transmissive and semi-reflective electrode from the light-emitting layer (first incident light); therefore, the optical path length between the reflective electrode and the light-emitting layer is preferably adjusted to (2n−1)λ/4 (n is a natural number of 1 or larger and λ is a wavelength of light emission to be amplified). By adjusting the optical path length, the phases of the first reflected light and the first incident light can be aligned with each other and the light emitted from the light-emitting layer can be further amplified.

Note that in the above structure, the EL layer may include a plurality of light-emitting layers or may include a single light-emitting layer; for example, in combination with the structure of the above-described tandem light-emitting device, a plurality of EL layers each including a single or a plurality of light-emitting layer(s) may be provided in one light-emitting device with a charge-generation layer interposed between the EL layers.

With the microcavity structure, emission intensity with a specific wavelength in the front direction can be increased, whereby power consumption can be reduced. Note that in the case of a light-emitting apparatus which displays images with subpixels of four colors, red, yellow, green, and blue, the light-emitting apparatus can have favorable characteristics because a microcavity structure suitable for wavelengths of the corresponding color is employed in each subpixel, in addition to the effect of an improvement in luminance owing to yellow light emission.

For the light-emitting apparatus in this embodiment, the light-emitting device described in Embodiment 2 is used and thus a light-emitting apparatus having favorable characteristics can be obtained. Specifically, since the light-emitting device described in Embodiment 2 has high emission efficiency, the light-emitting apparatus with low power consumption can be obtained.

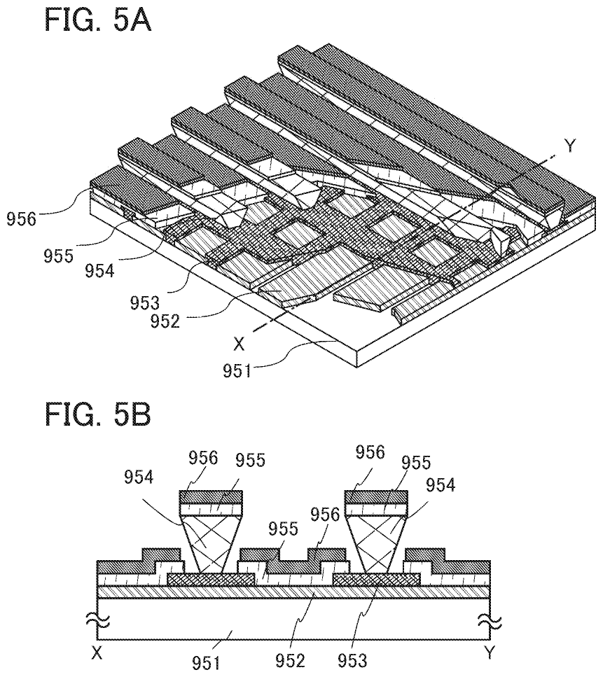

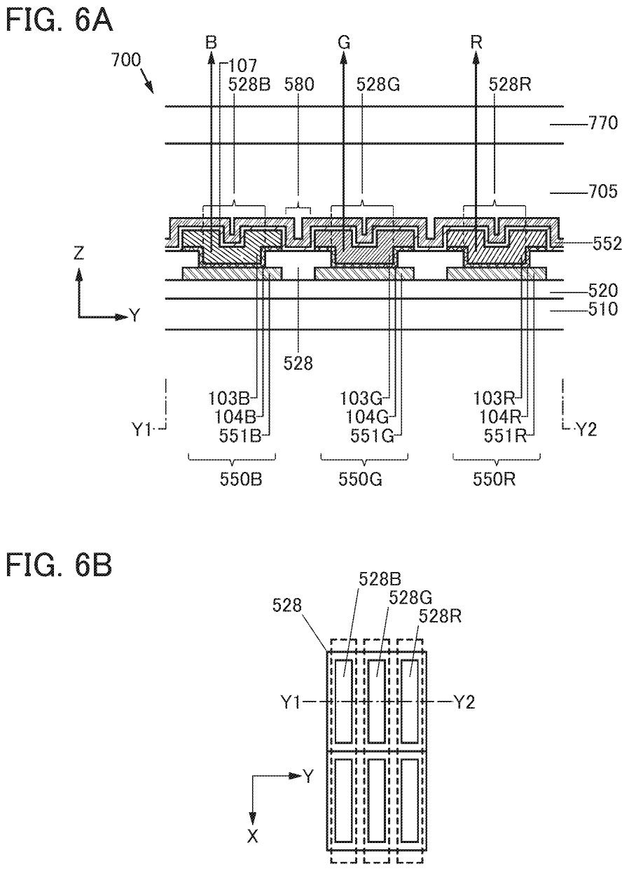

The active matrix light-emitting apparatus is described above, whereas a passive matrix light-emitting apparatus is described below. FIG. 5 illustrates a passive matrix light-emitting apparatus fabricated using the present invention. Note that FIG. 5A is a perspective view illustrating the light-emitting apparatus, and FIG. 5B is a cross-sectional view taken along X-Y in FIG. 5A. In FIG. 5, over a substrate 951, an EL layer 955 is provided between an electrode 952 and an electrode 956. An end portion of the electrode 952 is covered with an insulating layer 953. A partition layer 954 is provided over the insulating layer 953. Sidewalls of the partition layer 954 are aslope such that the distance between one sidewall and the other sidewall is gradually narrowed toward the surface of the substrate. That is, a cross section in the short side direction of the partition layer 954 is a trapezoidal shape, and the lower side (the side facing the same direction as the plane direction of the insulating layer 953 and touching the insulating layer 953) is shorter than the upper side (the side facing the same direction as the plane direction of the insulating layer 953, and not touching the insulating layer 953). By providing the partition layer 954 in this manner, defects of the light-emitting device due to static charge or the like can be prevented. The passive-matrix light-emitting apparatus also uses the light-emitting device described in Embodiment 2; thus, the light-emitting apparatus can have favorable reliability or low power consumption.

Since many minute light-emitting devices arranged in a matrix can each be controlled in the light-emitting apparatus described above, the light-emitting apparatus can be suitably used as a display device for displaying images.

This embodiment can be freely combined with any of the other embodiments.

### Embodiment 4

In this embodiment, specific structure examples and an example of a manufacturing method of a light-emitting apparatus (also referred to as a display panel) of one embodiment of the present invention will be described. Note that the material described in Embodiment 1 can be used for the EL layer 103 included in the light-emitting apparatus (also referred to as a display panel) described in this embodiment.

### <Structure Example 1 of Light-Emitting Apparatus 700>

A light-emitting apparatus 700 illustrated in FIG. 6A includes a light-emitting device 550B, a light-emitting device 550G, a light-emitting device 550R, and a partition 528. The light-emitting device 550B, the light-emitting device 550G, the light-emitting device 550R, and the partition 528 are formed over a functional layer 520 provided over a first substrate 510. The functional layer 520 includes, for example, a gate line driver circuit, a source line driver circuit, and the like that are composed of a plurality of transistors, and wirings that electrically connect these circuits. Note that these driver circuits are electrically connected to the light-emitting device 550B, the light-emitting device 550G, and the light-emitting device 550R, for example, to drive them. The light-emitting apparatus 700 includes an insulating layer 705 over the functional layer 520 and the light-emitting devices, and the insulating layer 705 has a function of attaching a second substrate 770 and the functional layer 520.

The light-emitting device 550B, the light-emitting device 550G, and the light-emitting device 550R each have the device structure described in Embodiment 2. Specifically, the case is described in which the EL layer 103 in the structure illustrated in FIG. 1A differs between the light-emitting devices.

The light-emitting device 550B includes an electrode 551B, an electrode 552, an EL layer 103B, and a blocking layer 107. Note that a specific structure of each layer is as described in Embodiment 2. The EL layer 103B has a stacked-layer structure of layers having different functions including a light-emitting layer. Although FIG. 6A illustrates only a hole-injection/transport layer 104B in the layers included in the EL layer 103B, which includes the light-emitting layer, the present invention is not limited thereto. Note that the hole-injection/transport layer 104B represents the layer having the functions of the hole-injection layer and the hole-transport layer described in Embodiment 2 and may have a stacked-layer structure. Note that in this specification, a hole-injection/transport layer in any light-emitting device can be interpreted in the above manner. The EL layer 103B may include an electron-injection/transport layer. The electron-injection/transport layer also represents the layer having the functions of the electron-injection layer and the electron-transport layer and may have a stacked-layer structure.

The blocking layer 107 is formed to cover the EL layer 103B formed over the electrode 551B. As illustrated in FIG. 6A, the EL layer 103B includes a side surface (or an end portion). Thus, the blocking layer 107 is formed in contact with a side surface (or an end portion) of the EL layer 103B. This can inhibit entry of oxygen, moisture, or constituent elements thereof into the inside through the side surface of the EL layer 103B. The hole-transport material described in Embodiment 2 can be used for the blocking layer 107.

The electrode 552 is formed over the blocking layer 107. Note that the electrode 551B and the electrode 552 have an overlap region. The EL layer 103B is positioned between the electrode 551B and the electrode 552. Thus, part of the blocking layer 107 is positioned between the electrode 552 and the side surface (or the end portion) of the EL layer 103B. Hence, the EL layer 103B and the electrode 552, specifically the hole-injection/transport layer 104B in the EL layer 103B and the electrode 552 can be prevented from being electrically short-circuited.

The EL layer 103B illustrated in FIG. 6A has a structure similar to that of the EL layer 103 described in Embodiment 2. The EL layer 103B is capable of emitting blue light, for example.

The light-emitting device 550G includes an electrode 551G, the electrode 552, an EL layer 103G, and the blocking layer 107. Note that a specific structure of each layer is as described in Embodiment 3. The EL layer 103G has a stacked-layer structure of layers having different functions including a light-emitting layer. Although FIG. 6A illustrates only a hole-injection/transport layer 104G in the layers included in the EL layer 103G, which includes the light-emitting layer, the present invention is not limited thereto. Note that the hole-injection/transport layer 104G represents the layer having the functions of the hole-injection layer and the hole-transport layer described in Embodiment 2 and may have a stacked-layer structure.

The blocking layer 107 is formed to cover the EL layer 103G formed over the electrode 551G. As illustrated in FIG. 6A, the EL layer 103G includes a side surface (or an end portion). Thus, the blocking layer 107 is formed in contact with also a side surface (or an end portion) of the EL layer 103G. Accordingly, entry of oxygen, moisture, or constituent elements thereof through the side surface of the EL layer 103G into the inside of the EL layer 103G can be inhibited. The hole-transport material described in Embodiment 2 can be used for the blocking layer 107.

The electrode 552 is formed over the blocking layer 107. Note that the electrode 551G and the electrode 552 have an overlap region. The EL layer 103G is positioned between the electrode 551G and the electrode 552. Thus, part of the blocking layer 107 is positioned between the electrode 552 and the side surface of the EL layer 103G. Hence, the EL layer 103G and the electrode 552, specifically the hole-injection/transport layer 104G in the EL layer 103G and the electrode 552 can be prevented from being electrically short-circuited.

The EL layer 103G illustrated in FIG. 6A has a structure similar to that of the EL layer described in Embodiment 2. The EL layer 103G is capable of emitting green light, for example.

The light-emitting device 550R includes an electrode 551R, an electrode 552, an EL layer 103R, and the blocking layer 107. Note that a specific structure of each layer is as described in Embodiment 2. The EL layer 103R has a stacked-layer structure of layers having different functions including a light-emitting layer. Although FIG. 6A illustrates only a hole-injection/transport layer 104R in the layers included in the EL layer 103R, which includes the light-emitting layer, the present invention is not limited thereto. Note that the hole-injection/transport layer 104R represents the layer having the functions of the hole-injection layer and the hole-transport layer described in Embodiment 2 and may have a stacked-layer structure.

The blocking layer 107 is formed to cover the EL layer 103R formed over the electrode 551R. As illustrated in FIG. 6A, the EL layer 103R includes a side surface (or an end portion). Thus, the blocking layer 107 is formed in contact with also a side surface (or an end portion) of the EL layer 103R. Accordingly, entry of oxygen, moisture, or constituent elements thereof through the side surface of the EL layer 103R into the inside of the EL layer 103R can be inhibited. The hole-transport material described in Embodiment 2 can be used for the blocking layer 107.

The electrode 552 is formed over the blocking layer 107. Note that the electrode 551R and the electrode 552 have an overlap region. The EL layer 103R is positioned between the electrode 551R and the electrode 552. Thus, part of the blocking layer 107 is positioned between the electrode 552 and the side surface of the EL layer 103R. Hence, the EL layer 103R and the electrode 552, specifically the hole-injection/transport layer 104R in the EL layer 103R and the electrode 552 can be prevented from being electrically short-circuited.

The EL layer 103R illustrated in FIG. 6A has a structure similar to that of the EL layer 103 described in Embodiment 2. The EL layer 103R is capable of emitting red light, for example.

A space 580 is provided between the EL layer 103B, the EL layer 103G, and the EL layer 103R. In each of the EL layers, particularly the hole-injection layer, which is included in the hole-transport region between the anode and the light-emitting layer, often has high conductivity; therefore, a hole-injection layer formed as a layer shared by adjacent light-emitting devices might cause crosstalk. Thus, providing the space 580 between the EL layers as shown in this structure example can suppress occurrence of crosstalk between adjacent light-emitting devices.

When electrical continuity is established between the EL layer 103B, the EL layer 103G, and the EL layer 103R in a light-emitting apparatus (display panel) with a high resolution exceeding 1000 ppi, a crosstalk phenomenon occurs, resulting in a narrower color gamut that the light-emitting apparatus is capable of reproducing. Providing the space 580 in a high-resolution display panel with more than 1000 ppi, preferably more than 2000 ppi, or further preferably in an ultrahigh-resolution display panel with more than 5000 ppi allows the display panel to express vivid colors.

As illustrated in FIG. 6B, the partition 528 has an opening 528B, an opening 528G, and an opening 528R. As illustrated in FIG. 6A, the opening 528B overlaps with the electrode 551B, the opening 528G overlaps with the electrode 551G, and the opening 528R overlaps with the electrode 551R.

The EL layers 103B, 103G, and 103R are processed to be separated by patterning using a photolithography method; hence, a high-resolution light-emitting apparatus (display panel) can be fabricated. End portions (side surfaces) of the EL layer processed by patterning using a photolithography method have substantially one surface (or are positioned on substantially the same plane). In this case, the space 580 between the EL layers is preferably 5 μm or less, further preferably 1 μm or less.

In the EL layer, particularly the hole-injection layer, which is included in the hole-transport region between the anode and the light-emitting layer, often has high conductivity; thus, a hole-injection layer formed as a layer shared by adjacent light-emitting devices might cause crosstalk. Therefore, processing the EL layers to be separated by patterning using a photolithography method as shown in this structure example can suppress occurrence of crosstalk between adjacent light-emitting devices.

In this specification and the like, a device formed using a metal mask or an FMM (fine metal mask) may be referred to as a device having an MM (metal mask) structure. In this specification and the like, a device formed without using a metal mask or an FMM may be referred to as a device having an MML (metal maskless) structure.

In this specification and the like, a structure in which light-emitting layers in light-emitting devices of different colors (here, blue (B), green (G), and red (R)) are separately formed or separately patterned may be referred to as an SBS (Side By Side) structure. In this specification and the like, a light-emitting device capable of emitting white light may be referred to as a white-light-emitting device. Note that a white light-emitting device that is combined with coloring layers (e.g., color filters) can be a light-emitting device of full-color display.

Structures of light-emitting devices can be classified roughly into a single structure and a tandem structure. A device having a single structure includes one EL layer between a pair of electrodes, and the EL layer preferably includes one or more light-emitting layers. To obtain white light emission, two or more light-emitting layers are selected such that emission colors of the light-emitting layers are complementary colors. For example, when emission colors of a first light-emitting layer and a second light-emitting layer are complementary colors, the light-emitting device can be configured to emit white light as a whole. The same applies to a light-emitting device including three or more light-emitting layers.

A light-emitting device having a tandem structure includes two or more light-emitting units (EL layers) between a pair of electrodes, and each light-emitting unit (EL layer) preferably includes one or more light-emitting layers. To obtain white light emission, the structure is made so that light from light-emitting layers of the light-emitting units (EL layers) can be combined to be white light emission. Note that a structure for obtaining white light emission is similar to a structure in the case of a single structure. In the light-emitting device having a tandem structure, it is preferable that an intermediate layer such as a charge-generation layer be provided between the plurality of light-emitting units (EL layers).

When the white-light-emitting device (having a single structure or a tandem structure) and a light-emitting device having an SBS structure are compared to each other, the light-emitting device having an SBS structure can have lower power consumption than the white-light-emitting device. To reduce power consumption, a light-emitting device having an SBS structure is preferably used. Meanwhile, the white-light-emitting device is preferable in terms of lower manufacturing cost or higher manufacturing yield because the manufacturing process of the white-light-emitting device is simpler than that of a light-emitting device having an SBS structure.

### <Example 1 of Method for Manufacturing Light-Emitting Apparatus>

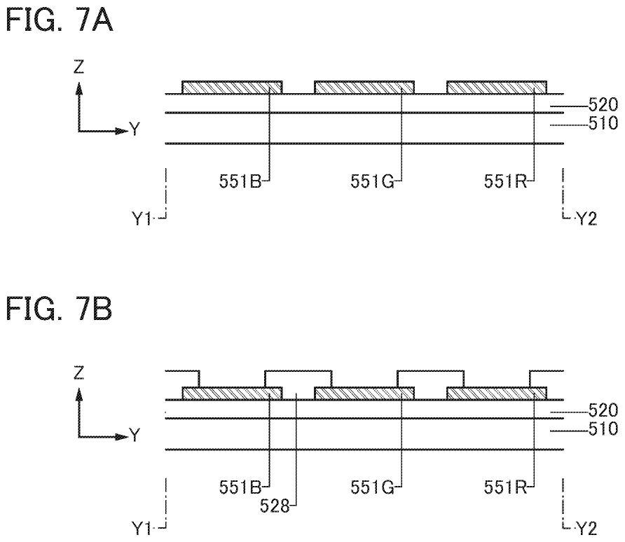

The electrode 551B, the electrode 551G, and the electrode 551R are formed as illustrated in FIG. 7A. For example, a conductive film is formed over the functional layer 520 over the first substrate 510 and processed into predetermined shapes by a photolithography method.

The conductive film can be formed by any of a sputtering method, a chemical vapor deposition (CVD) method, a vacuum evaporation method, a pulsed laser deposition (PLD) method, an atomic layer deposition (ALD) method, and the like. Examples of the CVD method include a plasma-enhanced chemical vapor deposition (PECVD) method and a thermal CVD method. An example of a thermal CVD method is a metal organic CVD (MOCVD) method.

The conductive film may be processed by a nanoimprinting method, a sandblasting method, a lift-off method, or the like as well as a photolithography method described above. Alternatively, island-shaped thin films may be directly formed by a deposition method using a shielding mask such as a metal mask.

There are the following two typical examples of a photolithography method. In one of the methods, a resist mask is formed over a thin film that is to be processed, the thin film is processed by etching or the like, and then the resist mask is removed. In the other method, a photosensitive thin film is deposited and then processed into a desired shape by light exposure and development.

As light for exposure in a photolithography method, it is possible to use light with the i-line (wavelength: 365 nm), light with the g-line (wavelength: 436 nm), light with the h-line (wavelength: 405 nm), or combined light of any of them. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Instead of the light for exposure, an electron beam can be used. It is preferable to use extreme ultraviolet light, X-rays, or an electron beam because extremely minute processing can be performed. Note that a photomask is not needed when exposure is performed by scanning with a beam such as an electron beam.

For etching of a thin film using a resist mask, a dry etching method, a wet etching method, a sandblast method, or the like can be used.

Next, as illustrated in FIG. 7B, the partition 528 is formed between the electrode 551B, the electrode 551G, and the electrode 551R. For example, the partition 528 can be formed in such a manner that an insulating film covering the electrode 551B, the electrode 551G, and the electrode 551R is formed, and openings are formed by a photolithography method to partly expose the electrode 551B, the electrode 551G, and the electrode 551R. Examples of a material that can be used for the partition 528 include an inorganic material, an organic material, and a composite material of an inorganic material and an organic material. Specifically, it is possible to use an inorganic oxide film, an inorganic nitride film, an inorganic oxynitride film, or the like, or a layered material in which two or more films selected from the above are stacked. More specifically, it is possible to use a silicon oxide film, a film containing acrylic, a film containing polyimide, or the like, or a layered material in which two or more films selected from the above are stacked.

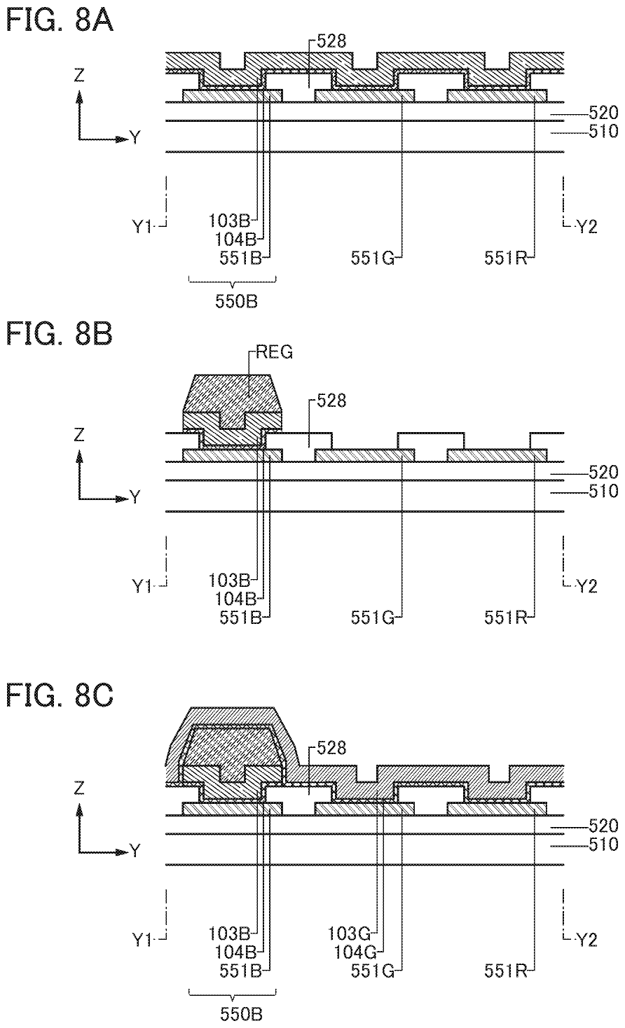

Then, as illustrated in FIG. 8A, the EL layer 103B is formed over the electrode 551B, the electrode 551G, the electrode 551R, and the partition 528. Note that in this structure example, only the hole-injection/transport layer 104B included in the EL layer 103B is illustrated. For example, the EL layer 103B is formed by a vacuum evaporation method over the electrode 551B, the electrode 551G, the electrode 551R, and the partition 528 so as to cover them.

Then, as illustrated in FIG. 8B, the EL layer 103B over the electrode 551B is processed to have a predetermined shape, for example, a shape having side surfaces (or exposed side surfaces) or a belt-like shape that extends in the direction intersecting the sheet of the diagram in such a manner that a resist is formed by a photolithography method and the EL layer 103G over the electrode 551G and the EL layer 103R over the electrode 551R are removed by etching. Specifically, dry etching is performed using the resist REG formed over the EL layer 103B overlapping with the electrode 551B (see FIG. 8B). The partition 528 can be used as an etching stopper. When the EL layers are each patterned by a photolithography method in this embodiment, a known method is employed. That is, a known resist material suitable for an organic material is used; specifically, an aqueous resist material is given.

Next, as illustrated in FIG. 8C, with the resist REG formed, the EL layer 103G (including the hole-injection/transport layer 104G) is formed over the resist REG, the electrode 551G, the electrode 551R, and the partition 528. For example, the EL layer 103G is formed by a vacuum evaporation method over the electrode 551G, the electrode 551R, and the partition 528 so as to cover them.

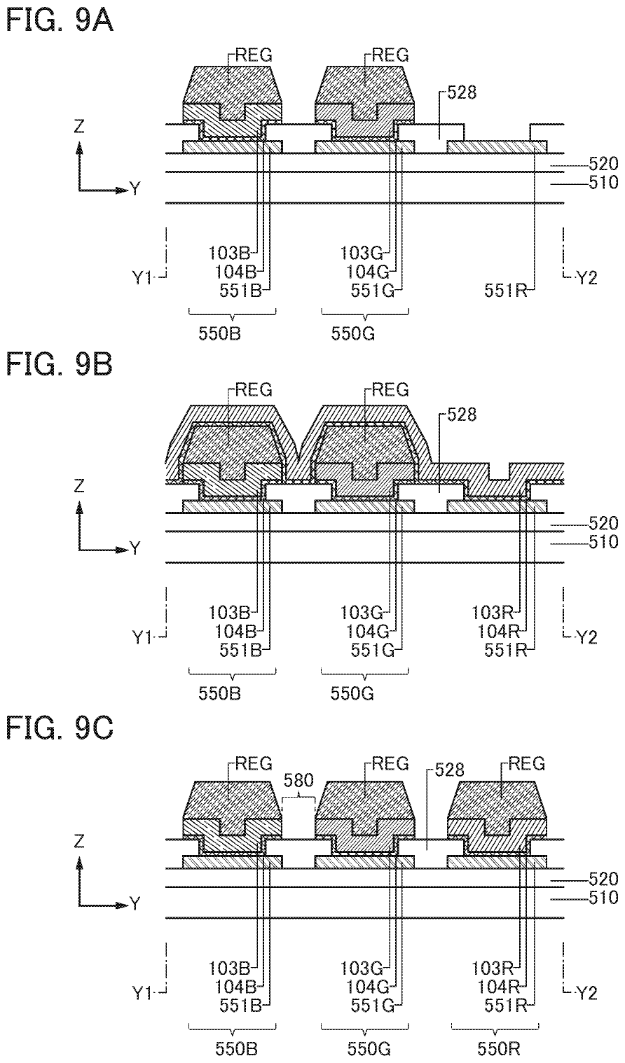

Then, as illustrated in FIG. 9A, the EL layer 103G over the electrode 551G is processed to have a predetermined shape, for example, a shape having side surfaces (or exposed side surfaces) or a belt-like shape that extends in the direction intersecting the sheet of the diagram in such a manner that a resist is formed over the EL layer 103G over the electrode 551G by a photolithography method and the EL layer 103G over the electrode 551B and the EL layer 103G over the electrode 551R are removed by etching. Specifically, dry etching is performed using the resist REG formed over the EL layer 103G overlapping with the electrode 551G. The partition 528 can be used as an etching stopper.

Next, as illustrated in FIG. 9B, with the resist REG formed over the electrode 551B and the electrode 551G, the EL layer 103R (including the hole-injection/transport layer 104R) is formed over the resist REG, the electrode 551R, and the partition 528. For example, the EL layer 103R is formed by a vacuum evaporation method over the electrode 551R, the resist REG, and the partition 528 so as to cover them.

Then, as illustrated in FIG. 9C, the EL layer 103R over the electrode 551R is processed to have a predetermined shape, for example, a shape having side surfaces (or exposed side surfaces) or a belt-like shape that extends in the direction intersecting the sheet of the diagram in such a manner that a resist is formed over the EL layer 103R over the electrode 551R by a photolithography method and the EL layer 103R over the electrode 551B and the EL layer 103R over the electrode 551G are removed. Specifically, dry etching is performed using the resist REG formed over the EL layer 103R overlapping with the electrode 551R. The partition 528 can be used as an etching stopper.

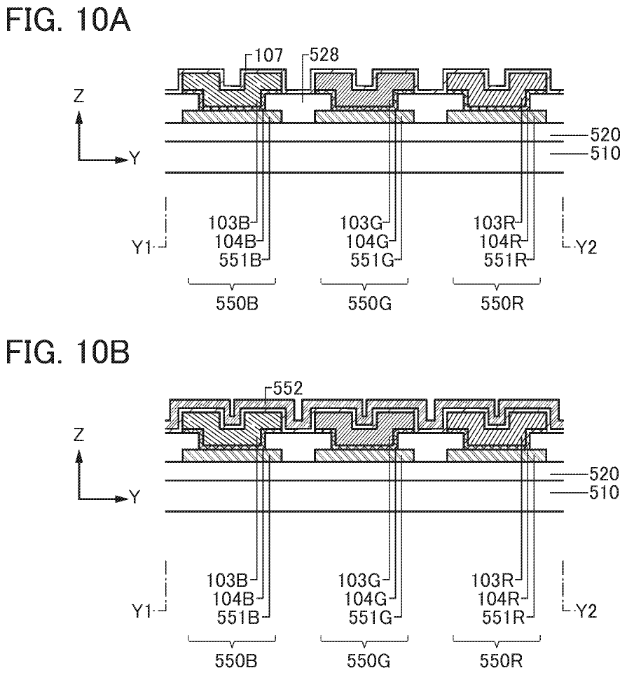

Then, as illustrated in FIG. 10A, the blocking layer 107 is formed over the EL layers (103B, 103G, and 103R) and the partition 528. For example, the blocking layer 107 is formed by a vacuum evaporation method over the EL layers (103B, 103G, and 103R) and the partition 528 so as to cover them. In this case, the blocking layer 107 is formed in contact with the side surfaces of the EL layers (103B, 103G, and 103R) as illustrated in FIG. 10A. This can inhibit entry of oxygen, moisture, or constituent elements thereof into the inside through the side surfaces of the EL layers (103B, 103G, and 103R). As a material used for the insulating layer 107, the hole-transport material described in Embodiment 2 can be used.

Next, as illustrated in FIG. 10B, the electrode 552 is formed over the blocking layer 107. The electrode 552 is formed by a vacuum evaporation method, for example. The electrode 552 is formed over the blocking layer 107. Part of the blocking layer 107 is positioned between the electrode 552 and the side surfaces of the EL layers (103B, 103G, and 103R). Thus, the EL layers (103B, 103G, and 103R) and the electrode 552, specifically the hole-injection/transport layers (104B, 104G, and 104R) in the EL layers (103B, 103G, and 103R) and the electrode 552 can be prevented from being electrically short-circuited.

Through the above steps, the EL layer 103B, the EL layer 103G, and the EL layer 103R in the light-emitting device 550B, the light-emitting device 550G, and the light-emitting device 550R can be processed to be separated from each other.

The EL layers 103B, 103G, and 103R are processed to be separated by patterning using a photolithography method; hence, a high-resolution light-emitting apparatus (display panel) can be fabricated. End portions (side surfaces) of the EL layer processed by patterning using a photolithography method have substantially one surface (or are positioned on substantially the same plane).

In the EL layer, particularly the hole-injection layer, which is included in the hole-transport region between the anode and the light-emitting layer, often has high conductivity; thus, a hole-injection layer formed as a layer shared by adjacent light-emitting devices might cause crosstalk. Therefore, processing the EL layers to be separated by patterning using a photolithography method as shown in this structure example can suppress occurrence of crosstalk between adjacent light-emitting devices.

### <Structure Example 2 of Light-Emitting Apparatus 700>

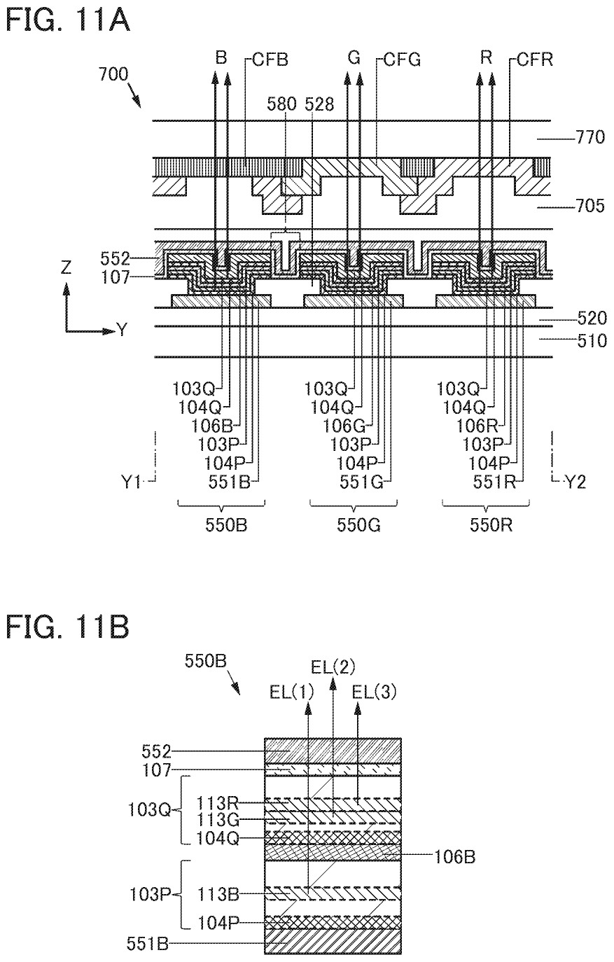

The light-emitting apparatus 700 illustrated in FIG. 11A includes the light-emitting device 550B, the light-emitting device 550G, the light-emitting device 550R, and the partition 528. The light-emitting device 550B, the light-emitting device 550G, the light-emitting device 550R, and the partition 528 are formed over the functional layer 520 provided over the first substrate 510. The functional layer 520 includes, for example, the driver circuits that are composed of a plurality of transistors, such as the gate line driver circuit and the source line driver circuit, and wirings that electrically connect these circuits. Note that these driver circuits are electrically connected to the light-emitting device 550B, the light-emitting device 550G, and the light-emitting device 550R to drive them.

The light-emitting device 550B, the light-emitting device 550G, and the light-emitting device 550R each have the device structure described in Embodiment 2. Specifically, the case is described in which the light-emitting devices share the EL layer 103 having the structure illustrated in FIG. 1B, i.e., a tandem structure.

The light-emitting device 550B has a stacked-layer structure illustrated in FIG. 11A, which includes the electrode 551B, the electrode 552, EL layers (103P and 103Q), a charge-generation layer 106B, and the blocking layer 107. Note that a specific structure of each layer is as described in Embodiment 2. The electrode 551B and the electrode 552 overlap each other. The EL layer 103P and the EL layer 103Q are stacked with the charge-generation layer 106B therebetween, and the EL layer 103P, the EL layer 103Q, and the charge-generation layer 106B are positioned between the electrode 551B and the electrode 552. Note that each of the EL layers 103P and 103Q has a stacked-layer structure of layers having different functions, including a light-emitting layer, like the EL layer 103 described in Embodiment 2. The EL layer 103P is capable of emitting blue light, for example, and the EL layer 103Q is capable of emitting yellow light, for example.

FIG. 11A illustrates only a hole-injection/transport layer 104P in the layers included in the EL layer 103P and only a hole-injection/transport layer 104Q in the layers included in the EL layer 103Q. Thus, in the following description, the term “EL layer” (the EL layer 103P and the EL layer 103Q) is used for convenience to describe the layers included in the EL layer as well.

Furthermore, the blocking layer 107 is formed to cover the EL layer 103P, the EL layer 103Q, and the charge-generation layer 106B which are formed over the electrode 551B. As illustrated in FIG. 11A, the EL layer 103P, the EL layer 103Q, and the charge-generation layer 106B have side surfaces (or end portions). Thus, the blocking layer 107 is formed in contact with the side surfaces (or the end portions) of the EL layer 103P, the EL layer 103Q, and the charge-generation layer 106B. Accordingly, it is possible to inhibit entry of oxygen, moisture, or constituent elements thereof into the inside through the side surfaces of the EL layer 103P, the EL layer 103Q, and the charge-generation layer 106B. The hole-transport material described in Embodiment 2 can be used for the blocking layer 107.

The electrode 552 is formed over the blocking layer 107. Note that the electrode 551B and the electrode 552 overlap with each other. The EL layer 103P, the EL layer 103Q, and the charge-generation layer 106B are positioned between the electrode 551B and the electrode 552. Thus, portions of the blocking layer 107 are positioned between the electrode 552 and the side surface (or the end portion) of the EL layer 103P, between the electrode 552 and the side surface of the EL layer 103Q, and between the electrode 552 and the side surface of the charge-generation layer 106B. Consequently, the EL layer 103P and the electrode 552, specifically the hole-injection/transport layer 104P in the EL layer 103P and the electrode 552 or the EL layer 103Q and the electrode 552, more specifically the hole-injection/transport layer 104Q in the EL layer 103Q and the electrode 552 or the charge-generation layer 106B and the electrode 552 can be prevented from being electrically short-circuited.

The light-emitting device 550G has a stacked-layer structure illustrated in FIG. 11A, which includes the electrode 551G, the electrode 552, the EL layers (103P and 103Q), a charge-generation layer 106G, and the blocking layer 107. Note that a specific structure of each layer is as described in Embodiment 2. The electrode 551G and the electrode 552 overlap each other. The EL layer 103P and the EL layer 103Q are stacked with the charge-generation layer 106G therebetween, and the EL layer 103P, the EL layer 103Q, and the charge-generation layer 106G are positioned between the electrode 551G and the electrode 552.

Furthermore, the blocking layer 107 is formed to cover the EL layer 103P, the EL layer 103Q, and the charge-generation layer 106G which are formed over the electrode 551G. As illustrated in FIG. 11A, the EL layer 103P, the EL layer 103Q, and the charge-generation layer 106G have side surfaces (or end portions). Thus, the blocking layer 107 is formed in contact with the side surfaces (or the end portions) of the EL layer 103P, the EL layer 103Q, and the charge-generation layer 106G. Accordingly, it is possible to inhibit entry of oxygen, moisture, or constituent elements thereof into the inside through the side surfaces of the EL layer 103P, the EL layer 103Q, and the charge-generation layer 106G. The hole-transport material described in Embodiment 2 can be used for the blocking layer 107.

The electrode 552 is formed over the blocking layer 107. Note that the electrode 551G and the electrode 552 overlap with each other. The EL layer 103P, the EL layer 103Q, and the charge-generation layer 106G are positioned between the electrode 551G and the electrode 552. Thus, portions of the blocking layer 107 are positioned between the electrode 552 and the side surface (or the end portion) of the EL layer 103P, between the electrode 552 and the side surface of the EL layer 103Q, and between the electrode 552 and the side surface of the charge-generation layer 106G. Consequently, the EL layer 103P and the electrode 552, specifically the hole-injection/transport layer 104P in the EL layer 103P and the electrode 552 or the EL layer 103Q and the electrode 552, more specifically the hole-injection/transport layer 104Q in the EL layer 103Q and the electrode 552 or the charge-generation layer 106G and the electrode 552 can be prevented from being electrically short-circuited.

The light-emitting device 550R has a stacked-layer structure illustrated in FIG. 11A, which includes the electrode 551R, the electrode 552, the EL layers (103P and 103Q), a charge-generation layer 106R, and the blocking layer 107. Note that a specific structure of each layer is as described in Embodiment 2. The electrode 551R and the electrode 552 overlap each other. The EL layer 103P and the EL layer 103Q are stacked with the charge-generation layer 106R therebetween, and the EL layer 103P, the EL layer 103Q, and the charge-generation layer 106R are positioned between the electrode 551R and the electrode 552.

Furthermore, the blocking layer 107 is formed to cover the EL layer 103P, the EL layer 103Q, and the charge-generation layer 106R which are formed over the electrode 551R. As illustrated in FIG. 11A, the EL layer 103P, the EL layer 103Q, and the charge-generation layer 106R have side surfaces (or end portions). Thus, the blocking layer 107 is formed in contact with the side surfaces (or the end portions) of the EL layer 103P, the EL layer 103Q, and the charge-generation layer 106R. Accordingly, it is possible to inhibit entry of oxygen, moisture, or constituent elements thereof into the inside through the side surfaces of the EL layer 103P, the EL layer 103Q, and the charge-generation layer 106R. The hole-transport material described in Embodiment 2 can be used for the blocking layer 107.

The electrode 552 is formed over the blocking layer 107. Note that the electrode 551R and the electrode 552 overlap with each other. In addition, (103P and 103Q) are positioned between the electrode 551R and the electrode 552. Note that portions of the blocking layer 107 are positioned between the electrode 552 and the side surface (or the end portion) of the EL layers (103P and 103Q) and between the electrode 552 and the side surface of the charge-generation layer 106R. Consequently, the EL layer 103P and the electrode 552, specifically the hole-injection/transport layer 104P in the EL layer 103P and the electrode 552 or the EL layer 103Q and the electrode 552, more specifically the hole-injection/transport layer 104Q in the EL layer 103Q and the electrode 552 or the charge-generation layer 106R and the electrode 552 can be prevented from being electrically short-circuited.

The EL layers (103P and 103Q) and the charge-generation layer 106R included in the light-emitting devices are processed to be separated between the light-emitting devices by patterning using a photolithography method; thus, the end portions (side surfaces) of the processed EL layers have substantially one surface (or are positioned on substantially the same plane).

The space 580 is provided between the EL layers (103P and 103Q) and the charge-generation layer 106R in one light-emitting device and those in the adjacent light-emitting device. The charge-generation layer 106R and the hole-injection layers included in the hole-transport regions in the EL layers (103P and 103Q) often have high conductivity; therefore, these layers formed as layers shared by adjacent light-emitting devices might cause crosstalk. Thus, providing the space 580 as shown in this structure example can suppress occurrence of crosstalk between adjacent light-emitting devices.

When electrical continuity is established between the EL layer 103B, the EL layer 103G, and the EL layer 103R in a light-emitting apparatus (display panel) with a high resolution exceeding 1000 ppi, a crosstalk phenomenon occurs, resulting in a narrower color gamut that the light-emitting apparatus is capable of reproducing. Providing the space 580 in a high-resolution display panel with more than 1000 ppi, preferably more than 2000 ppi, or further preferably in an ultrahigh-resolution display panel with more than 5000 ppi allows the display panel to express vivid colors.

In this structure example, the light-emitting device 550B, the light-emitting device 550G, and the light-emitting device 550R each emit white light. Accordingly, the second substrate 770 includes a coloring layer CFB, a coloring layer CFG, and a coloring layer CFR. Note that these coloring layers may be provided to partly overlap each other as illustrated in FIG. 11A. When the coloring layers partly overlap each other, the overlap portion can function as a light-blocking film. In this structure example, a material that preferentially transmits blue light (B) is used for the coloring layer CFB, a material that preferentially transmits green light (G) is used for the coloring layer CFG, and a material that preferentially transmits red light (R) is used for the coloring layer CFR, for example.

FIG. 11B illustrates a structure of the light-emitting device 550B in the case where each of the light-emitting device 550B, the light-emitting device 550G, and the light-emitting device 550R is a white-light-emitting device. The EL layer 103P and the EL layer 103Q are stacked over the electrode 551B, with the charge-generation layer 106B between the EL layers. The EL layer 103P includes the light-emitting layer 113B that emits blue light EL(1), and the EL layer 103Q includes the light-emitting layer 113G that emits green light EL(2) and the light-emitting layer 113R that emits red light EL(3).

Note that a color conversion layer can be used instead of the coloring layer. For example, nanoparticles or quantum dots can be used for the color conversion layer.

For example, a color conversion layer that converts blue light into green light can be used instead of the coloring layer CFG. Thus, blue light emitted from the light-emitting device 550G can be converted into green light. Moreover, a color conversion layer that converts blue light into red light can be used instead of the coloring layer CFR. Thus, blue light emitted from the light-emitting device 550R can be converted into red light.

The structure described in this embodiment can be used in an appropriate combination with any of the structures described in the other embodiments.

### Embodiment 5

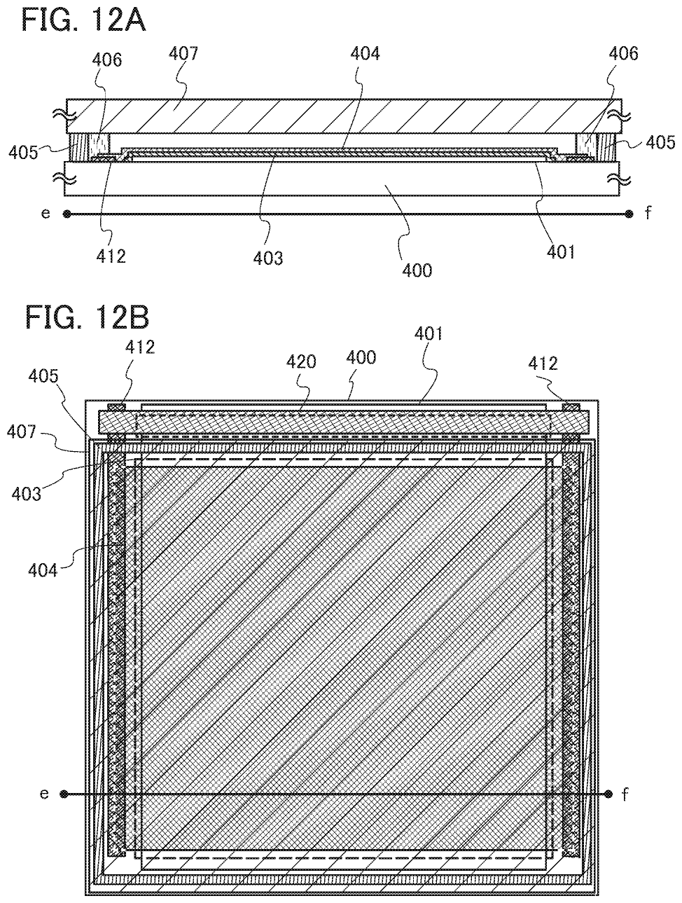

In this embodiment, an example in which the light-emitting device described in Embodiment 2 is used for a lighting device will be described with reference to FIG. 12. By using the light-emitting device described in Embodiment 2 for a lighting device, a lighting device that brings about a high relaxation effect, a lighting device that can suppress eye fatigue of a user and improve the quality of sleep, or a lighting device for light therapy can be provided. FIG. 12B is a top view of the lighting device, and FIG. 12A is a cross-sectional view taken along e-f in FIG. 12B.

In the lighting device in this embodiment, a first electrode 401 is formed over a substrate 400 which is a support and has a light-transmitting property. The first electrode 401 corresponds to the first electrode 101 in Embodiment 2. In the case where light emission is extracted from the first electrode 401 side, the first electrode 401 is formed with a material having a light-transmitting property.

A pad 412 for supplying a voltage to a second electrode 404 is formed over the substrate 400.

An EL layer 403 is formed over the first electrode 401. The EL layer 403 has a structure corresponding to the structure of the EL layer 103 in Embodiment 2, or the structure in which the first light-emitting unit 511 and the second light-emitting unit 512 are combined with the charge-generation layer 513. Note that for these structures, the corresponding description can be referred to.

The second electrode 404 is formed to cover the EL layer 403. The second electrode 404 corresponds to the second electrode 102 in Embodiment 2. In the case where light-emission is extracted from the first electrode 401 side, the second electrode 404 is formed with a material having high reflectivity. The second electrode 404 is supplied with a voltage when connected to the pad 412.

As described above, the lighting device described in this embodiment includes a light-emitting device including the first electrode 401, the EL layer 403, and the second electrode 404. Since the light-emitting device is a light-emitting device with high emission efficiency, the lighting device in this embodiment can be a lighting device with low power consumption.

The substrate 400 over which the light-emitting device having the above structure is formed is fixed to a sealing substrate 407 with sealants 405 and 406 and sealing is performed, whereby the lighting device is completed. It is possible to use only either the sealant 405 or 406. In addition, the inner sealant 406 (not shown in FIG. 12B) can be mixed with a desiccant, which enables moisture to be adsorbed, resulting in improved reliability.

When parts of the pad 412 and the first electrode 401 are provided to extend to the outside of the sealants 405 and 406, those can serve as external input terminals. An IC chip 420 mounted with a converter or the like may be provided over the external input terminals.

The lighting device described in this embodiment uses the light-emitting device described in Embodiment 2 as an EL device; thus, the lighting device can have low power consumption.

### Embodiment 6

In this embodiment, examples of electronic apparatuses each partly including the light-emitting device described in Embodiment 2 are described. The light-emitting device described in Embodiment 2 is a light-emitting device with favorable emission efficiency and low power consumption. As a result, the electronic apparatuses described in this embodiment can be electronic apparatuses each including a light-emitting portion with low power consumption.

Examples of electronic apparatuses to which the light-emitting device is applied include television devices (also referred to as TV or television receivers), monitors for computers and the like, cameras such as digital cameras and digital video cameras, digital photo frames, mobile phones (also referred to as portable telephones or portable telephone devices), portable game machines, portable information terminals, audio playback devices, and large game machines such as pin-ball machines. Specific examples of these electronic apparatuses are shown below.

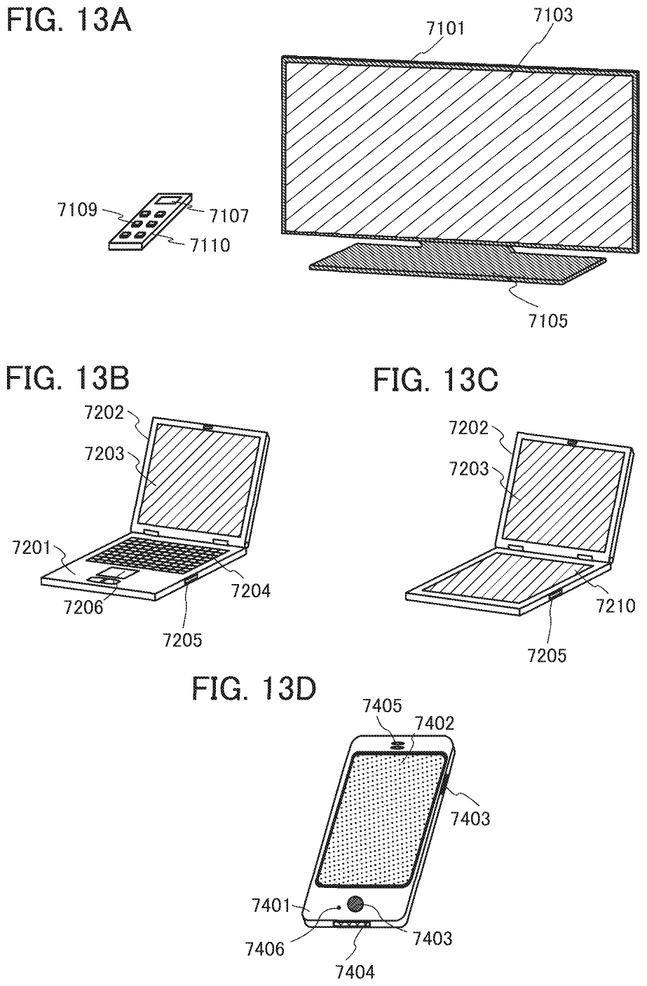

FIG. 13A shows an example of a television device. In the television device, a display portion 7103 is incorporated in a housing 7101. Here, a structure in which the housing 7101 is supported by a stand 7105 is shown. Images can be displayed on the display portion 7103, and the light-emitting devices described in Embodiment 2 are arranged in a matrix in the display portion 7103.

The television device can be operated with an operation switch of the housing 7101 or a separate remote controller 7110. With operation keys 7109 of the remote controller 7110, channels and volume can be operated and images displayed on the display portion 7103 can be operated. Furthermore, a structure may be employed in which the remote controller 7110 is provided with a display portion 7107 for displaying data output from the remote controller 7110.

Note that the television device has a structure of including a receiver, a modem, and the like. With the use of the receiver, a general television broadcast can be received, and moreover, when the television device is connected to a communication network with or without a wire via the modem, one-way (from a sender to a receiver) or two-way (between a sender and a receiver or between receivers) data communication can be performed.

FIG. 13B is a computer which includes a main body 7201, a housing 7202, a display portion 7203, a keyboard 7204, an external connection port 7205, a pointing device 7206, and the like. Note that this computer is fabricated using the light-emitting devices described in Embodiment 2 arranged in a matrix in the display portion 7203. The computer in FIG. 13B may be such a mode as illustrated in FIG. 13C. The computer in FIG. 13C is provided with a second display portion 7210 instead of the keyboard 7204 and the pointing device 7206. The second display portion 7210 is of a touch-panel type, and input can be performed by operating display for input displayed on the second display portion 7210 with a finger or a dedicated pen. The second display portion 7210 can also display images other than the display for input. The display portion 7203 may also be a touch panel. Connecting the two screens with a hinge can prevent troubles such as a crack in or damage to the screens caused when the computer is stored or carried.

FIG. 13D shows an example of a portable terminal. A mobile phone includes operation buttons 7403, an external connection port 7404, a speaker 7405, a microphone 7406, and the like in addition to a display portion 7402 incorporated in a housing 7401. Note that a mobile phone includes the display portion 7402 which is fabricated by arranging the light-emitting devices described in Embodiment 2 in a matrix.

The portable terminal illustrated in FIG. 13D may have a structure in which information can be input by touching the display portion 7402 with a finger or the like. In this case, operations such as making a call and creating an e-mail can be performed by touching the display portion 7402 with a finger or the like.

The display portion 7402 has mainly three screen modes. The first one is a display mode mainly for displaying images, and the second one is an input mode mainly for inputting data such as text. The third one is a display+input mode in which two modes of the display mode and the input mode are combined.

For example, in the case of making a call or creating an e-mail, a text input mode mainly for inputting text is selected for the display portion 7402 so that an operation of inputting text displayed on the screen may be performed. In this case, it is preferable to display a keyboard or number buttons on the entire screen of the display portion 7402.

When a sensing device including a sensor for sensing inclination, such as a gyroscope sensor or an acceleration sensor, is provided inside the portable terminal, screen display of the display portion 7402 can be automatically changed by determining the orientation of the portable terminal (vertically or horizontally).

The screen modes are changed by touching the display portion 7402 or operating the operation buttons 7403 of the housing 7401. Alternatively, the screen modes can be changed depending on the kind of image displayed on the display portion 7402. For example, when a signal of an image displayed on the display portion is moving image data, the screen mode is changed to the display mode, and when the signal is text data, the screen mode is changed to the input mode.

Moreover, in the input mode, when input by the touch operation of the display portion 7402 is not performed for a certain period while a signal sensed by an optical sensor in the display portion 7402 is sensed, the screen mode may be controlled so as to be changed from the input mode to the display mode.

The display portion 7402 can also function as an image sensor. For example, an image of a palm print, a fingerprint, or the like is taken when the display portion 7402 is touched with the palm or the finger, whereby personal authentication can be performed. Furthermore, by using a backlight which emits near-infrared light or a sensing light source which emits near-infrared light in the display portion, an image of a finger vein, a palm vein, or the like can be taken.

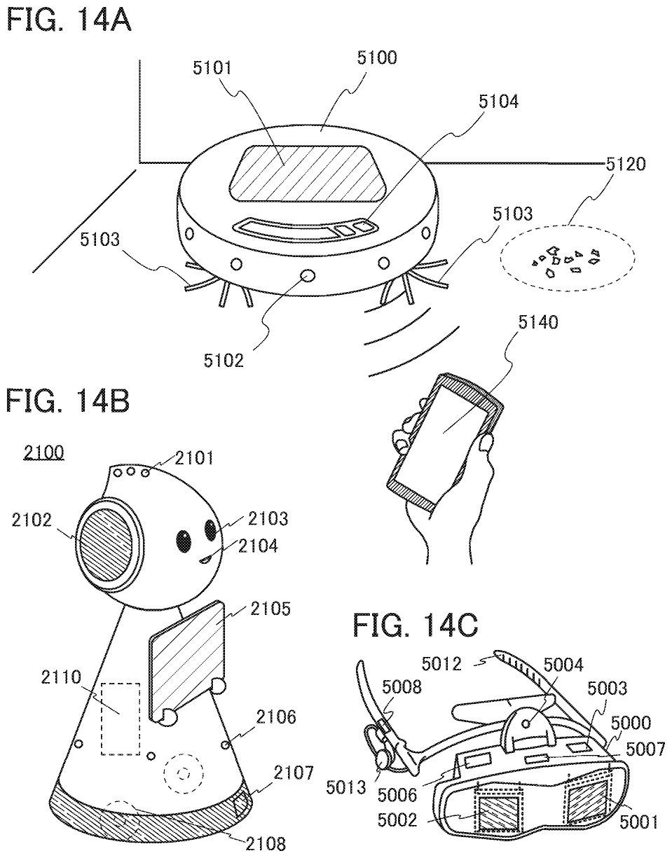

FIG. 14A is a schematic view showing an example of a cleaning robot.

A cleaning robot 5100 includes a display 5101 placed on its top surface, a plurality of cameras 5102 placed on its side surface, a brush 5103, and operation buttons 5104. Although not illustrated, the bottom surface of the cleaning robot 5100 is provided with a tire, an inlet, and the like. Furthermore, the cleaning robot 5100 includes various sensors such as an infrared sensor, an ultrasonic sensor, an acceleration sensor, a piezoelectric sensor, an optical sensor, and a gyroscope sensor. In addition, the cleaning robot 5100 has a wireless communication means.

The cleaning robot 5100 is self-propelled, detects dust 5120, and sucks up the dust through the inlet provided on the bottom surface.

The cleaning robot 5100 can judge whether there is an obstacle such as a wall, furniture, or a step by analyzing images taken by the cameras 5102. When an object that is likely to be caught in the brush 5103, such as a wire, is detected by image analysis, the rotation of the brush 5103 can be stopped.

The display 5101 can display the remaining capacity of a battery, the amount of vacuumed dust, and the like. The display 5101 may display a path on which the cleaning robot 5100 has run. The display 5101 may be a touch panel, and the operation buttons 5104 may be provided on the display 5101.

The cleaning robot 5100 can communicate with a portable electronic apparatus 5140 such as a smartphone. The portable electronic apparatus 5140 can display images taken by the cameras 5102. Accordingly, an owner of the cleaning robot 5100 can monitor the room even from the outside. The display on the display 5101 can be checked by the portable electronic apparatus 5140 such as a smartphone.

The light-emitting apparatus of one embodiment of the present invention can be used for the display 5101.

A robot 2100 illustrated in FIG. 14B includes an arithmetic device 2110, an illuminance sensor 2101, a microphone 2102, an upper camera 2103, a speaker 2104, a display 2105, a lower camera 2106, an obstacle sensor 2107, and a moving mechanism 2108.

The microphone 2102 has a function of detecting a speaking voice of a user, an environmental sound, and the like. The speaker 2104 also has a function of outputting sound. The robot 2100 can communicate with a user using the microphone 2102 and the speaker 2104.

The display 2105 has a function of displaying various kinds of information. The robot 2100 can display information desired by a user on the display 2105. The display 2105 may be provided with a touch panel. Moreover, the display 2105 may be a detachable information terminal, in which case charging and data communication can be performed when the display 2105 is set at the home position of the robot 2100.

The upper camera 2103 and the lower camera 2106 each have a function of taking an image of the surroundings of the robot 2100. The obstacle sensor 2107 can detect the presence of an obstacle in the direction where the robot 2100 advances with the moving mechanism 2108. The robot 2100 can move safely by recognizing the surroundings with the upper camera 2103, the lower camera 2106, and the obstacle sensor 2107. The light-emitting apparatus of one embodiment of the present invention can be used for the display 2105.

FIG. 14C shows an example of a goggle-type display. The goggle-type display includes, for example, a housing 5000, a display portion 5001, a speaker 5003, an LED lamp 5004, a connection terminal 5006, a sensor 5007 (a sensor having a function of measuring force, displacement, position, speed, acceleration, angular velocity, rotational frequency, distance, light, liquid, magnetism, temperature, a chemical substance, sound, time, hardness, an electric field, current, voltage, power, radiation, flow rate, humidity, gradient, oscillation, odor, or infrared ray), a microphone 5008, a display portion 5002, a support 5012, and an earphone 5013.

The light-emitting apparatus of one embodiment of the present invention can be used for the display portion 5001 and the display portion 5002.

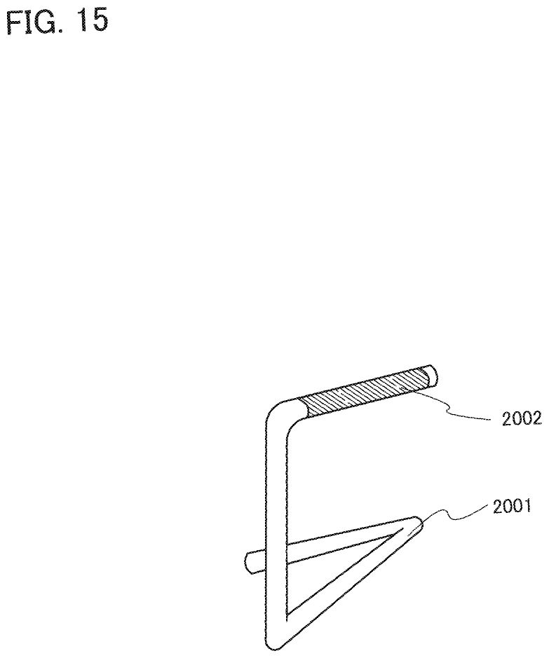

FIG. 15 shows an example in which the light-emitting device described in Embodiment 2 is used for a table lamp which is a lighting device. The table lamp illustrated in FIG. 15 includes a housing 2001 and a light source 2002, and the lighting device described in Embodiment 4 may be used for the light source 2002.

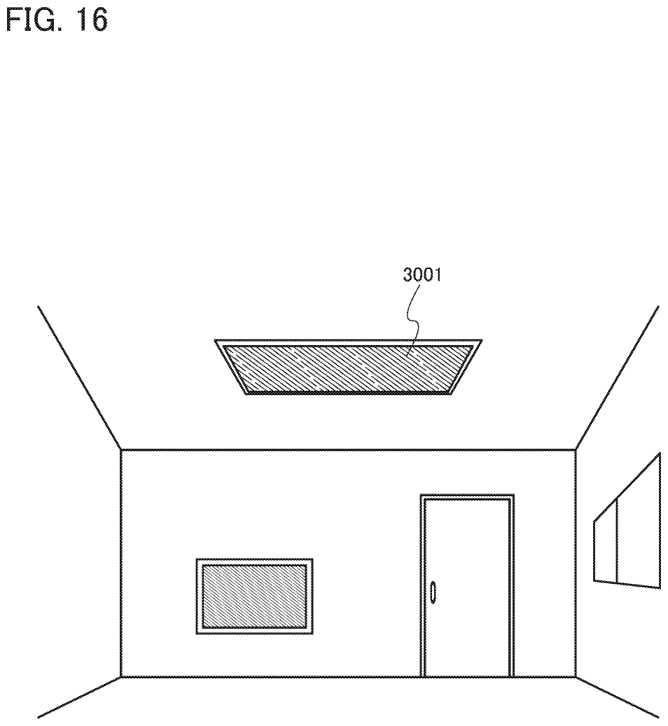

FIG. 16 shows an example in which the light-emitting device described in Embodiment 2 is used for an indoor lighting device 3001. Since the light-emitting device described in Embodiment 2 is a light-emitting device with high emission efficiency, the lighting device can have low power consumption. Furthermore, the light-emitting device described in Embodiment 2 can have a larger area, and thus can be used for a large-area lighting device. Furthermore, the light-emitting device described in Embodiment 2 is thin, and thus can be used for a lighting device having a reduced thickness.

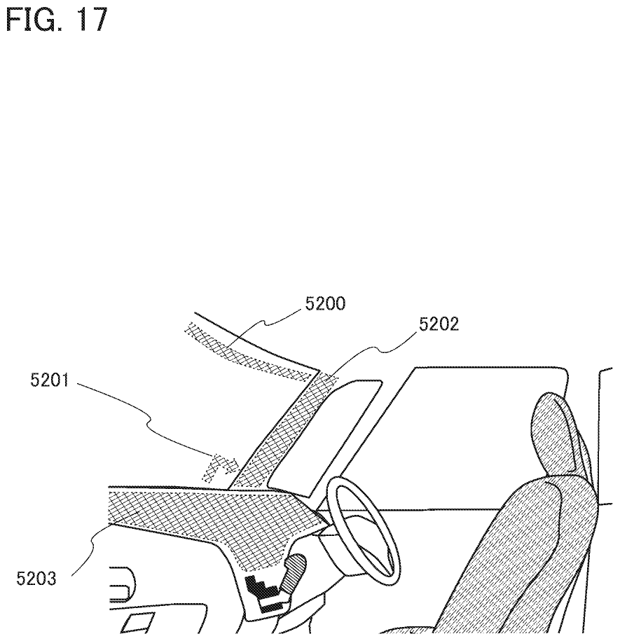

The light-emitting device described in Embodiment 2 can also be incorporated in an automobile windshield or an automobile dashboard. FIG. 17 illustrates one mode in which the light-emitting device described in Embodiment 2 is used for a windshield and a dashboard of an automobile. A display region 5200 to a display region 5203 are each a display region provided using the light-emitting device described in Embodiment 2.

The display region 5200 and the display region 5201 are display devices provided in the automobile windshield, in which the light-emitting devices described in Embodiment 2 are incorporated. When the light-emitting devices described in Embodiment 2 are fabricated using electrodes having light-transmitting properties as a first electrode and a second electrode, what is called see-through display devices, through which the opposite side can be seen, can be obtained. See-through display can be provided without hindering the vision even when being provided in the automobile windshield. Note that in the case where a driving transistor or the like is provided, a transistor having a light-transmitting property, such as an organic transistor using an organic semiconductor material or a transistor using an oxide semiconductor, is preferably used.

The display region 5202 is a display device provided in a pillar portion, in which the light-emitting devices described in Embodiment 2 are incorporated. The display region 5202 can compensate for the view hindered by the pillar by displaying an image taken by an imaging means provided on the car body. Similarly, the display region 5203 provided in the dashboard portion can compensate for the view hindered by the car body by displaying an image taken by an imaging means provided on the outside of the automobile. Thus, blind areas can be compensated for and the safety can be enhanced. Showing an image so as to compensate for the area that cannot be seen makes it possible to confirm safety more naturally and comfortably.

The display region 5203 can provide a variety of kinds of information by displaying navigation information, a speedometer, a rotation rate, a mileage, a fuel level, a gearshift state, air-condition setting, and the like. The content, layout, or the like of the display can be changed freely in accordance with the preference of a user. Note that such information can also be provided on the display region 5200 to the display region 5202. The display region 5200 to the display region 5203 can also be used as lighting devices.

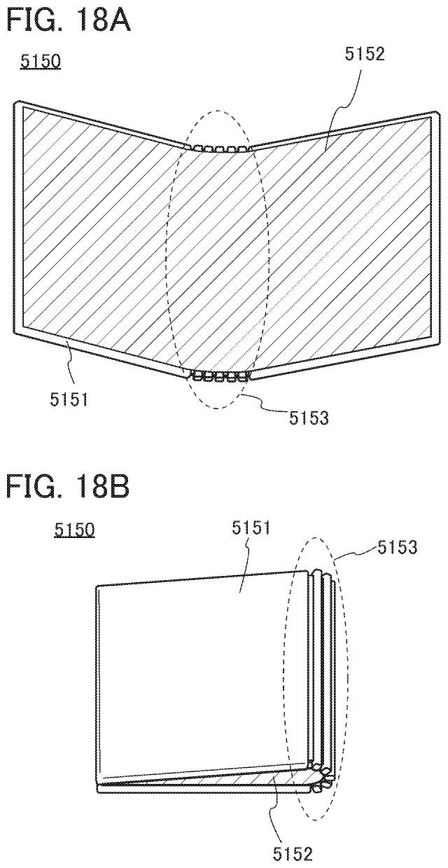

FIG. 18A and FIG. 18B illustrate a foldable portable information terminal 5150. The foldable portable information terminal 5150 includes a housing 5151, a display region 5152, and a bend portion 5153. FIG. 18A illustrates the portable information terminal 5150 that is opened. FIG. 18B illustrates the portable information terminal that is folded. The portable information terminal 5150 is compact in size and has excellent portability when folded, despite its large display region 5152.

The display region 5152 can be folded in half with the bend portion 5153. The bend portion 5153 includes a flexible member and a plurality of supporting members, and when the display region is folded, the flexible member expands and the bend portion 5153 has a radius of curvature of 2 mm or more, preferably 3 mm or more.

Note that the display region 5152 may be a touch panel (an input/output device) including a touch sensor (an input device). The light-emitting apparatus of one embodiment of the present invention can be used for the display region 5152.

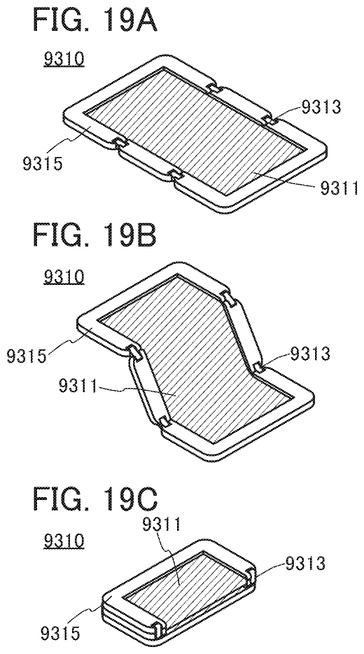

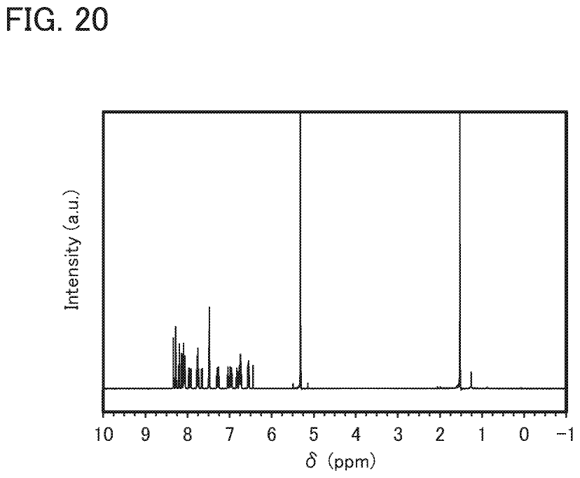

FIG. 19A to FIG. 19C illustrate a foldable portable information terminal 9310. FIG. 19A illustrates the portable information terminal 9310 that is opened. FIG. 19B illustrates the portable information terminal 9310 that is in the state of being changed from one of an opened state and a folded state to the other. FIG. 19C illustrates the portable information terminal 9310 that is folded. The portable information terminal 9310 is excellent in portability when folded, and is excellent in display browsability when opened because of a seamless large display region.

A display panel 9311 is supported by three housings 9315 joined together by hinges 9313. Note that the display panel 9311 may be a touch panel (an input/output device) including a touch sensor (an input device). By folding the display panel 9311 at the hinges 9313 between two housings 9315, the portable information terminal 9310 can be reversibly changed in shape from the opened state to the folded state. A light-emitting apparatus of one embodiment of the present invention can be used for the display panel 9311.

Note that the structures described in this embodiment can be combined with the structures described in any of Embodiment 1 to Embodiment 5 as appropriate.

The compound of one embodiment of the present invention can be used for a photoelectric conversion element such as an organic thin film solar cell (OPV) or an organic photo diode (OPD). Specifically, the organic compound can be used in a carrier-transport layer and a carrier-injection layer because the organic compound has a carrier-transport property. In addition, a mixed film of the organic compound and a donor substance can be used as a charge-generation layer. The organic compound is photoexcited and thus can be used as a power generation layer and an active layer.

As described above, the application range of the light-emitting apparatus including the light-emitting device described in Embodiment 2 is wide so that this light-emitting apparatus can be applied to electronic apparatuses in a variety of fields. With the use of the light-emitting device described in Embodiment 2, an electronic apparatus with low power consumption can be obtained.

### Example 1

### <<Synthesis Example 1>>

Described in this example is a method for synthesizing bis[2-(2-quinolinyl-κN)phenyl-κC][2-(6-phenyl-4-pyrimidinyl-κN³)phenyl-κC]iridium(III) (abbreviation: [Ir(pqn)₂(dppm)]) which is one embodiment of an organometallic complex of the present invention represented by Structural Formula (100) in Embodiment 1. The structure of [Ir(pqn)₂(dppm)] is shown below.

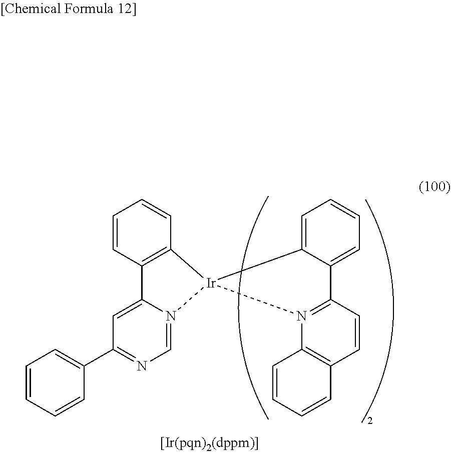

<Step 1: Synthesis of 2-phenylquinoline (Abbreviation: Hpqn)>

7.8 g (38 mmol) of 2-bromoquinoline, 5.5 g (45 mmol) of phenylboronic acid, 113 mL of a 2M aqueous solution of potassium carbonate, and 125 mL of 1,2-dimethoxyethane (DME) were put into a 300 mL three-neck flask and the air in the flask was replaced with nitrogen. 1.2 g (1.0 mmol) of tetrakis(triphenylphosphine)palladium was added to this mixture, and the mixture was heated and refluxed at 90° C. for 3.5 hours. Water was added to the obtained reaction solution, and extraction with ethyl acetate was performed. The obtained solution of the extract was washed with saturated saline, and anhydrous magnesium sulfate was added to the organic layer for drying. The obtained mixture was gravity-filtered to give a filtrate. The filtrate was concentrated to give a solid. The solid was dissolved in toluene, followed by suction filtration through a medium in which Celite, alumina, and Celite were stacked in this order. The filtrate was concentrated to give a solid. This solid was generated by silica gel column chromatography. Toluene was used as the developing solvent. The obtained fraction was concentrated to give 7.3 g of a white solid in a yield of 95%. The synthesis scheme in Step 1 is shown in Formula (a-I) below.

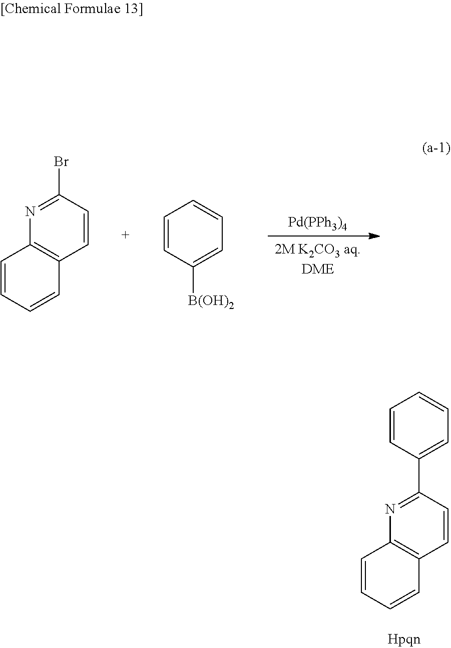 [SMILES: Brc1ccc2ccccc2n1 ; OB(O)c1ccccc1 ; c1ccc(-c2ccc3ccccc3n2)cc1 ; "Pd(PPh3)4"]

<Step 2: Synthesis of di-μ-chloro-tetrakis[2-(2-quinolinyl-κN)phenyl-κC]diiridium(III) (Abbreviation: [Ir(pqn)₂Cl]₂])>

3 g (15 mmol) of Hpqn obtained by the synthesis method in Step 1 above, 1.97 g (6.6 mmol) of IrCl₃·H₂O, 81 mL of 2-ethoxyethanol, and 27 mL of water were put into a three-neck flask and the air in the flask was replaced with argon. This mixture was heated by irradiation with microwaves under conditions of 400 W and 100° C. for one hour to promote a reaction. After a predetermined time elapsed, the obtained mixture was subjected to suction filtration, and the solid was washed with water and ethanol. The obtained filtrate was concentrated and washed with water and then with ethanol to give a solid. The solids obtained after the suction filtration performed twice were combined and washed with toluene, so that 2.2 g of an orange solid was obtained in a yield of 53%. The synthesis scheme in Step 2 is shown in Formula (a-2) below.

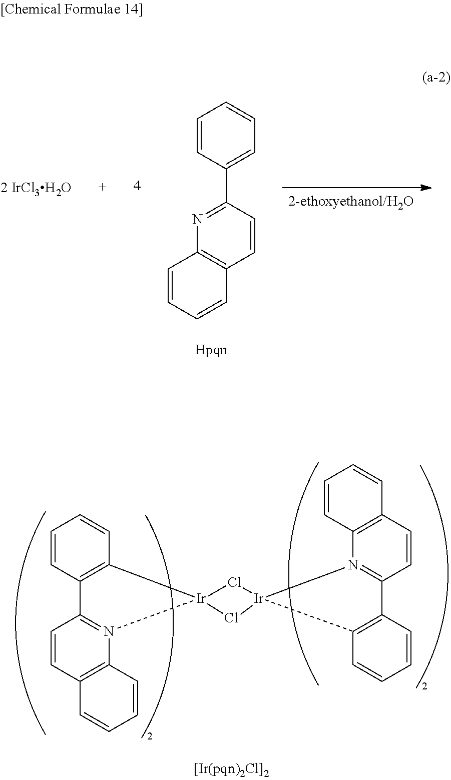

<Step 3: Synthesis of bis[2-(2-quinolinyl-κN)phenyl-κC][2-(6-phenyl-4-pyrimidinyl-κN³)phenyl-κC]iridium(III) (abbreviation: [Ir(pqn)₂(dppm)])>

2.2 g (1.73 mmol) of [Ir(pqn)₂Cl]₂ obtained in Step 2 above and 200 mL of dichloromethane were put into a three-neck flask. A mixed solution of 0.89 g (3.5 mmol) of silver trifluoromethanesulfonate (abbreviation: AgOTf) and 15 mL of methanol was dripped, followed by stirring at room temperature for 16 hours. After a predetermined time elapsed, the obtained mixture was filtered through Celite, and the filtrate was concentrated to give 2.32 g of a deep red solid. The obtained solid, 1.2 g (5.19 mmol) of 2,6-diphenylpyrimidine (abbreviation: Hdppm), and 130 mL of ethanol were put into a three-neck flask and were heated and refluxed for 25 hours. The obtained mixture was concentrated, 3 mL of ethanol was added, and the mixture was suction-filtered. The obtained solid was purified by silica gel column chromatography. Dichloromethane was used as the developing solvent. Moreover, 0.79 g of the obtained solid was purified by high performance liquid chromatography. Chloroform was used as the solvent of a mobile phase. The obtained solid was washed with hexane, so that 0.680 g of a red solid was obtained in a yield of 24%. By a train sublimation method, 0.59 g of the obtained red solid was purified twice by sublimation. The solid was heated under the sublimation purification conditions where the pressure was 1.5 to 1.7×10⁻³ Pa and the argon flow rate was 0 mL/min at 285 to 295° C. After the sublimation purification, a red solid which was the object was obtained in a yield of 24%. The synthesis scheme in Step 3 is shown in Formula (a-3) below.

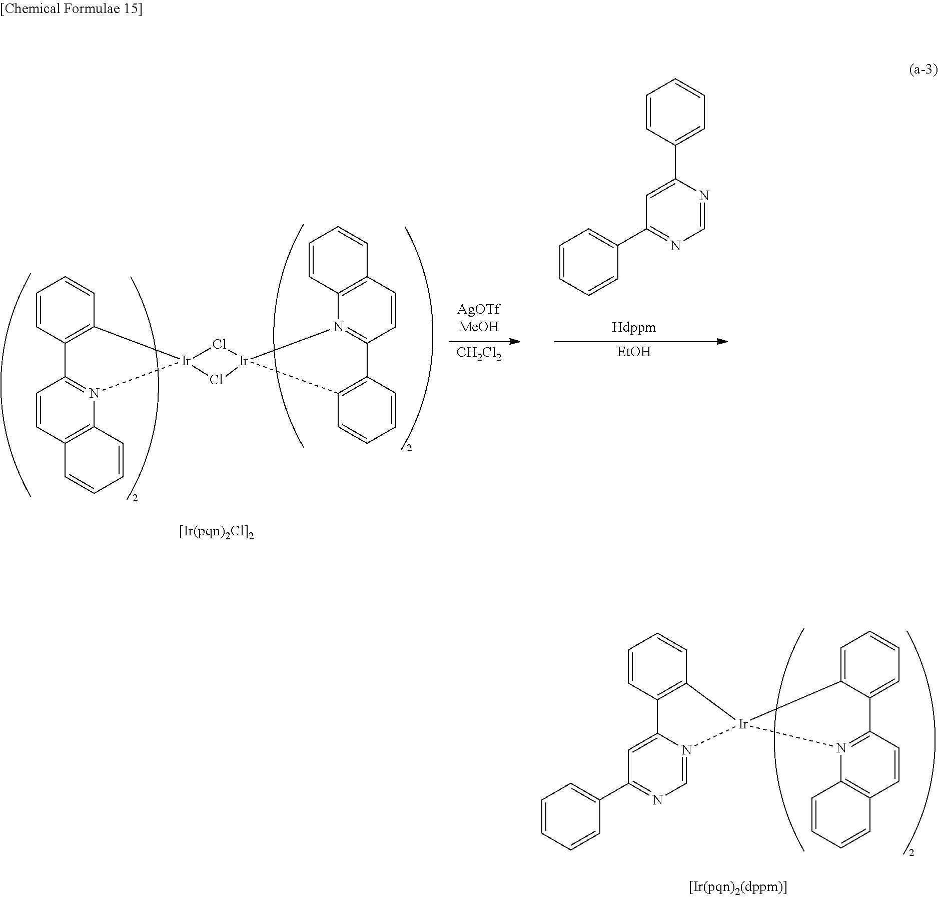

Protons (¹H) of the red solid obtained in Step 3 above were measured by nuclear magnetic resonance (NMR) spectroscopy. The obtained values are shown below. FIG. 20 shows ¹H-NMR charts. These reveal that [Ir(pqn)₂(dppm)], which is one embodiment of an organometallic complex of the present invention represented by Structural Formula (100) above, was obtained in this synthesis example.

¹H-NMR δ (CD₂Cl₂): 6.44 (d, 1H), 6.55 (t, 2H), 6.72-6.77 (m, 4H), 6.83 (t, 1H), 6.94-6.99 (m, 2H), 7.04 (t, 1H), 7.25-7.31 (m, 2H), 7.48-7.49 (m, 3H), 7.66 (d, 1H), 7.33-7.78 (m, 3H), 7.92 (d, 1H), 7.96 (d, 1H), 8.05-8.10 (m, 4H), 8.13 (d, 1H), 8.20 (d, 1H), 8.25-8.29 (m, 2H), 8.34 (s, 1H).

Next, an ultraviolet-visible absorption spectrum (hereinafter simply referred to as an “absorption spectrum”) and an emission spectrum of [Ir(pqn)₂(dppm)] in a dichloromethane solution were measured. The absorption spectrum was measured with an ultraviolet-visible spectrophotometer (V550 manufactured by JASCO Corporation). The measurement was conducted at room temperature, for which the dichloromethane solution (0.0123 mmol/L) was put into a quartz cell. The absorption spectrum is obtained in such a way that the absorption spectrum measured by putting only dichloromethane in a quartz cell was subtracted from the absorption spectrum measured by putting the dichloromethane solution (0.0123 mmol/L) in a quartz cell. The emission spectrum was measured with an absolute PL quantum yield measurement system (C11347-01 manufactured by Hamamatsu Photonics K. K.). The measurement was conducted at room temperature, for which the deoxidized dichloromethane solution (0.0123 mmol/L) was put and sealed in a quartz cell under a nitrogen atmosphere in a glove box (LABstar M13 (1250/780) manufactured by Bright Co., Ltd.).

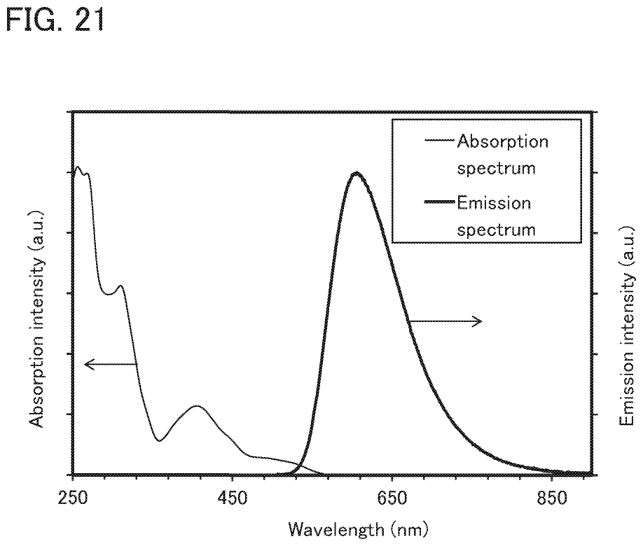

FIG. 21 shows measurement results of the absorption spectrum and the emission spectrum. The horizontal axis represents a wavelength and the vertical axes represent absorption intensity and emission intensity.

As shown in FIG. 21, [Ir(pqn)₂(dppm)] had an emission peak at 606 nm, and reddish-orange light emission from the dichloromethane solution was observed. The half width of the emission spectrum of [Ir(pqn)₂(dppm)] was 104 nm.

### Example 2

This example will describe an element structure and characteristics of a light-emitting device 1 using [Ir(pqn)₂(dppm)], which is described in Example 1, in a light-emitting layer as the light-emitting device of one embodiment of the present invention. Table 1 shows specific components of the light-emitting device 1 used in this example. Chemical formulae of materials used in this example are shown below.

TABLE 1

| | | hole- | hole- | light- | electron- | | electron- | |
|---|---|---|---|---|---|---|---|---|
| | first | injection | transport | emitting | transport | | injection | second |
| | electrode | layer | layer | layer | layer | | layer | electrode |
| light- | ITSO | DBT3P-II:MoOx | BPAFLP | * | 2mDBTBPDBq-II | NBPhen | LiF | Al |
| emitting | (70 nm) | (2:1 70 nm) | (20 nm) | | (30 nm) | (15 nm) | (1 nm) | (200 nm) |
| device 1 | | | | | | | | |

*2mDBTBPDBq-II:PCBBiF:[Ir(pqn)₂(dppm)] (0.8:0.2:0.1 40 nm)

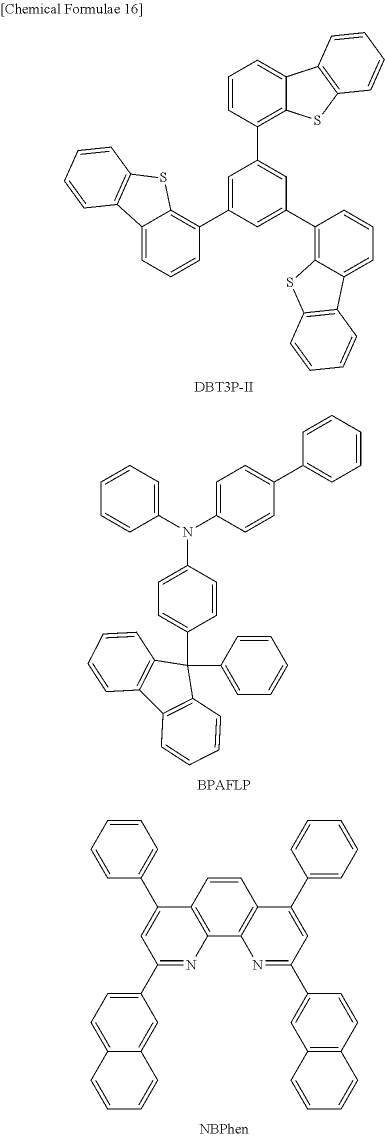 [SMILES: c1ccc2c(c1)sc1c(-c3cc(-c4cccc5c4sc4ccccc45)cc(-c4cccc5c4sc4ccccc45)c3)cccc12 ; c1ccc(-c2ccc(N(c3ccccc3)c3ccc(C4(c5ccccc5)c5ccccc5-c5ccccc54)cc3)cc2)cc1 ; "DBT3P-II" ; c1ccc(-c2cc(-c3ccc4ccccc4c3)nc3c2ccc2c(-c4ccccc4)cc(-c4ccc5ccccc5c4)nc23)cc1]

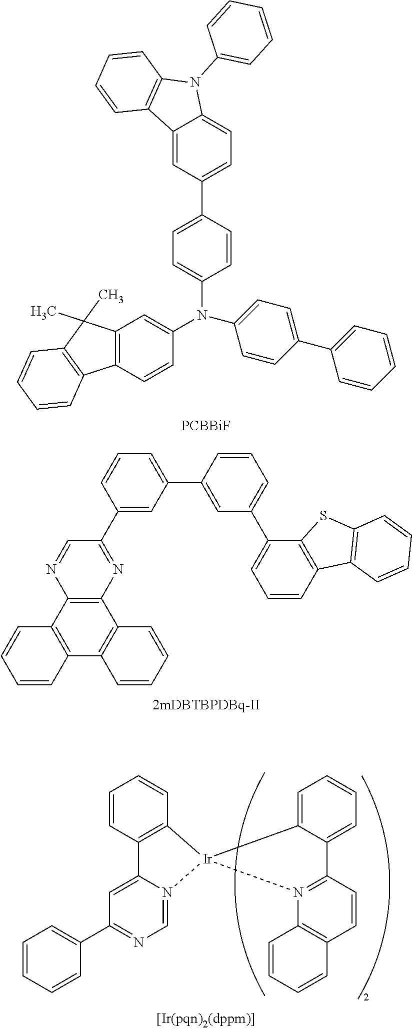

### <<Fabrication of Light-Emitting Device 1>>

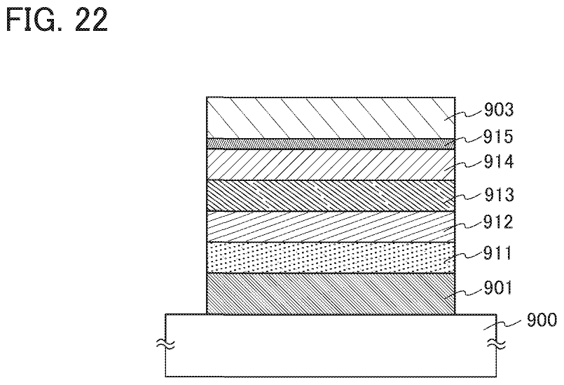

The light-emitting device 1 described in this example has a structure, as illustrated in FIG. 22, in which a hole-injection layer 911, a hole-transport layer 912, a light-emitting layer 913, an electron-transport layer 914, and an electron-injection layer 915 are stacked in this order over a first electrode 901 formed over a substrate 900, and a second electrode 903 is stacked over the electron-injection layer 915.

First, the first electrode 901 was formed over the substrate 900. The electrode area was set to 4 mm² (2 mm×2 mm). A glass substrate was used as the substrate 900. The first electrode 901 was formed by deposition of indium tin oxide containing silicon oxide (ITSO) by a sputtering method to a thickness of 70 nm.

As pretreatment, a surface of the substrate was washed with water, baking was performed at 200° C. for one hour, and then UV ozone treatment was performed for 370 seconds. After that, the substrate was transferred into a vacuum evaporation apparatus where the inside pressure had been reduced to approximately 10⁻⁴ Pa, and was subjected to vacuum baking at 170° C. for 60 minutes in a heating chamber of the vacuum evaporation apparatus, and then the substrate was cooled down for approximately 30 minutes.

Next, the hole-injection layer 911 was formed over the first electrode 901. For the formation of the hole-injection layer 911, the pressure in the vacuum evaporation apparatus was reduced to 10⁻⁴ Pa, and then 4,4′,4″-(benzene-1,3,5-triyl)tri(dibenzothiophene) (abbreviation: DBT3P-II) and molybdenum oxide (abbreviation: MoOx) were co-evaporated such that DBT3P-II: molybdenum oxide was 2:1 (mass ratio) and the thickness was 70 nm.

Then, the hole-transport layer 912 was formed over the hole-injection layer 911. The hole-transport layer 912 was formed by evaporation of 4-phenyl-4′-(9-phenylfluoren-9-yl)triphenylamine (abbreviation: BPAFLP) to a thickness of 20 nm.

Next, the light-emitting layer 913 was formed over the hole-transport layer 912.

For the formation of the light-emitting layer 913, 2-[3-(3′-dibenzothiophen-4-yl)biphenyl]dibenzo[f,h]quinoxaline (abbreviation: 2mDBTBPDBq-II), N-(1,1′-biphenyl-4-yl)-N-[4-(9-phenyl-9H-carbazol-3-yl)phenyl]-9,9-dimethyl-9H-fluoren-2-amine (abbreviation: PCBBiF), and [Ir(pqn)₂(dppm)] were co-evaporated such that 2mDBTBPDBq-II: PCBBiF: [Ir(pqn)₂(dppm)] was 0.8:0.2:0.1 and the thickness was 40 nm.

Next, the electron-transport layer 914 was formed over the light-emitting layer 913. For the formation of the electron-transport layer 914, 2mDBTBPDBq-II was formed to a thickness of 30 nm by evaporation and then 2,9-di(2-naphthyl)-4,7-diphenyl-1,10-phenanthroline (abbreviation: NBPhen) was formed to a thickness of 15 nm by evaporation.

Then, the electron-injection layer 915 was formed over the electron-transport layer 914. The electron-injection layer 915 was formed by evaporation of lithium fluoride (LiF) to a thickness of 1 nm.

Next, the second electrode 903 was formed over the electron-injection layer 915. The second electrode 903 was formed using aluminum by an evaporation method such that the thickness was 200 nm. In this example, the second electrode 903 functions as a cathode.

Through the above steps, the light-emitting device 1 in which an EL layer was provided between the pair of electrodes over the substrate 900 was formed. The hole-injection layer 911, the hole-transport layer 912, the light-emitting layer 913, the electron-transport layer 914, and the electron-injection layer 915 described in the above steps are functional layers forming the EL layer in one embodiment of the present invention. Furthermore, in all the evaporation steps in the above fabrication method, an evaporation method by a resistance-heating method was used.

The fabricated light-emitting device 1 was sealed in a glove box containing a nitrogen atmosphere so as not to be exposed to the air (a sealant was applied to surround the element, and at the time of sealing, UV treatment was performed and then heat treatment was performed at 80° C. for one hour).

### <<Operating Characteristics of Light-Emitting Device 1>>

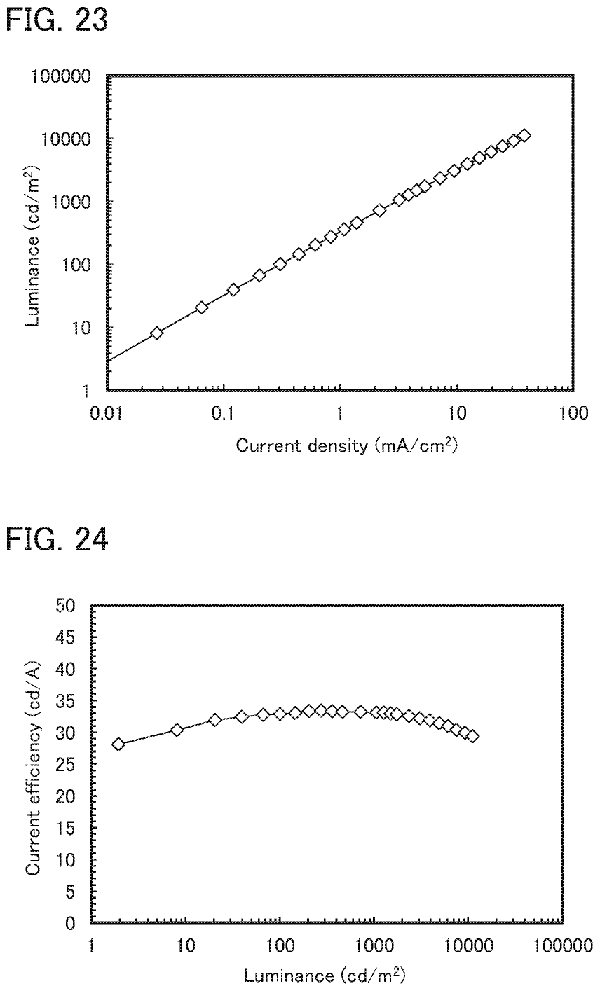

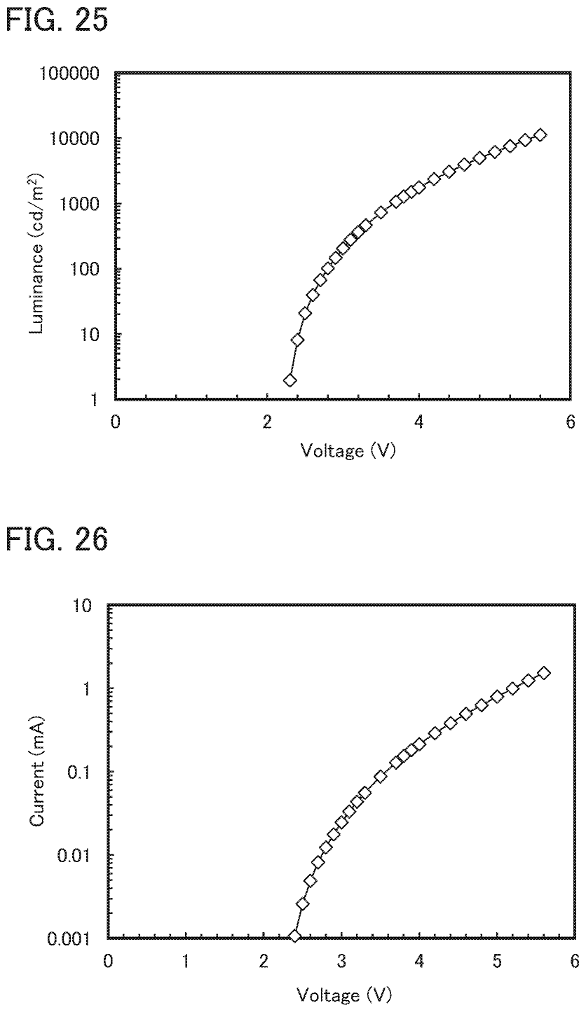

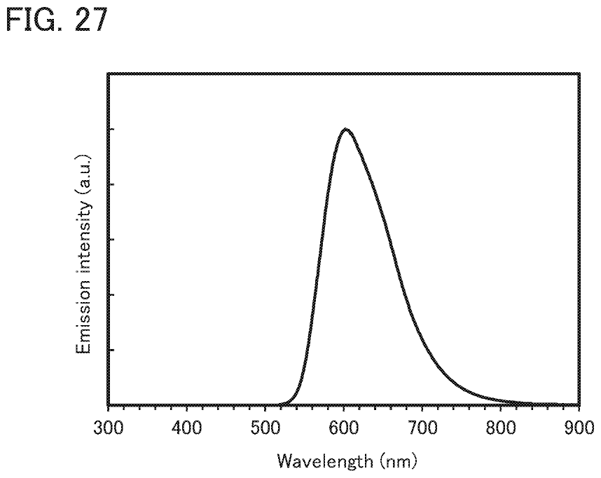

Next, the operating characteristics of the light-emitting device 1 were measured. Note that the measurement was conducted at room temperature (in an atmosphere maintained at 25° C.). FIG. 23 shows the luminance-current density characteristics of the light-emitting device 1. FIG. 24 shows the current efficiency-luminance characteristics thereof. FIG. 25 shows the luminance-voltage characteristics thereof. FIG. 26 shows the current-voltage characteristics thereof. The initial values of main characteristics of the light-emitting device 1 at approximately 1000 cd/m² are listed in Table 2 below.

TABLE 2

| | | | | | | | | external |
|---|---|---|---|---|---|---|---|---|
| | | | | | | current | power | quantum |
| | voltage | current | current density | chromaticity | luminance | efficiency | efficiency | efficiency |
| | (V) | (mA) | (mA/cm²) | (x, y) | (cd/m²) | (cd/A) | (lm/W) | (%) |
| light- | 3.7 | 0.13 | 3.2 | (0.59, 0.40) | 1061 | 33.1 | 28.1 | 19.1 |
| emitting | | | | | | | | |
| device 1 | | | | | | | | |

FIG. 27 shows the emission spectrum of the light-emitting device 1 to which current flows at a current density of 2.5 mA/cm². As shown in FIG. 27, the emission spectrum of the light-emitting device 1 has a peak at 603 nm, which indicates that the light-emitting device 1 emits light derived from the organometallic complex [Ir(pqn)₂(dppm)] included in the EL layer. The half width of the emission spectrum of the light-emitting device 1 was 100 nm.

Such a large half width of the electroluminescence spectrum is preferable because the color-rendering properties are improved; however, the large half width of the electroluminescence spectrum is attributed to a large change in the structure of the transition state of a light-emitting material to be used, so that there has been a problem of a reduction in emission efficiency. However, it is found that with use of the organometallic complex of one embodiment of the present invention, a highly efficient light-emitting device can be obtained. The organometallic complex of one embodiment of the present invention is a material suitable for such a highly efficient light-emitting device that exhibits an electroluminescence spectrum with a large half width and emits light of warm colors.

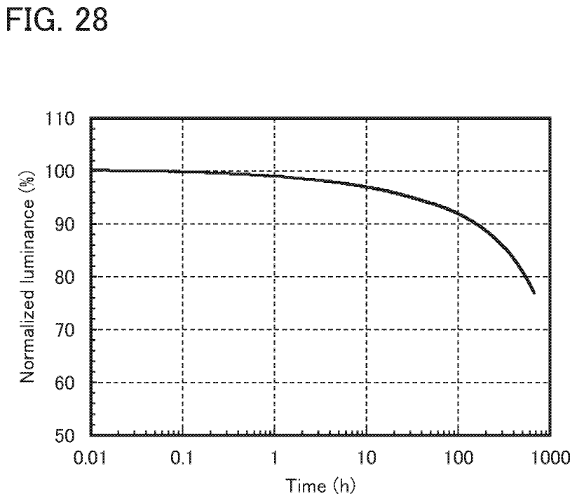

Next, a reliability test was performed on the light-emitting device 1. FIG. 28 shows the result of the reliability test. In FIG. 28, the vertical axis represents normalized luminance (%) with an initial luminance of 100%, and the horizontal axis represents driving time (h) of the element. Note that the reliability test is a driving test at a constant current of 2 mA.

The result of the reliability test shown in FIG. 28 revealed that the light-emitting device 1 including the organometallic complex of one embodiment of the present invention has high reliability. The organometallic complex of one embodiment of the present invention has a shallow HOMO and a deep LUMO as a whole because the HOMO and the LUMO are spatially separated from each other by being distributed over different ligands. In other words, in the organometallic complex used as the light-emitting material in the light-emitting device 1, both at the time of carrier transport and in an excited state, holes are distributed over a ligand that is highly resistant to holes (the second ligand over which the HOMO is likely to be distributed), and electrons are distributed over a ligand that is highly resistant to electrons (the first ligand over which the LUMO is likely to be distributed). This makes it possible to increase stability at the time of carrier transport and in an excited state and to manufacture a light-emitting device with a long lifetime.

Furthermore, by such separation of the HOMO and the LUMO from each other, the organometallic complex itself can transport both carriers. The organometallic complex of one embodiment of the present invention contains, as ligands, two phenylquinoline compounds over which the HOMO is mainly distributed and one phenylpyrimidine compound over which the LUMO is mainly distributed. For this reason, it is considered that the organometallic complex has good hole-injection and electron-injection properties and a good balance of hole-transport and electron-transport properties and a light-emitting region is less likely to be narrowed, whereby the element has high reliability. This is also a factor of an increase in a lifetime of the light-emitting device including the organometallic complex of one embodiment of the present invention.

### REFERENCE NUMERALS

101: first electrode, 102: second electrode, 103: EL layer, 103B: EL layer, 103G: EL layer, 103R: EL layer, 103P: EL layer, 103Q: EL layer, 104B: hole-injection/transport layer, 104G: hole-injection/transport layer, 104R: hole-injection/transport layer, 104P: hole-injection/transport layer, 104Q: hole-injection/transport layer, 106B: charge-generation layer, 106G: charge-generation layer, 106R: charge-generation layer, 107: blocking layer, 111: hole-injection layer, 112: hole-transport layer, 113: light-emitting layer, 113B: light-emitting layer, 113G: light-emitting layer, 113R: light-emitting layer, 114: electron-transport layer, 115: electron-injection layer, 116: charge-generation layer, 117: P-type layer, 118: electron-relay layer, 119: electron-injection buffer layer, 400: substrate, 401: first electrode, 403: EL layer, 404: second electrode, 405: sealant, 406: sealant, 407: sealing substrate, 412: pad, 420: IC chip, 501: anode, 502: cathode, 510: substrate, 511: first light-emitting unit, 512: second light-emitting unit, 513: charge-generation layer, 520: functional layer, 528: partition, 528B: opening, 528G: opening, 528R: opening, 550B: light-emitting device, 550G: light-emitting device, 550R: light-emitting device, 551B: electrode, 551G: electrode, 551R: electrode, 552: electrode, 580: space, 601: driver circuit portion (source line driver circuit), 602: pixel portion, 603: driver circuit portion (gate line driver circuit), 604: sealing substrate, 605: sealant, 607: space, 608: wiring, 609: FPC (flexible printed circuit), 610: element substrate, 611: switching FET, 612: current control FET, 613: first electrode, 614: insulator, 616: EL layer, 617: second electrode, 618: light-emitting device, 700: light-emitting apparatus, 705: insulating layer, 770: substrate, 900: substrate, 901: first electrode, 903: second electrode, 911: hole-injection layer, 912: hole-transport layer, 913: light-emitting layer, 914: electron-transport layer, 915: electron-injection layer, 951: substrate, 952: electrode, 953: insulating layer, 954: partition layer, 955: EL layer, 956: electrode, 1001: substrate, 1002: base insulating film, 1003: gate insulating film, 1006: gate electrode, 1007: gate electrode, 1008: gate electrode, 1020: first interlayer insulating film, 1021: second interlayer insulating film, 1022: electrode, 1024W: first electrode, 1024R: first electrode, 1024G: first electrode, 1024B: first electrode, 1025: partition, 1028: EL layer, 1029: second electrode, 1031: sealing substrate, 1032: sealant, 1033: transparent base material, 1034R: red coloring layer, 1034G: green coloring layer, 1034B: blue coloring layer, 1035: black matrix, 1036: overcoat layer, 1037: third interlayer insulating film, 1040: pixel portion, 1041: driver circuit portion, 1042: peripheral portion, 2001: housing, 2002: light source, 2100: robot, 2110: arithmetic device, 2101: illuminance sensor, 2102: microphone, 2103: upper camera, 2104: speaker, 2105: display, 2106: lower camera, 2107: obstacle sensor, 2108: moving mechanism, 3001: lighting device, 5000: housing, 5001: display portion, 5002: display portion, 5003: speaker, 5004: LED lamp, 5006: connection terminal, 5007: sensor, 5008: microphone, 5012: support, 5013: earphone, 5100: cleaning robot, 5101: display, 5102: camera, 5103: brush, 5104: operation button, 5150: portable information terminal, 5151: housing, 5152: display region, 5153: bend portion, 5120: dust, 5200: display region, 5201: display region, 5202: display region, 5203: display region, 7101: housing, 7103: display portion, 7105: stand, 7107: display portion, 7109: operation key, 7110: remote controller, 7201: main body, 7202: housing, 7203: display portion, 7204: keyboard, 7205: external connection port, 7206: pointing device, 7210: second display portion, 7401: housing, 7402: display portion, 7403: operation button, 7404: external connection port, 7405: speaker, 7406: microphone, 9310: portable information terminal, 9311: display panel, 9313: hinge, 9315: housing,

1. An organometallic complex represented by General Formula G1, 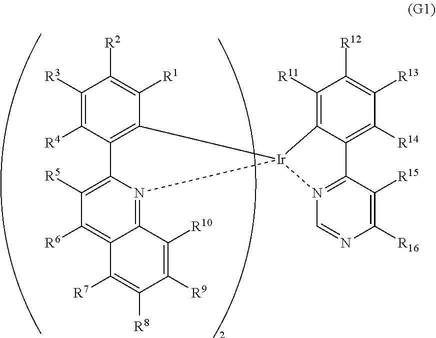
wherein in General Formula (G1), R¹ to R¹⁶ each independently represent any one of hydrogen, a substituted or unsubstituted alkyl group having 1 to 6 carbon atoms, a substituted or unsubstituted aryl group having 6 to 13 carbon atoms, and a substituted or unsubstituted heteroaryl group having 3 to 12 carbon atoms.

2. An organometallic complex represented by General Formula G2, 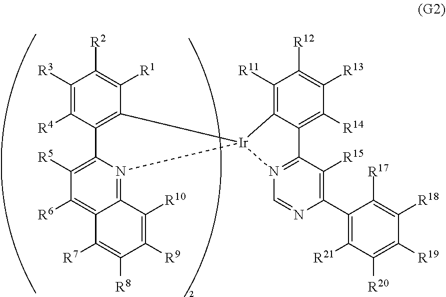
wherein in General Formula (G2), R¹ to R¹⁵ and R¹⁷ to R²¹ each independently represent any one of hydrogen, a substituted or unsubstituted alkyl group having 1 to 6 carbon atoms, a substituted or unsubstituted aryl group having 6 to 13 carbon atoms, and a substituted or unsubstituted heteroaryl group having 3 to 12 carbon atoms.

3. The organometallic complex according to claim 1,
wherein a half width of an emission spectrum is greater than or equal to 90 nm and less than or equal to 120 nm.

4. The organometallic complex according to claim 3,
wherein a peak wavelength of an emission spectrum is greater than or equal to 590 nm and less than or equal to 620 nm.

5. An organometallic complex represented by Structural Formula (100).

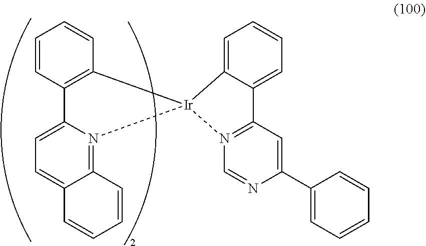

6. A light-emitting device comprising the organometallic complex according to claim 1.

7. A light-emitting device comprising an EL layer between a pair of electrodes,
wherein the EL layer comprises the organometallic complex according to claim 1.

8. A light-emitting device comprising an EL layer between a pair of electrodes,
wherein the EL layer comprises a light-emitting layer, and
wherein the light-emitting layer comprises the organometallic complex according to claim 1.

9. The light-emitting device according to claim 6,
wherein a half width of an electroluminescence spectrum is greater than or equal to 90 nm and less than or equal to 120 nm.

10. The light-emitting device according to claim 6,
wherein a peak wavelength of an electroluminescence spectrum is greater than or equal to 590 nm and less than or equal to 620 nm.

11. A light-emitting apparatus comprising:
the light-emitting device according to claim 6; and
at least one of a transistor and a substrate.

12. An electronic device comprising:
the light-emitting apparatus according to claim 11; and
at least one of a microphone, a camera, a button for operation, an external connection portion, and a speaker.

13. A lighting device comprising the light-emitting device according to claim 6, and a housing.

14. The organometallic complex according to claim 2,
wherein a half width of an emission spectrum is greater than or equal to 90 nm and less than or equal to 120 nm.

15. The organometallic complex according to claim 2,
wherein a peak wavelength of an emission spectrum is greater than or equal to 590 nm and less than or equal to 620 nm.

16. A light-emitting device comprising the organometallic complex according to claim 2.

17. A light-emitting device comprising an EL layer between a pair of electrodes,
wherein the EL layer comprises the organometallic complex according to claim 2.

18. A light-emitting device comprising an EL layer between a pair of electrodes,
wherein the EL layer comprises a light-emitting layer, and
wherein the light-emitting layer comprises the organometallic complex according to claim 2.

19. A light-emitting device comprising the organometallic complex according to claim 5.

20. A light-emitting device comprising an EL layer between a pair of electrodes,
wherein the EL layer comprises the organometallic complex according to claim 5.

21. A light-emitting device comprising an EL layer between a pair of electrodes,
wherein the EL layer comprises a light-emitting layer, and
wherein the light-emitting layer comprises the organometallic complex according to claim 5.
